(19) United States
(12) Patent Application Publication
(10) Pub. No.: US 2026/0206392 A1
(43) Pub. Date: Jul. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Sun Hwa LEE, Yongin-si (KR); Ji Sun KIM, Yongin-si (KR); Se Hyun LEE, Yongin-si (KR); Kwi Hyun KIM, Yongin-si (KR); Kyung Hoon CHUNG, Yongin-si (KR)

(21) Appl. No.: 19/378,918

(22) Filed: Nov. 4, 2025

(30) Foreign Application Priority Data
Jan. 13, 2025 (KR) 10-2025-0004645

(51) Int. Cl. H10H 29/49; H10H 29/32; H10K 59/121; H10K 59/131

(52) U.S. Cl. CPC H10H 29/49; H10H 29/32; H10K 59/1213; H10K 59/1216; H10K 59/1315

(57) ABSTRACT

A display device includes pixels located in a display area where an image is displayed, each of the pixels including a plurality of pixel circuits located in a backplane layer of the display device, a plurality of pixel electrodes and a common electrode located on the backplane layer, and a plurality of light emitting elements electrically connected between the pixel electrodes and the common electrode, first power lines located in the backplane layer in the display area and electrically connected to the pixel circuits of the pixels, and second power lines located in the backplane layer in the display area and electrically connected to the common electrode of the pixels, wherein the common electrode and the second power lines cross each other in the display area and are electrically connected to each other.

### CROSS-REFERENCE TO RELATED APPLICATION

This application claims priority to and the benefit of Korean Patent Application No. 10-2025-0004645, filed on January 13, 2025, in the Korean Intellectual Property Office, the entire disclosure of which is incorporated by reference herein.

### BACKGROUND

### Field

Embodiments of the present disclosure relate to a display device and an electronic device including the same.

### Description of the Related Art

As the information society develops, demands for display devices for displaying images are increasing in various forms. For example, display devices are included in various electronic devices and are used as display screens of the electronic devices. Accordingly, various types of display devices, including light emitting display devices, are being developed.

### SUMMARY

Aspects of the present disclosure provide a display device, which can reduce a drop in a driving voltage transmitted to the pixels, and an electronic device including the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including pixels located in a display area where an image is displayed, each of the pixels including a plurality of pixel circuits located in a backplane layer of the display device, a plurality of pixel electrodes and a common electrode located on the backplane layer, and a plurality of light emitting elements electrically connected between the pixel electrodes and the common electrode, first power lines located in the backplane layer in the display area and electrically connected to the pixel circuits of the pixels, and second power lines located in the backplane layer in the display area and electrically connected to the common electrode of the pixels, wherein the common electrode and the second power lines cross each other in the display area and are electrically connected to each other.

In one or more embodiments, the display device may further include a power bus line located in a non-display area surrounding the display area, and the common electrode may be electrically connected to the power bus line by extending to the non-display area.

In one or more embodiments, the display device may further include at least one scan driver located in the non-display area and electrically connected to the pixel circuits of the pixels, and at least a portion of the power bus line may be located between the display area and the scan driver.

In one or more embodiments, the power bus line may be located on a left side and a right side of the display area, and the common electrode may extend in both directions from the display area toward the power bus line.

In one or more embodiments, the power bus line may be further located on at least one of an upper side and a lower side of the display area.

In one or more embodiments, the power bus line may include at least one of a first wiring layer which is located on a same layer as the common electrode and extends from the common electrode and a second wiring layer which is located in the backplane layer and electrically connected to the common electrode through at least one contact hole.

In one or more embodiments, the pixels may be arranged in along first direction and a second direction in the display area, wherein two or more pixels of the pixels of each pixel row are arranged along the first direction and may share the common electrode extending in the first direction, and common electrodes of two or more pixels of the pixels, which are arranged along the second direction, may be arranged along the second direction.

In one or more embodiments, the second power lines may be arranged along the first direction in the display area and each of the second power lines may extend in the second direction.

In one or more embodiments, the pixel circuits may include a first pixel circuit, a second pixel circuit and a third pixel circuit arranged along the first direction in each pixel area where each of the pixels is located.

In one or more embodiments, the second power lines may be located between the first pixel circuit and the second pixel circuit of each of the pixels.

In one or more embodiments, the second power lines may be located between pixel circuits of two pixels adjacent to each other in the first direction.

In one or more embodiments, the pixel electrodes may include a first pixel electrode, a second pixel electrode, and a third pixel electrode located on the first pixel circuit, the second pixel circuit, and the third pixel circuit, respectively, and may be electrically connected to the first pixel circuit, the second pixel circuit, and the third pixel circuit, respectively, and the common electrode may be located on a same layer as the first pixel electrode, the second pixel electrode, and the third pixel electrode and may face the first pixel electrode, the second pixel electrode, and the third pixel electrode in the second direction.

In one or more embodiments, the light emitting elements may include a first light emitting element located on the first pixel electrode and the common electrode, a second light emitting element located on the second pixel electrode and the common electrode, and a third light emitting element located on the third pixel electrode and the common electrode.

In one or more embodiments, the first power lines may be arranged along the first direction in the display area and each of the first power lines may extend in the second direction.

In one or more embodiments, the first power lines and the second power lines may be located on a same layer and may be spaced from each other in the first direction.

In one or more embodiments, one of the first power lines may overlap the first pixel circuit, and an other of the first power lines may overlap the second pixel circuit and the third pixel circuit.

In one or more embodiments, the second pixel circuit and the third pixel circuit may be connected in common to the other of the first power lines and are symmetrical to each other with respect to the other of the first power lines.

In one or more embodiments, the display device may further include a first emission control line extending in the first direction in the display area and electrically connected to the first pixel circuit, and a second emission control line extending in the first direction in the display area and electrically connected to the second pixel circuit and the third pixel circuit.

In one or more embodiments, the common electrode and the second power lines may be electrically connected to each other in the display area through a plurality of contact holes in an insulating layer located between the common electrode and the second power lines.

According to one or more embodiments of the present disclosure, there is provided an electronic device including a display module including a display panel; a memory configured to store an image data signal or an input control signal; and a processor configured to transmit the image data signal or the input control signal, which is stored in the memory, to the display module. The display panel may include pixels located in a display area, each of the pixels including a plurality of pixel circuits located in a backplane layer of the display panel, a plurality of pixel electrodes and a common electrode located on the backplane layer, and a plurality of light emitting elements electrically connected between the pixel electrodes and the common electrode, first power lines located in the backplane layer in the display area and electrically connected to the pixel circuits of the pixels, and second power lines located inside the backplane layer in the display area and electrically connected to the common electrode of the pixels, and the common electrode and the second power lines may cross each other inside the display area and may be electrically connected to each other.

A display device according to one or more embodiments may include common electrodes and second power lines which intersect each other in a display area and are electrically connected to each other. In the display device according to the embodiments and an electronic device including the same, a drop of a driving voltage transmitted to pixels through the common electrodes and the second power lines may be reduced. Accordingly, the power consumption of the display device and the electronic device including the same can be reduced.

In some embodiments, pixel circuits of two subpixels included in one pixel may be designed symmetrically in a flipped form. Accordingly, the design structure of the display area can be improved or optimized, and the second power lines can be appropriately placed in a secured design space.

Additionally, the display device according to one or more embodiments may further include a power bus line which is located in a non-display area and electrically connected to the common electrodes and the second power lines. In some embodiments, because a mesh-shaped power line is formed by the common electrodes and the second power lines, wiring resistance is reduced. Accordingly, a width of the power bus line can be reduced, and a size of the non-display area can be reduced or minimized.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of one or more embodiments, taken in conjunction with the accompanying drawings in which:

FIG. 1 is a perspective view of a display device according to one or more embodiments;

FIG. 2 is a plan view of a display panel according to one or more embodiments;

FIG. 3 is a block diagram of the display device according to one or more embodiments;

FIG. 4 is an equivalent circuit diagram of a subpixel according to one or more embodiments;

FIG. 5 is a waveform diagram illustrating driving signals of the subpixel according to one or more embodiments;

FIG. 6 is a plan view illustrating pixel circuits, signal lines, and power lines located in a backplane layer of a display panel according to one or more embodiments;

FIG. 7 is a plan view illustrating pixel circuits, signal lines, and power lines located in a backplane layer of a display panel according to one or more embodiments;

FIG. 8 is a plan view illustrating second power lines, pixel electrodes, and common electrodes located in a display area of a display panel according to one or more embodiments;

FIG. 9 is a layout view of a backplane layer of a display panel according to one or more embodiments;

FIG. 10 is a detailed layout view of a first pixel circuit of FIG. 9;

FIG. 11 is a detailed layout view of a second pixel circuit of FIG. 9;

FIG. 12 is a detailed layout view of a third pixel circuit of FIG. 9;

FIG. 13 is a layout view illustrating patterns included in a first semiconductor layer, a first gate conductive layer, a second semiconductor layer, and a third gate conductive layer of a backplane layer according to one or more embodiments;

FIG. 14 is a layout view illustrating patterns included in a first gate conductive layer and a second gate conductive layer according to one or more embodiments;

FIG. 15 is a layout view illustrating patterns included in a first source-drain conductive layer and a second source-drain conductive layer of a backplane layer according to one or more embodiments;

FIG. 16 is a layout view illustrating, in detail, part of a first pixel circuit, a second pixel circuit, and a third pixel circuit according to one or more embodiments;

FIG. 17 is a layout view illustrating, in detail, part of the first pixel circuit, the second pixel circuit, and the third pixel circuit according to one or more embodiments;

FIG. 18 is a layout view of a light emitting element layer of a display panel according to one or more embodiments;

FIG. 19 is a cross-sectional view illustrating an example of a cross-section of a display panel corresponding to the line X1-X1’ of FIGS. 9 and 18;

FIG. 20 is a detailed cross-sectional view of an area A2 of FIG. 19;

FIG. 21 is a cross-sectional view illustrating an example of a cross-section of a display panel corresponding to the lines X2-X2’ and X3-X3’ of FIGS. 9 and 18;

FIG. 22 is a cross-sectional view illustrating an example of a cross-section of a display panel corresponding to the line X1-X1’ of FIGS. 9 and 18;

FIG. 23 is a plan view of a display panel according to one or more embodiments;

FIG. 24 is a plan view of a display panel according to one or more embodiments;

FIG. 25 is a plan view of a display panel according to one or more embodiments;

FIG. 26 is a plan view of a display panel according to one or more embodiments;

FIG. 27 is a detailed plan view of an area A3 of FIG. 23;

FIG. 28 is a detailed plan view of the area A3 of FIG. 23;

FIG. 29 is a detailed plan view of the area A3 of FIG. 23;

FIG. 30 is an example view of a smart watch including a display device according to one or more embodiments;

FIGS. 31 and 32 are example views of a head-mounted display device including display devices according to one or more embodiments;

FIG. 33 is an example view of a head-mounted display device including a display device according to one or more embodiments;

FIG. 34 is an example view illustrating a vehicle instrument cluster and center fascia including display devices according to one or more embodiments; and

FIG. 35 is an example view of a transparent display device including a display device according to one or more embodiments.

FIG. 36 is a block diagram of an electronic device according to one or more embodiments.

### DETAILED DESCRIPTION

The present disclosure will now be described more fully hereinafter with reference to the accompanying drawings, in which embodiments of the present disclosure are shown. This disclosure may, however, be embodied in different forms and should not be construed as limited to embodiments set forth herein. Rather, these embodiments are provided so that the present disclosure will be thorough and complete, and will fully convey the scope of the present disclosure to those skilled in the art.

It will also be understood that when an element or a layer is referred to as being "on" another element or layer, it can be directly on the other element or layer, or intervening layers may also be present. The same reference numbers indicate the same components throughout the specification.

It will be understood that, although the terms "first," "second," etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

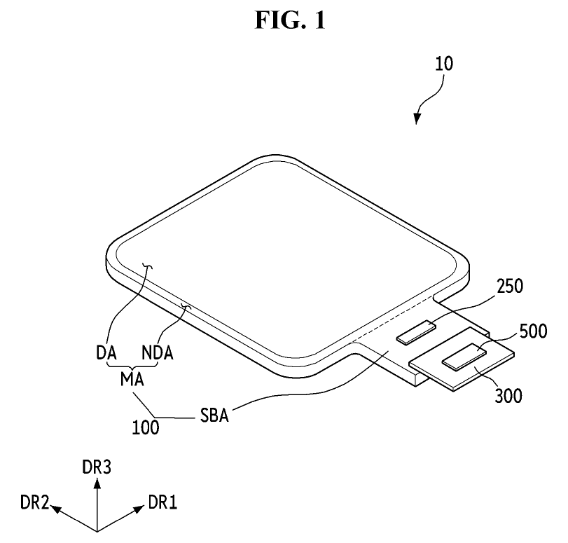

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices, and/or ultra-mobile PCs (UMPCs), as well as in various electronic devices such as televisions, notebook computers, monitors, billboards, and/or Internet of things (IoT) devices. In addition, the display device 10 may be included in other electronic devices, such as a virtual reality (VR) device and/or an augmented reality (AR) device, and may be used to display images in the electronic devices. In one or more embodiments, an electronic device including the display device 10 may further include a display device housing, in which the display device 10 is accommodated, and/or a case or cover for protecting the display device 10.

In one or more embodiments, the display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or a micro- or nano-light emitting display device using a micro- or nano-light emitting diode (LED). A case where the display device 10 is a micro- or nano-light emitting display device will be mainly described below, but the present disclosure is not limited to this case. For ease of description, a micro- or nano-LED will be referred to as a light emitting element.

The display device 10 may include a display panel 100, a display driver 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded or right-angled. The planar shape of the display panel 100 is not limited to a quadrangular shape but may also be other polygonal shapes, a circular shape, or an elliptical shape. The display panel 100 may be formed flat, but the present disclosure is not limited to this case. For example, the display panel 100 may include a curved portion formed at left and right ends and having a constant or varying curvature. In one or more embodiments, the display panel 100 may be formed to be flexible so that it can be curved, bent, folded, and/or rolled.

The display panel 100 may include a main area MA and a sub-area SBA.

The main area MA may include a display area DA that displays an image and a non-display area NDA that is located around the display area DA. The display area DA may include pixels that display an image. Each of the pixels may include a plurality of subpixels. For example, each of the pixels may include a first subpixel that emits light of a first color (or first light), a second subpixel that emits light of a second color (or second light), and a third subpixel that emits light of a third color (third light), but the present disclosure is not limited to this example.

The sub-area SBA may protrude from a side of the main area MA in the second direction DR2 (e.g., a vertical direction of the display panel 100). Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3, which is a thickness direction of the display panel 100. The display driver 250 may be located in the sub-area SBA.

The display driver 250 may generate signals and voltages for driving the display panel 100. The display driver 250 may be formed as an integrated circuit (IC) and attached onto the display panel 100 using a chip on glass (COG) method, a chip on plastic (COP) method, and/or an ultrasonic bonding method. However, the present disclosure is not limited to this case. For example, the display driver 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driver 250. The display panel 100 and the display driver 250 may receive digital video data, timing signals, and driving voltages through the circuit board 300. The circuit board 300 may be a flexible printed circuit board (FPCB), a printed circuit board (PCB), or a flexible film such as a chip on film (CoF).

The power supply unit 500 may generate panel driving voltages according to a power supply voltage supplied from the outside. The power supply unit 500 may be formed as an integrated circuit (IC) and attached onto the circuit board 300 using the COF method.

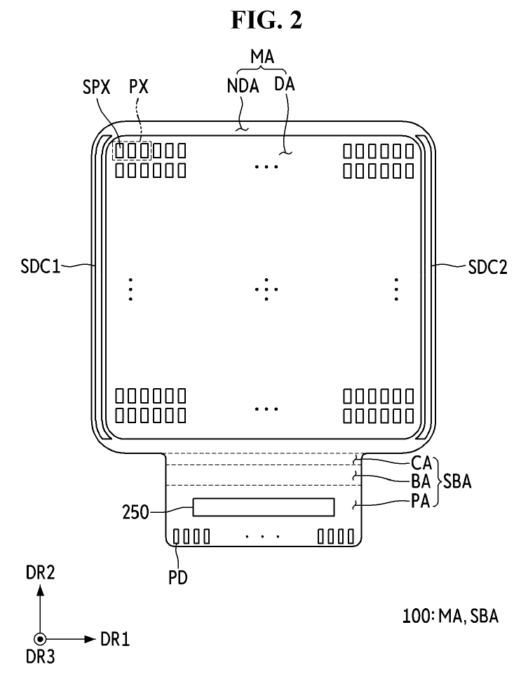

FIG. 2 is a plan view of a display panel 100 according to one or more embodiments. FIG. 2 shows a state in which a sub-area SBA is unfolded.

Referring to FIGS. 1 and 2, the display panel 100 may include a main area MA and the sub-area SBA.

The main area MA may include a display area DA that displays an image and a non-display area NDA that is located around the display area DA along an edge or a periphery of the display area DA. The display area DA may occupy most of the main area MA. The display area DA may be located in the center of the main area MA.

The display area DA may include pixels PX for displaying an image, and each of the pixels PX may include a plurality of subpixels SPX. A pixel PX may be defined as the smallest subpixel group that can express a white gray level.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be located in the non-display area NDA. The first scan driver SDC1 may be located on a side (e.g., a left side) of the display panel 100, and the second scan driver SDC2 may be located on the other side (e.g., a right side) of the display panel 100, but the present disclosure is not limited to this case. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, generate scan signals according to the scan control signal, and output the scan signals to scan lines. Although FIG. 2 discloses an embodiment in which the display device 10 (e.g., the display panel 100) includes two scan drivers (e.g., the first scan driver SDC1 and the second scan driver SDC2) located on opposite sides of the display area DA, the present disclosure is not limited to this embodiment. For example, the display device 10 may include at least one scan driver, and the number or positions of scan drivers included in the display device 10 may vary depending on embodiments.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driver 250 are located. The display driver 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be located between the connection area CA and the pad area PA. A side of the bending area BA may contact the connection area CA, and the other side of the bending area BA may contact the pad area PA.

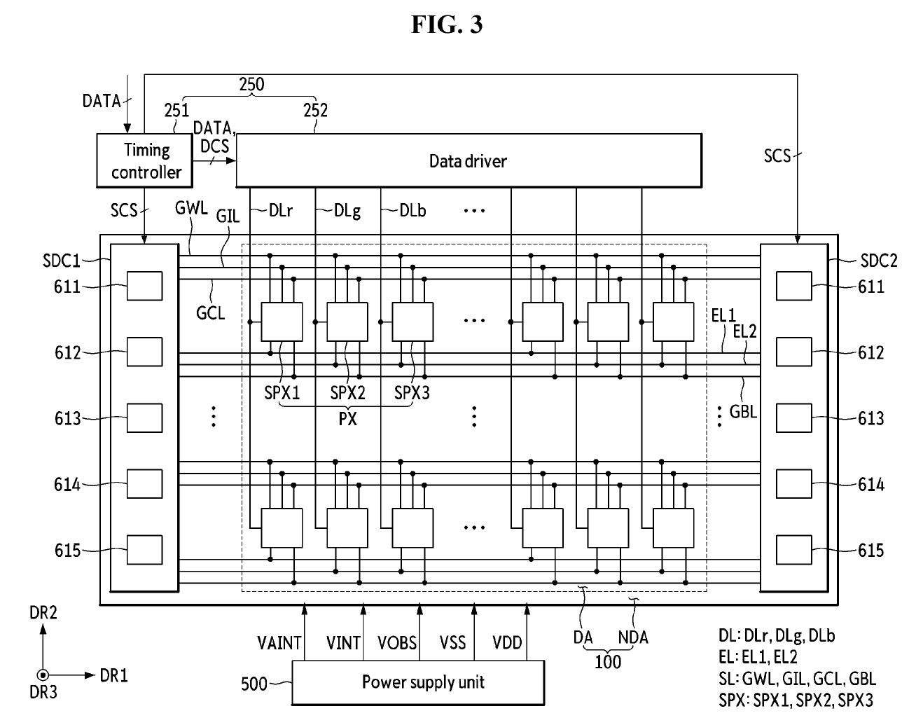

FIG. 3 is a block diagram of the display device 10 according to one or more embodiments.

Referring to FIG. 3, the display area DA may include pixels PX, scan lines SL, emission control lines EL, and data lines DL.

The pixels PX may be arranged along the first direction DR1 and the second direction DR2. For example, the pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged or placed along the second direction DR2. The data lines DL may extend in the second direction DR2 and may be arranged or placed along the first direction DR1. The scan lines SL may include write scan lines GWL, initialization scan lines GIL, control scan lines GCL, and bias scan lines GBL. The configuration or number of scan lines SL may vary depending on the structure or driving method of the pixels PX.

Each of the pixels PX may include a plurality of subpixels SPX. For example, each of the pixels PX may include a first subpixel SPX1, a second subpixel SPX2, and a third subpixel SPX3. The first subpixel SPX1, the second subpixel SPX2, and the third subpixel SPX3 may emit light of a first color, light of a second color, and light of a third color, respectively. The light of the first color, the light of the second color, and the light of the third color may be, but are not limited to, red light (e.g., light in a red wavelength band having a main peak wavelength of about 600 to 750㎚), green light (e.g., light in a green wavelength band having a main peak wavelength of about 480 to 560㎚), and blue light (e.g., light in a blue wavelength band having a main peak wavelength of about 370 to 460㎚), respectively. In one or more embodiments, the first subpixel SPX1, the second subpixel SPX2, and the third subpixel SPX3 of each of the pixels PX may be arranged along the first direction DR1. The number, type, arrangement structure, and/or emission wavelength of the subpixels SPX included in each of the pixels PX may vary depending on embodiments.

Each of the subpixels SPX may be connected to one of the write scan lines GWL, one of the initialization scan lines GIL, one of the control scan lines GCL, one of the bias scan lines GBL, one of the emission control lines EL, and one of the data lines DL. In the description of embodiments, the term “connection” may mean “physical connection” and/or “electrical connection.”

Each of the subpixels SPX may receive a data voltage of a data line DL according to a write scan signal of a write scan line GWL and may emit light from a light emitting element according to the data voltage. The subpixels SPX included in each pixel PX may be connected to different data lines DL. For example, the first subpixel SPX1, the second subpixel SPX2, and the third subpixel SPX3 may be connected to a first data line DLr, a second data line DLg, and a third data line DLb, respectively. Accordingly, the emission luminance of each of the first subpixel SPX1, the second subpixel SPX2, and the third subpixel SPX3 may be individually controlled.

In one or more embodiments, each of the pixels PX may be connected to two or more emission control lines EL, and emission periods (or on-duty ratios) of at least two of the subpixels SPX included in each pixel PX may be independently and/or individually controlled by different emission control signals supplied to different emission control lines EL. For example, in each horizontal line (e.g., each pixel row) of the display area DA, a first emission control line EL1 and a second emission control line EL2, which are connected to different subpixels SPX from among subpixels SPX included in pixels PX located in the corresponding horizontal line (e.g., the corresponding pixel row), may be located. For example, the first emission control line EL1 may be connected to first subpixels SPX1 of pixels PX located in a corresponding horizontal line (e.g., a corresponding pixel row), and the second emission control line EL2 may be connected to second subpixels SPX2 and third subpixels SPX3 included in the pixels PX of the corresponding horizontal line (e.g., the corresponding pixel row).

The first subpixel SPX1 may emit light during a first emission period in response to a first emission control signal supplied through the first emission control line EL1. The first emission period may be a period during which a driving current may flow through the first subpixel SPX1 in response to the first emission control signal. The second subpixel SPX2 and the third subpixel SPX3 may emit light during a second emission period in response to a second emission control signal supplied through the second emission control line EL2. The second emission period may be a period during which a driving current may flow through the second subpixel SPX2 and the third subpixel SPX3 in response to the second emission control signal. The first emission period and the second emission period may be independently or individually controlled and may or may not temporally overlap each other.

In one or more embodiments, the duration of the first emission period and the duration of the second emission period may be different. For example, the duration of the first emission period may correspond to an on-duty ratio adjusted to allow the first subpixel SPX1 to emit light with a target luminance according to a driving current optimized for the luminous efficiency of the first subpixel SPX1 (e.g., a driving current within a range in which a light emitting element of the first subpixel SPX1 exhibits optimal consumption efficiency). The duration of the second emission period may correspond to an on-duty ratio adjusted to allow the second subpixel SPX2 and the third subpixel SPX3 to emit light with a target luminance according to a driving current optimized for the luminous efficiency of the second subpixel SPX2 and the third subpixel SPX3 (e.g., a driving current within a range in which light emitting elements of the second subpixel SPX2 and the third subpixel SPX3 exhibit optimal consumption efficiency). In this case, emission control signal output units 615 included in the first scan driver SDC1 and the second scan driver SDC2 may output emission control signals having different pulse widths to the first emission control line EL1 and the second emission control line EL2.

The first scan driver SDC1, the second scan driver SDC2, and the display driver 250 may be located in the non-display area NDA.

Each of the first scan driver SDC1 and the second scan driver SDC2 may be electrically connected to the pixels PX through the scan lines SL and the emission control lines EL. For example, each of the first scan driver SDC1 and the second scan driver SDC2 may be electrically connected to pixel circuits of the subpixels SPX included in each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit 611, an initialization scan signal output unit 612, a control scan signal output unit 613, a bias scan signal output unit 614, and an emission control signal output unit 615. Each of the write scan signal output unit 611, the initialization scan signal output unit 612, the control scan signal output unit 613, the bias scan signal output unit 614, and the emission control signal output unit 615 may receive a scan timing control signal SCS from a timing controller 251.

The write scan signal output unit 611 may generate write scan signals according to the scan timing control signal SCS and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The control scan signal output unit 613 may generate control scan signals according to the scan timing control signal SCS and sequentially output the control scan signals to the control scan lines GCL.

The bias scan signal output unit 614 may generate bias scan signals according to the scan timing control signal SCS and sequentially output the bias scan signals to the bias scan lines GBL.

The emission control signal output unit 615 may generate emission control signals according to the scan timing control signal SCS and sequentially output the emission control signals to the emission control lines EL. When the subpixels SPX of each horizontal line are divided and connected to a plurality of emission control lines EL (e.g., the first emission control line EL1 and the second emission control line EL2 of each horizontal line), the emission control signal output unit 615 may output the emission control signals to the emission control lines EL, respectively, in each horizontal period.

The display driver 250 may include the timing controller 251 and a data driver 252.

The data driver 252 may be electrically connected to the pixels PX through the data lines DL. For example, the data driver 252 may be electrically connected to the pixel circuits of the subpixels SPX included in each pixel PX through the first data line DLr, the second data line DLg, and the third data line DLb.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by a write scan signal of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate panel driving voltages according to a power supply voltage supplied from the outside. For example, the power supply unit 500 may generate a first driving voltage VDD, a second driving voltage VSS, a third driving voltage VINT, a fourth driving voltage VAINT, and a fifth driving voltage VOBS and supply them to the display panel 100. The first driving voltage VDD, the second driving voltage VSS, the third driving voltage VINT, the fourth driving voltage VAINT, and the fifth driving voltage VOBS may be supplied to the subpixels SPX through respective power lines connected between the power supply unit 500 and the subpixels SPX and may be used to drive the subpixels SPX. The number and/or type of panel driving voltages output from the power supply unit 500 may vary depending on the structure or operation method of the subpixels SPX.

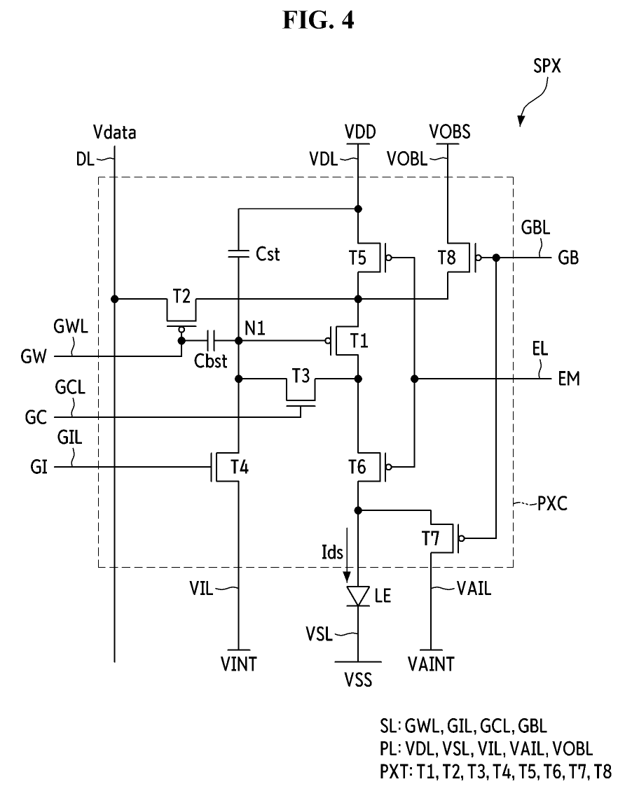

FIG. 4 is an equivalent circuit diagram of a subpixel SPX according to one or more embodiments. For example, FIG. 4 may be an equivalent circuit diagram of one of the subpixels SPX of FIGS. 2 and 3. In one or more embodiments, circuit configurations of a plurality of subpixels SPX that forms each pixel PX may be substantially identical to each other. For example, equivalent circuit diagrams of the first subpixel SPX1, the second subpixel SPX2, and the third subpixel SPX3 of FIG. 3 may be identical to each other.

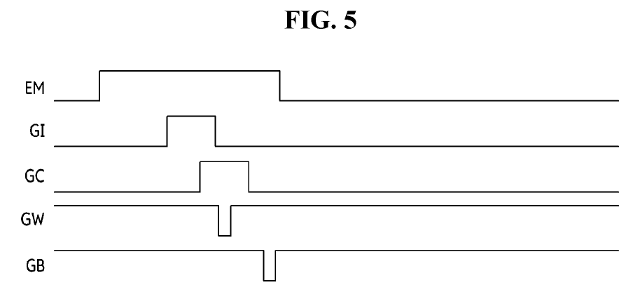

FIG. 5 is a waveform diagram illustrating driving signals of the subpixel SPX according to the embodiment. For example, FIG. 5 shows a write scan signal GW, a control scan signal GC, an initialization scan signal GI, a bias scan signal GB, and an emission control signal EM supplied to scan lines SL and an emission control line EL of FIG. 4.

Referring to FIGS. 4 and 5 in addition to FIGS. 1 through 3, each of the subpixels SPX may include a pixel circuit PXC and a light emitting element LE electrically connected to the pixel circuit PXC.

A subpixel SPX may be connected to at least one scan driver through scan lines SL and an emission control line EL. For example, the subpixel SPX may be connected to the first scan driver SDC1 and the second scan driver SDC2 through a write scan line GWL, an initialization scan line GIL, a control scan line GCL, a bias scan line GBL, and the emission control line EL. The first scan driver SDC1 and the second scan driver SDC2 may output a write scan signal GW, an initialization scan signal GI, a control scan signal GC, a bias scan signal GB, and an emission control signal EM to the write scan line GWL, the initialization scan line GIL, the control scan line GCL, the bias scan line GBL, and the emission control line EL, respectively.

When the subpixel SPX is the first subpixel SPX1, it may be connected to the first emission control line EL1 located in a corresponding horizontal line (e.g., a corresponding pixel row) and may be supplied with an emission control signal EM (also referred to as a “first emission control signal”) from the first emission control line EL1. When the subpixel SPX is the second subpixel SPX2 or the third subpixel SPX3, it may be connected to the second emission control line EL2 located in a corresponding horizontal line (e.g., a corresponding pixel row) and may be supplied with an emission control signal EM (also referred to as a “second emission control signal”) from the second emission control line EL2.

The subpixel SPX may be connected to the data driver 252 through a data line DL. The data driver 252 may output a data voltage Vdata, which corresponds to image data of each frame, to the data line DL.

When the subpixel SPX is the first subpixel SPX1, it may be connected to the first data line DLr located in a corresponding pixel column. When the subpixel SPX is the second subpixel SPX2, it may be connected to the second data line DLg located in a corresponding pixel column. When the subpixel SPX is the third subpixel SPX3, it may be connected to the third data line DLb located in a corresponding pixel column.

The subpixel SPX may be connected to the power supply unit 500 through power lines PL. For example, the subpixel SPX may be connected to the power supply unit 500 through a first power line VDL, a second power line VSL, a third power line VIL, a fourth power line VAIL, and a fifth power line VOBL. The power supply unit 500 may supply a first driving voltage VDD, a second driving voltage VSS, a third driving voltage VINT, a fourth driving voltage VAINT, and a fifth driving voltage VOBS to the first power line VDL, the second power line VSL, the third power line VIL, the fourth power line VAIL, and the fifth power line VOBL, respectively. In one or more embodiments, the first driving voltage VDD, the second driving voltage VSS, the third driving voltage VINT, the fourth driving voltage VAINT, and the fifth driving voltage VOBS may be a high-potential pixel voltage (e.g., an anode voltage), a low-potential pixel voltage (e.g., a cathode voltage or a common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals supplied to the subpixel SPX (e.g., the write scan signal GW, the initialization scan signal GI, the control scan signal GC, the bias scan signal GB, the emission control signal EM and the data voltage Vdata). The emission timing and luminance of the light emitting element LE may be controlled by the pixel circuit PXC.

The pixel circuit PXC may include pixel transistors PXT and a storage capacitor Cst. In one or more embodiments, the pixel circuit PXC may further include a boosting capacitor Cbst.

In one or more embodiments, the pixel transistors PXT may include first through eighth transistors T1 through T8. The first transistor T1 may be a driving transistor of the subpixel SPX. The second through eighth transistors T2 through T8 may be switching transistors of the subpixel SPX.

In one or more embodiments, the subpixel SPX may include heterogeneous pixel transistors PXT. For example, the first, second, fifth, sixth, seventh, and eighth transistors T1, T2, T5, T6, T7, and T8 may be P-type transistors (e.g., P-type polycrystalline silicon transistors that include respective active layers including polycrystalline silicon), and the third and fourth transistors T3 and T4 may be N-type transistors (e.g., N-type oxide transistors that include respective active layers including oxide semiconductor). In one or more embodiments, the active layers of the P-type transistors (e.g., the active layers including polycrystalline silicon) and the active layers of the N-type transistors (the active layers including oxide semiconductor) may be located in different layers within the display panel 100 (e.g., within a backplane layer of the display panel 100).

The first transistor T1 may be connected between the fifth transistor T5 and the sixth transistor T6. The first transistor T1 may be connected to the first power line VDL via the fifth transistor T5 and may be connected to the light emitting element LE via the sixth transistor T6. A gate electrode of the first transistor T1 may be connected to a first node N1. The first transistor T1 may control the driving current Ids, which flows through the subpixel SPX, according to the voltage of the first node N1 applied to the gate electrode (e.g., a voltage corresponding to the data voltage Vdata) of the first transistor T1.

The second transistor T2 may be connected between the data line DL and a first electrode of the first transistor T1 (e.g., a source electrode of the first transistor T1, which is connected to the fifth transistor T5). A gate electrode of the second transistor T2 may be connected to the write scan line GWL. The second transistor T2 may be turned on by the write scan signal GW of a gate-on voltage supplied from the write scan line GWL (e.g., a low-level voltage at which the second transistor T2 is turned on). When the second transistor T2 is turned on, the data voltage Vdata supplied from the data line DL may be transmitted to the first electrode (e.g., the source electrode) of the first transistor T1.

The third transistor T3 may be connected between a second electrode of the first transistor T1 (e.g., a drain electrode of the first transistor T1 which is connected to the sixth transistor T6) and the first node N1. A gate electrode of the third transistor T3 may be connected to the control scan line GCL. The third transistor T3 may be turned on by the control scan signal GC of a gate-on voltage supplied from the control scan line GCL (e.g., a high-level voltage at which the third transistor T3 is turned on) to connect the gate electrode and the second electrode of the first transistor T1. When the third transistor T3 is turned on, the first transistor T1 may operate as a diode (e.g., the first transistor is diode-connected), and a voltage corresponding to the data voltage Vdata may be applied to the first node N1.

The fourth transistor T4 may be connected between the first node N1 and the third power line VIL. A gate electrode of the fourth transistor T4 may be connected to the initialization scan line GIL. The fourth transistor T4 may be turned on by the initialization scan signal GI of a gate-on voltage supplied from the initialization scan line GIL (e.g., a high-level voltage at which the fourth transistor T4 is turned on) to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. A gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage supplied from the emission control line EL (e.g., a low-level voltage at which the fifth transistor T5 is turned on) to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light emitting element LE. A gate electrode of the sixth transistor T6 may be connected to the emission control line EL. The sixth transistor T6 may be turned on by the emission control signal EM of a gate-on voltage supplied from the emission control line EL (e.g., a low-level voltage at which the sixth transistor T6 is turned on) to connect the second electrode of the first transistor T1 to the light emitting element LE.

The seventh transistor T7 may be connected between a first electrode of the light emitting element LE (e.g., an anode connected to the sixth transistor T6) and the fourth power line VAIL. A gate electrode of the seventh transistor T7 may be connected to the bias scan line GBL. The seventh transistor T7 may be turned on by the bias scan signal GB of a gate-on voltage supplied from the bias scan line GBL (e.g., a low-level voltage at which the seventh transistor T7 is turned on) to connect the first electrode of the light emitting element LE to the fourth power line VAIL. When the seventh transistor T7 is turned on, the voltage of the first electrode of the light emitting element LE may be initialized to the fourth driving voltage VAINT of the fourth power line VAIL.

The eighth transistor T8 may be connected between the fifth power line VOBL and the first electrode of the first transistor T1. A gate electrode of the eighth transistor T8 may be connected to the bias scan line GBL. The eighth transistor T8 may be turned on by the bias scan signal GB of a gate-on voltage supplied from the bias scan line GBL to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In one or more embodiments, the fifth driving voltage VOBS may be a bias voltage having a voltage level suitable for compensating for hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by a coupling action of the boosting capacitor Cbst, thereby stabilizing the operation of the first transistor T1. The boosting capacitor Cbst may be formed by parasitic capacitance formed between the first node N1 and the write scan line GWL or may be designed separately.

In each frame period, the subpixel SPX may emit light during a period corresponding to an on-duty ratio and may not emit light during the remaining period. An emission period and a non-emission period of the subpixel SPX may be controlled by the emission control signal EM.

A period during which the fifth transistor T5 and the sixth transistor T6 are turned off (e.g., a period during which a high-level emission control signal EM is supplied to the subpixel SPX) may be the non-emission period of the subpixel SPX. The non-emission period of the subpixel SPX may include an initialization period for initializing the voltage of a specific node (e.g., the first node N1) of the subpixel SPX and a data writing and storage period for charging the storage capacitor Cst with a voltage corresponding to the data voltage Vdata. In one or more embodiments, the initialization scan signal GI, the control scan signal GC, the write scan signal GW, and the bias scan signal GB of a gate-on voltage may be supplied during the non-emission period of the subpixel SPX. In one or more embodiments, the initialization scan signal GI, the control scan signal GC, and the bias scan signal GB of a gate-on voltage may be sequentially supplied during the non-emission period of the subpixel SPX. Periods during which the initialization scan signal GI and the control scan signal GC of a gate-on voltage are supplied may overlap, but the present disclosure is not limited to this case. The write scan signal GW of a gate-on voltage may be supplied during a period in which the control scan signal GC of a gate-on voltage is supplied.

A period during which the fifth transistor T5 and the sixth transistor T6 are turned on (e.g., a period during which a low-level emission control signal EM is supplied to the subpixel SPX) may be the emission period of the subpixel SPX. During the emission period of the subpixel SPX, the first transistor T1 may supply the driving current Ids, which corresponds to the voltage of the first node N1, to the light emitting element LE.

The light emitting element LE may be connected between the pixel circuit PXC and the second power line VSL. For example, the first electrode (e.g., an anode or a pixel electrode) of the light emitting element LE may be connected to a node between the sixth transistor T6 and the seventh transistor T7, and a second electrode (e.g., a cathode or a common electrode) of the light emitting element LE may be connected to the second power line VSL. The light emitting element LE may emit light in response to the driving current Ids supplied from the pixel circuit PXC.

In one or more embodiments, the subpixel SPX may include a single light emitting element LE, but the present disclosure is not limited to this case. For example, the subpixel SPX may include at least two light emitting elements LE. The at least two light emitting elements LE may be connected in a series, parallel, or series-parallel structure between the pixel circuit PXC and the second power line VSL.

In one or more embodiments, the light emitting element LE may be a micro-LED including an inorganic compound such as a nitride-based and/or phosphide-based semiconductor material, but the present disclosure is not limited to this case. For example, the light emitting element LE may also be an organic light emitting element, a quantum dot light emitting element, or other types of light emitting elements. In addition, the size or shape of the light emitting element LE may vary depending on embodiments.

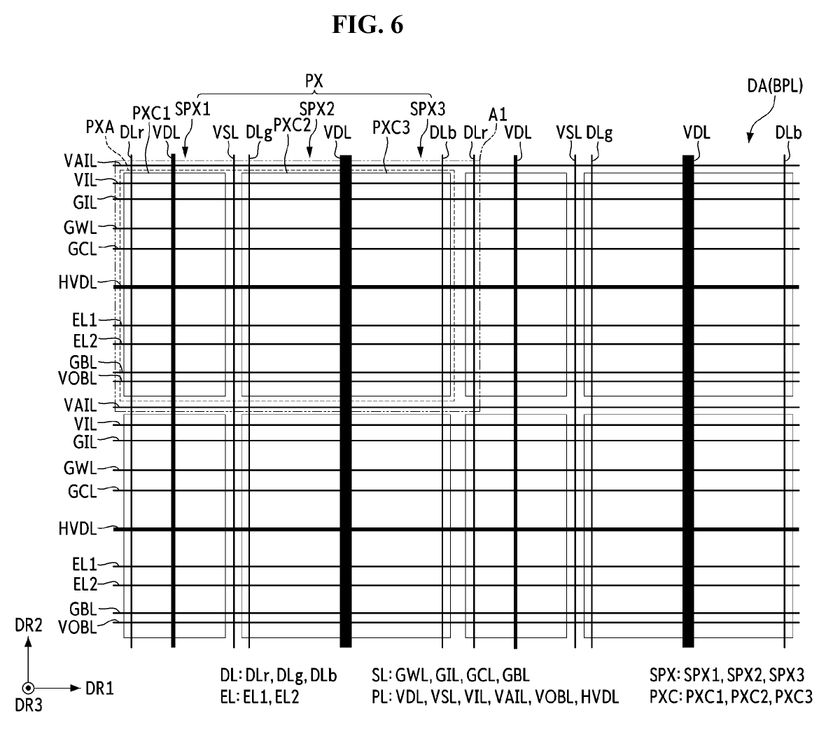

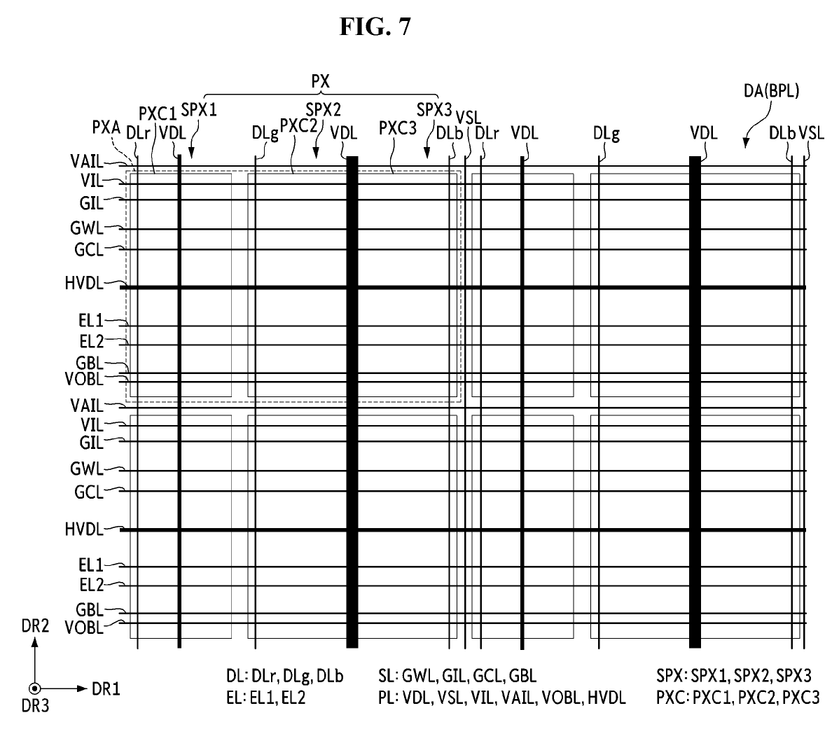

FIG. 6 is a plan view illustrating pixel circuits, signal lines, and power lines located in a backplane layer of a display panel according to one or more embodiments. FIG. 7 is a plan view illustrating pixel circuits, signal lines, and power lines located in a backplane layer of a display panel according to one or more embodiments.

For example, FIGS. 6 and 7 show a rough arrangement of pixel circuits PXC, signal lines, and power lines PL in a backplane layer BPL of a display panel 100 in a portion of a display area DA, which includes four pixel areas PXA in which four pixels PX are arranged along the first direction DR1 and the second direction DR2. FIGS. 6 and 7 show different embodiments in relation to a second power line VSL. For convenience, in FIGS. 6 and 7, only subpixels SPX located in one pixel area PXA and a pixel PX including the subpixels SPX are indicated by reference numerals.

Referring to FIGS. 6 and 7 in addition to FIGS. 1 through 5, in each pixel area PXA of the display area DA, a plurality of pixel circuits PXC included in a pixel PX in the corresponding pixel area PXA may be located. For example, in each pixel area PXA, a pixel circuit PXC (hereinafter, referred to as a “first pixel circuit PXC1”) of a first subpixel SPX1, a pixel circuit PXC (hereinafter, referred to as a “second pixel circuit PXC2”) of a second subpixel SPX2, and a pixel circuit PXC (hereinafter, referred to as a “third pixel circuit PXC3”) of a third subpixel SPX3 may be located.

In each pixel area PXA of the display area DA and/or its surroundings, signal lines and power lines PL, which are electrically connected to subpixels SPX in the corresponding pixel area PXA, may be located. The signal lines of the display area DA may include scan lines SL, emission control lines EL, and data lines DL. The power lines PL of the display area DA may include a first power line VDL, a second power line VSL, a third power line VIL, a fourth power line VAIL, and a fifth power line VOBL.

In one or more embodiments, the power lines PL of the display area DA may further include a horizontal power line HVDL, which is connected to the first power line VDL and extends in the first direction DR1. The first power line VDL and the horizontal power line HVDL may be electrically connected to each other inside and/or outside the display area DA.

In one or more embodiments, a plurality of first power lines VDL, which is arranged along the first direction DR1, may be located in the display area DA. For example, the first power lines VDL may be electrically connected to each other inside and/or outside the display area DA (e.g., a non-display area NDA around the display area DA) to form a single wiring in an electrical sense, which, however, may branch into a plurality of wirings in the display area DA. Each of the first power lines VDL of the display area DA may extend in the second direction DR2.

Similarly, a plurality of second power lines VSL, which is arranged along the first direction DR1, may be located in the display area DA. For example, the second power lines VSL may be electrically connected to each other inside and/or outside the display area DA to form a single wiring in an electrical sense, which, however, may branch into a plurality of wirings in the display area DA. Each of the second power lines VSL of the display area DA may extend in the second direction DR2. In one or more embodiments, at least one of the power lines other than the first power lines VDL and the second power lines VSL may also branch into a plurality of power lines, which is arranged in the display area DA along one of the first direction DR1 or the second direction DR2.

The first pixel circuit PXC1, the second pixel circuit PXC2, and the third pixel circuit PXC3 may be arranged in the display area DA along the first direction DR1. For example, the first pixel circuit PXC1, the second pixel circuit PXC2, and the third pixel circuit PXC3 may be sequentially arranged in each pixel area PXA along the first direction DR1.

In one or more embodiments, the second pixel circuit PXC2 and the third pixel circuit PXC3 of each pixel PX may share one first power line VDL. The second pixel circuit PXC2 and the third pixel circuit PXC3 may be located close to each other. For example, the second pixel circuit PXC2 and the third pixel circuit PXC3 may substantially adjoin each other at a portion where the first power line VDL is located, and a distance between the second pixel circuit PXC2 and the third pixel circuit PXC3 may be reduced or minimized. Accordingly, the first pixel circuit PXC1, the second pixel circuit PXC2, and the third pixel circuit PXC3 may be efficiently placed in the pixel area PXA allocated to each pixel PX, and the design structure and/or space utilization of the pixel area PXA may be improved.

In one or more embodiments, each of the first pixel circuit PXC1, the second pixel circuit PXC2, and the third pixel circuit PXC3 may overlap one first power line VDL. For example, two first power lines VDL may be located in each pixel area PXA. The first pixel circuit PXC1 may overlap one of the two first power lines VDL, and the second pixel circuit PXC2 and the third pixel circuit PXC3 may overlap the other first power line VDL. Accordingly, the space utilization and/or integration density of the backplane layer BPL may be improved.

In one or more embodiments, the second power lines VSL may be placed in a design space that is secured between the pixel circuits PXC by the efficient arrangement of the pixel circuits PXC. Alternatively, the design space secured between the pixel circuits PXC may be utilized as a space for placing a wiring or a conductive pattern other than the second power lines VSL or may be utilized to improve electrical stability by securing a distance between patterns located around the space.

The scan lines SL and the emission control lines EL may extend in the first direction DR1 and may be arranged or placed along the second direction DR2. In one or more embodiments, in each horizontal line in which a row of pixels PX are located, a write scan line GWL, an initialization scan line GIL, a control scan line GCL, a bias scan line GBL, a first emission control line EL1, and a second emission control line EL2, which are connected to the subpixels SPX of the corresponding horizontal line, may be located.

The positions and/or arrangement order of the write scan line GWL, the initialization scan line GIL, the control scan line GCL, the bias scan line GBL, the first emission control line EL1, and the second emission control line EL2 may vary depending on the design structure of each of the pixel circuits PXC. For example, the write scan line GWL may be located at a position corresponding to a second transistor T2 of each of the pixel circuits PXC. In an example, the write scan line GWL may overlap the second transistor T2 of each of the pixel circuits PXC or may be located around the second transistor T2. The initialization scan line GIL may be located at a position corresponding to a fourth transistor T4 of each of the pixel circuits PXC. The control scan line GCL may be located at a position corresponding to a third transistor T3 of each of the pixel circuits PXC. The bias scan line GBL may be located at a position corresponding to seventh and eighth transistors T7 and T8 of each of the pixel circuits PXC. The first emission control line EL1 and the second emission control line EL2 may be located at a position corresponding to fifth and sixth transistors T5 and T6 of each of the pixel circuits PXC. The first emission control line EL1 and the second emission control line EL2 of each horizontal line may be adjacent to each other in the second direction DR2.

The data lines DL may extend in the second direction DR2 and may be arranged or placed along the first direction DR1. In one or more embodiments, in each pixel column (or each vertical line) in which a column of pixels PX is located, a first data line DLr, a second data line DLg, and a third data line DLb, which are connected to the subpixels SPX of the corresponding pixel column, may be located.

The first data line DLr may be located at a position corresponding to the second transistor T2 of each of the first pixel circuits PXC1. For example, the first data line DLr may overlap the second transistor T2 of each of the first pixel circuits PXC1 or may be located around the second transistor T2. The second data line DLg may be located at a position corresponding to the second transistor T2 of each of the second pixel circuits PXC2. The third data line DLb may be located at a position corresponding to the second transistor T2 of each of the third pixel circuits PXC3.

In one or more embodiments, the first data line DLr, the second data line DLg, and the third data line DLb may be located at respective edges of the first pixel circuits PXC1, the second pixel circuits PXC2, and the third pixel circuits PXC3 of a corresponding pixel column, respectively. For example, the first data line DLr and the second data line DLg may be located at left edges of the first pixel circuits PXC1 and the second pixel circuits PXC2 of a corresponding pixel column, respectively. In one or more embodiments, the second data line DLg and the third data line DLb may be located at opposite positions from a first power line VDL, which is located at a boundary between the second pixel circuits PXC2 and the third pixel circuits PXC3 of a corresponding pixel column. For example, the third data line DLb may be located at right edges of the third pixel circuits PXC3 of a corresponding pixel column.

In one or more embodiments, the data lines DL of the subpixels SPX may be located around different wirings. For example, in the embodiment of FIG. 6, the first data line DLr located in each pixel column may be located between the third data line DLb of an adjacent pixel column and a first power line VDL of the corresponding pixel column (e.g., a first first power line VDL overlapping the first pixel circuits PXC1 among two first power lines VDL located in each pixel column). The second data line DLg may be located between a second power line VSL located in a corresponding pixel column and a first power line VDL (e.g., a second first power line VDL overlapping the second and third pixel circuits PXC2 and PXC3 from among the two first power lines VDL located in each pixel column). The third data line DLb may be located between a first power line VDL located in a corresponding pixel column (e.g., the second first power line VDL of each pixel column) and the first data line DLr of an adjacent pixel column. In the embodiment of FIG. 7, the first data line DLr located in each pixel column may be located between a second power line VSL and a first power line VDL (e.g., the first first power line VDL of each pixel column). The second data line DLg may be located between two first power lines VDL of a corresponding pixel column. The third data line DLb may be located between a first power line VDL (e.g., the second first power line VDL of each pixel column) and a second power line VSL.

The first power line VDL may be located in each pixel column and may extend in the second direction DR2. In one or more embodiments, a plurality of first power lines VDL may be located in each pixel column. For example, in each pixel column, one first power line VDL, which overlaps the first pixel circuits PXC1 of the corresponding pixel column and are connected to the first pixel circuits PXC1, and another first power line VDL, which overlaps the second and third pixel circuits PXC2 and PXC3 of the corresponding pixel column and are connected to the second and third pixel circuits PXC2 and PXC3, may be located. The first power line VDL may overlap a first transistor T1 and a storage capacitor Cst of each of the pixel circuits PXC. In one or more embodiments, a width of the first power line VDL connected to the second and third pixel circuits PXC2 and PXC3 may be greater than a width of the first power line VDL connected to the first pixel circuits PXC1, but the present disclosure is not limited to this case.

In the description of embodiments, the first power lines VDL spaced (e.g., spaced apart) from each other in at least a portion of the display area DA are referred to as a plurality of lines. However, lines to which the same voltage or signal is transmitted may be considered as a single wiring. For example, the first power lines VDL arranged along the first direction DR1 in FIGS. 6 and 7 may be electrically connected to each other to form a substantially single power line. For example, the first power lines VDL illustrated in FIGS. 6 and 7 may be substantially portions branching from a single power line and may be different portions of the single power line.

The horizontal power line HVDL may cross the first power lines VDL and may be located at a position corresponding to the storage capacitor Cst of each of the pixel circuits PXC. For example, the horizontal power line HVDL may be located in each horizontal line and may extend in the first direction DR1. In one or more embodiments, the horizontal power line HVDL may be integrally formed with one electrode (e.g., an electrode connected to the first power line VDL in FIG. 4) of each of the storage capacitors Cst included in the pixel circuits PXC located in a corresponding horizontal line.

The second power line VSL may extend in the second direction DR2. In one or more embodiments, a plurality of second power lines VSL may be located in each pixel column or between two adjacent pixel columns in the display area DA. The second power lines VSL may be arranged or placed along the first direction DR1.

Each of the second power lines VSL may be located between the first pixel circuit PXC1 and the second and third pixel circuits PXC2 and PXC3. For example, each of the second power lines VSL may be located between the first pixel circuit PXC1 and the second pixel circuit PXC2 in each pixel PX as illustrated in FIG. 6 or may be located between the pixel circuits PXC of two pixels PX adjacent to each other in the first direction DR1 (e.g., between the third pixel circuit PXC3 of a pixel PX located on the left and the first pixel circuit PXC1 of a pixel PX located on the right) as illustrated in FIG. 7. For example, each of the second power lines VSL may be located between the first power line VDL, which is located in an area where the first pixel circuit PXC1 is located, and the second data line DLg as illustrated in FIG. 6 or may be located between the third data line DLb and the first data line DLr, which are adjacent to each other in the first direction DR1, as illustrated in FIG. 7.

In one or more embodiments, the second power lines VSL may not intersect the data lines DL and the first power lines VDL at least in the display area DA and may be located in the same layer as the data lines DL and/or the first power lines VDL. For example, an uppermost conductive layer from among conductive layers included in the backplane layer BPL of the display panel 100 may include the data lines DL, the first power lines VDL, and the second power lines VSL spaced (e.g., spaced apart) from each other in the first direction DR1.

In the description of embodiments, the second power lines VSL spaced (e.g., spaced apart) from each other in the display area DA are referred to as a plurality of lines. However, the second power lines VSL may be electrically connected to each other to form a substantially single power line. For example, the second power lines VSL illustrated in FIGS. 6 and 7 may be substantially portions branching from a single power line and may be different portions of the single power line.

The second power lines VSL may be electrically connected to a common electrode located on the backplane layer BPL inside and/or outside the display area DA. The common electrode may be located at least in the display area DA. For example, the common electrode may be located in the display area DA and may also be located in a portion of the non-display area NDA located around the display area DA. The common electrode may be electrically connected to light emitting elements LE in the display area DA and may be electrically connected to the second power lines VSL in the display area DA and/or the non-display area NDA.

According to the embodiments of FIGS. 6 and 7, because the second power lines VSL are located between the pixel circuits PXC, a drop in a second driving voltage VSS transmitted to the common electrode CE and the light emitting elements LE may be reduced or minimized. For example, the second power lines VSL may be formed together with the first power lines VDL, etc. in the backplane layer BPL of the display panel 100 using a low-resistance material having low surface resistance. Accordingly, the drop in the second driving voltage VSS applied to the pixels PX through the second power lines VSL may be reduced or minimized.

The third power line VIL may be located in each horizontal line (e.g., each pixel row) and may extend in the first direction DR1. The third power line VIL may be located at a position corresponding to the fourth transistor T4 of each of the pixel circuits PXC.

The fourth power line VAIL may be located in each horizontal line and may extend in the first direction DR1. The fourth power line VAIL may be located at a position corresponding to the seventh transistor T7 of each of the pixel circuits PXC.

The fifth power line VOBL may be located in each horizontal line and may extend in the first direction DR1. The fifth power line VOBL may be located at a position corresponding to the eighth transistor T8 of each of the pixel circuits PXC.

Although each of the signal lines and the power lines PL extends straight along the first direction DR1 or the second direction DR2 in the embodiments of FIGS. 6 and 7, the present disclosure is not limited to this case. For example, FIGS. 6 and 7 illustrate the overall shape, position, extension direction, and arrangement direction of each of the signal lines and the power lines PL. However, the shape, position, arrangement direction, and/or size of each of the signal lines, and the power lines PL may be adjusted or changed in consideration of circuit density, minimization of interference between circuits, defect avoidance, and/or arrangement shape of the subpixels SPX. For example, each of the signal lines and the power lines PL may extend entirely or substantially along the first direction DR1 or the second direction DR2, but at least some of the signal lines and the power lines PL may also be partially bent or curved.

In addition, although the second power lines VSL do not overlap the pixel circuits PXC in the embodiments of FIGS. 6 and 7, the present disclosure is not limited to this case. For example, a portion of each of the second power lines VSL may overlap the pixel circuits PXC.

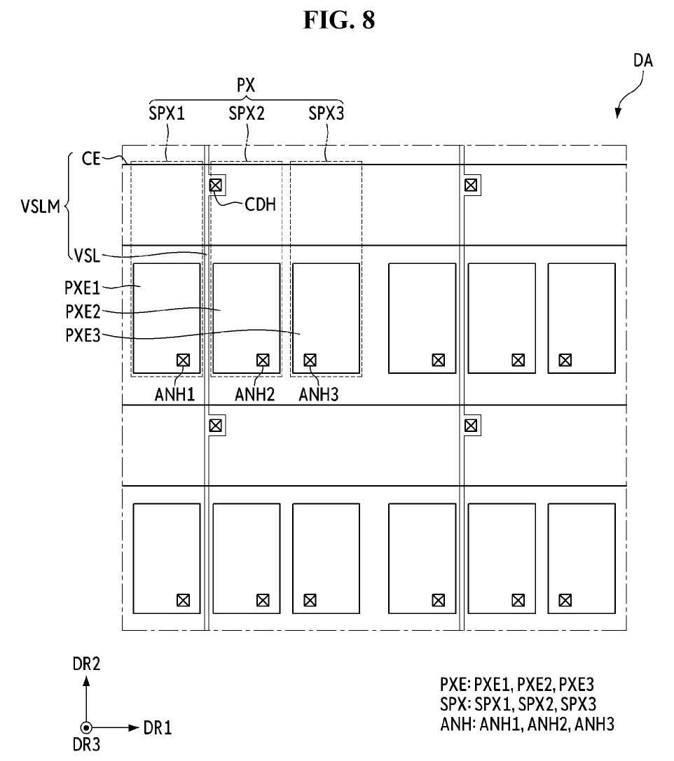

FIG. 8 is a plan view illustrating second power lines, pixel electrodes, and common electrodes located in a display area of a display panel according to one or more embodiments. For example, FIG. 8 shows a rough arrangement structure of second power lines VSL in a backplane layer BPL of a display panel 100 and pixel electrodes PXE and common electrodes CE on the backplane layer BPL.

Referring to FIG. 8 in addition to FIGS. 1 through 7, pixel electrodes PXE and a common electrode CE of each of pixels PX may be located in a display area DA. In addition, second power lines VSL, which are electrically connected to the common electrode CE, may be located in the display area DA.

Each of the pixels PX may include a plurality of pixel electrodes PXE and a common electrode CE. For example, each of the pixels PX may include a first pixel electrode PXE1, a second pixel electrode PXE2, a third pixel electrode PXE3, and a common electrode CE. Each of the pixels PX may further include a plurality of light emitting elements LE electrically connected between the pixel electrodes PXE and the common electrode CE. The detailed structure of each of the pixels PX will be described later.

The first pixel electrode PXE1 may be a pixel electrode PXE of a first subpixel SPX1. The first pixel electrode PXE1 may be located on a first pixel circuit PXC1 and may be electrically connected to the first pixel circuit PXC1. For example, the first pixel electrode PXE1 may be located in a light emitting element layer on the backplane layer BPL and may be electrically connected to the first pixel circuit PXC1 through a first anode contact hole ANH1.

The second pixel electrode PXE2 may be a pixel electrode PXE of a second subpixel SPX2. The second pixel electrode PXE2 may be located on a second pixel circuit PXC2 and may be electrically connected to the second pixel circuit PXC2. For example, the second pixel electrode PXE2 may be located in the light emitting element layer on the backplane layer BPL and may be electrically connected to the second pixel circuit PXC2 through a second anode contact hole ANH2.

The third pixel electrode PXE3 may be a pixel electrode PXE of a third subpixel SPX3. The third pixel electrode PXE3 may be located on a third pixel circuit PXC3 and may be electrically connected to the third pixel circuit PXC3. For example, the third pixel electrode PXE3 may be located in the light emitting element layer on the backplane layer BPL and may be electrically connected to the third pixel circuit PXC3 through a third anode contact hole ANH3.

The common electrode CE may be located around the first pixel electrode PXE1, the second pixel electrode PXE2, and the third pixel electrode PXE3 and may be spaced (e.g., spaced apart) from the first pixel electrode PXE1, the second pixel electrode PXE2, and the third pixel electrode PXE3. In one or more embodiments, the common electrode CE may be located in (e.g., at) the same layer as the pixel electrodes PXE. For example, the common electrode CE, the first pixel electrode PXE1, the second pixel electrode PXE2, and the third pixel electrode PXE3 may be located in (e.g., at) the same layer within the light emitting element layer on the backplane layer BPL.

In one or more embodiments, the common electrode CE may extend in one direction, and the first subpixel SPX1, the second subpixel SPX2 and the third subpixel SPX3 of each pixel PX may share one common electrode CE. For example, the common electrode CE may extend in the first direction DR1 in the display area DA, and pixels PX of each horizontal line, which are arranged along the first direction DR1, from among the pixels PX located in the display area DA may share one common electrode CE extending in the first direction DR1. For example, the pixels PX of each horizontal line (e.g., each pixel row) may include different portions of the common electrode CE located in the corresponding portions of the horizontal line.

In one or more embodiments, a plurality of common electrodes CE, which is arranged along the second direction DR2, may be located in the display area DA. For example, the common electrodes CE may be arranged along the second direction DR2 in the display area DA and may extend in the first direction DR1. In one or more embodiments, one common electrode CE may be located in each horizontal line (e.g., each pixel row) in the display area DA, and the common electrodes CE of pixels PX arranged along the second direction DR2 (e.g., pixels PX located in different horizontal lines (e.g., pixel rows) in the display area DA) from among the pixels PX located in the display area DA may be arranged along the second direction DR2.

In one or more embodiments, the common electrode CE of each pixel PX may face the first pixel electrode PXE1, the second pixel electrode PXE2, and the third pixel electrode PXE3 of the corresponding pixel PX. For example, in each pixel PX, the first pixel electrode PXE1, the second pixel electrode PXE2, and the third pixel electrode PXE3 may be sequentially arranged along the first direction DR1, and the common electrode CE may face the first pixel electrode PXE1, the second pixel electrode PXE2, and the third pixel electrode PXE3 in the second direction DR2.

The common electrodes CE may be located on the second power lines VSL. The common electrodes CE and the second power lines VSL may cross each other in the display area DA. The common electrodes CE and the second power lines VSL may be electrically connected to each other in the display area DA and/or around the display area DA (e.g., in a non-display area NDA immediately adjacent to the display area DA). A mesh-shaped power line VSLM including the common electrodes CE and the second power lines VSL, may be located in the display area DA.

In one or more embodiments, the common electrodes CE and the second power lines VSL may be electrically connected to each other in the display area DA. For example, the common electrodes CE and the second power lines VSL may be electrically connected to each other through a plurality of cathode contact holes CDH in the display area DA. Each of the cathode contact holes CDH may be formed to penetrate an insulating layer located between the common electrodes CE and the second power lines VSL, thereby exposing a portion of each of the second power lines VSL. In one or more embodiments, one cathode contact hole CDH may be formed in each pixel PX. However, the number or spacing of the cathode contact holes CDH located in the display area DA may vary depending on embodiments.

In one or more embodiments, the display device 10 may not include the cathode contact holes CDH of FIG. 8. In this case, the common electrodes CE and the second power lines VSL may be electrically connected to each other through direct or indirect contact in the non-display area NDA located around the display area DA. For example, the common electrodes CE and the second power lines VSL may extend from the display area DA to the non-display area NDA and may be electrically connected to each other through at least one contact hole and/or a power bus line located in the non-display area NDA.

According to the above-described embodiments, because the common electrodes CE and the second power lines VSL, which cross each other in the display area DA, are electrically connected to each other, the mesh-shaped power line VSLM may be formed. Accordingly, the resistance of wiring (e.g., wiring including the mesh-shaped power line VSLM), which transmits the second driving voltage VSS, may be reduced, thereby reducing a drop in the second driving voltage VSS transmitted to the pixels PX. According to one or more embodiments, the power consumption of the display device 10 and an electronic device including the same can be reduced.

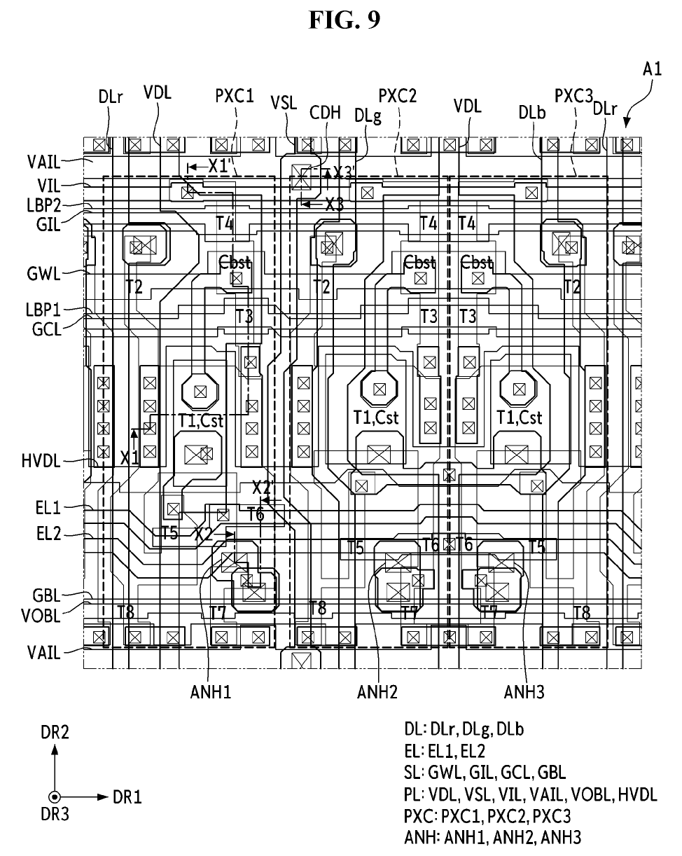

FIG. 9 is a layout view of a backplane layer of a display panel according to one or more embodiments. For example, FIG. 9 shows an embodiment of a layout of a backplane layer BPL in a portion of a display area DA which corresponds to area A1 of FIG. 6. The area A1 of FIGS. 6 and 9 may include one pixel area PXA, which includes a first pixel circuit PXC1, a second pixel circuit PXC2, and a third pixel circuit PXC3, and an area around the pixel area PXA.

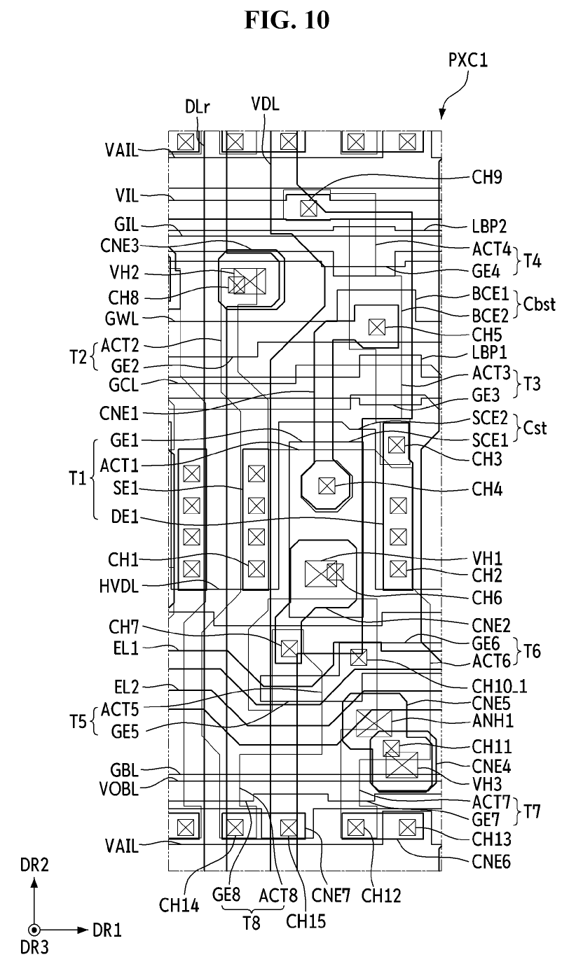

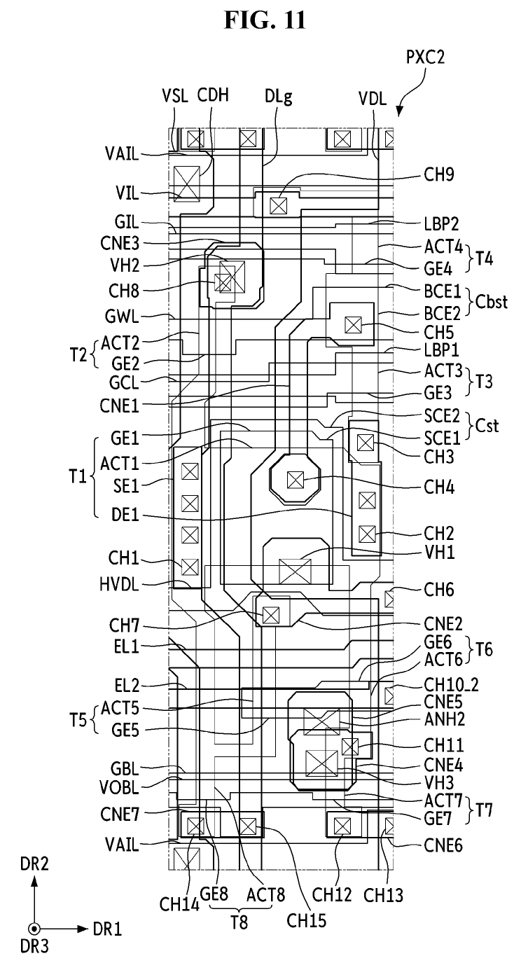

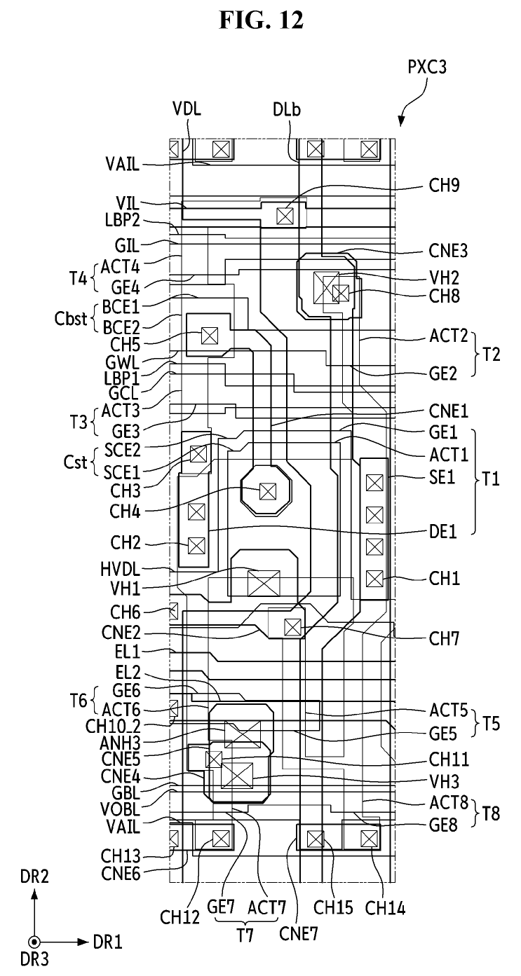

FIG. 10 is a detailed layout view of the first pixel circuit PXC1 of FIG. 9. FIG. 11 is a detailed layout view of the second pixel circuit PXC2 of FIG. 9. FIG. 12 is a detailed layout view of the third pixel circuit PXC3 of FIG. 9.

Referring to FIGS. 9 through 12 in addition to FIGS. 3 through 8, each of the first pixel circuit PXC1, the second pixel circuit PXC2, and the third pixel circuit PXC3 may include first through eighth transistors T1 through T8, a storage capacitor Cst, and a boosting capacitor Cbst.

The first transistor T1 may include a first active layer ACT1 and a first gate electrode GE1. The first gate electrode GE1 may overlap a portion of the first active layer ACT1. In one or more embodiments, the first transistor T1 may further include a source electrode SE1 and a drain electrode DE1. The source electrode SE1 and the drain electrode DE1 may be electrically connected to different portions of the first active layer ACT1, for example, a source region and a drain region of the first active layer ACT1, respectively.

The first active layer ACT1 may include a channel region that overlaps the first gate electrode GE1 and a source region and a drain region, which are located on opposite sides of the channel region. In FIGS. 9 through 12, the source region and the drain region included in the active layer of each of the transistors, as well as the first active layer ACT1, are not distinguished from each other. However, depending on the type (e.g., P-type or N-type) of each of the transistors and the voltage applied to both ends of each of the transistors, a portion of the active layer included in each of the transistors may be a source region, and another portion may be a drain region.

The source region of the first active layer ACT1 may be electrically connected to second, fifth and eighth active layers ACT2, ACT5, and ACT8 included in the second, fifth and eighth transistors T2, T5, and T8. For example, the first active layer ACT1, the second active layer ACT2, the fifth active layer ACT5, and the eighth active layer ACT8 may be integrally formed, and the source region of the first active layer ACT1 may be electrically connected to a portion (e.g., a drain region) of each of the second, fifth, and eighth active layers ACT2, ACT5, and ACT8. The drain region of the first active layer ACT1 may be electrically connected to third and sixth active layers ACT3 and ACT6 included in the third and sixth transistors T3 and T6. For example, the drain region of the first active layer ACT1 may be electrically connected to the drain electrode DE1 through at least one second contact hole CH2 and may be electrically connected to a portion (e.g., a drain region) of the third active layer ACT3 through the drain electrode DE1. The first active layer ACT1 may also be integrally formed with the sixth and seventh active layers ACT6 and ACT7. The drain region of the first active layer ACT1 may be electrically connected to a portion (e.g., a source region) of the sixth active layer ACT6.

The source electrode SE1 may be electrically connected to a portion of the first active layer ACT1 through at least one first contact hole CH1. For example, the source electrode SE1 may be electrically connected to the source region of the first active layer ACT1 through a plurality of first contact holes CH1.

The drain electrode DE1 may be electrically connected to another portion of the first active layer ACT1 through at least one second contact hole CH2. For example, the drain electrode DE1 may be electrically connected to the drain region of the first active layer ACT1 through a plurality of second contact holes CH2. The drain electrode DE1 may be electrically connected to the third transistor T3 through a third contact hole CH3. For example, the drain electrode DE1 may be electrically connected to a portion of the third active layer ACT3 (e.g., the drain region of the third active layer ACT3) through the third contact hole CH3.

The first gate electrode GE1 may be electrically connected to a first electrode SCE1 of the storage capacitor Cst. For example, the first gate electrode GE1 and the first electrode SCE1 of the storage capacitor Cst may be integrally formed and may be formed as substantially one conductive pattern. The first gate electrode GE1 may be electrically connected to a first connection electrode CNE1 through a fourth contact hole CH4 and may be electrically connected to the third and fourth transistors T3 and T4 through the first connection electrode CNE1. The first connection electrode CNE1 may be electrically connected to a portion (e.g., a source or drain region) of each of the third and fourth active layers ACT3 and ACT4, which are included in the third and fourth transistors T3 and T4, through a fifth contact hole CH5.

In one or more embodiments, the backplane layer BPL of the display panel 100 may further include a light blocking pattern located under the first active layer ACT1. For example, the backplane layer BPL may further include a bottom conductive layer (e.g., a bottom metal layer) located between a first semiconductor layer, in which the first active layer ACT1 is located, and a substrate, and the bottom conductive layer may include a bottom pattern overlapping the channel region of the first active layer ACT1. The bottom pattern may block light incident from under the first active layer ACT1 (e.g., under the backplane layer BPL) toward the channel region of the first active layer ACT1. Accordingly, the operating characteristics of the first transistor T1 may be stabilized. In addition, the bottom pattern may disperse charges that gather around the first transistor T1.

The storage capacitor Cst may include the first electrode SCE1 and a second electrode SCE2, which overlap each other. The first electrode SCE1 of the storage capacitor Cst may be integrally formed with the first gate electrode GE1. The second electrode SCE2 of the storage capacitor Cst may be integrally formed with a horizontal power line HVDL and may be electrically connected to a first power line VDL. For example, the second electrode SCE2 of the storage capacitor Cst may be electrically connected to a second connection electrode CNE2 through a sixth contact hole CH6 and may be electrically connected to the first power line VDL through the second connection electrode CNE2. The second connection electrode CNE2 may be electrically connected to the first power line VDL through a first via hole VH1 (or a contact hole). In addition, the second connection electrode CNE2 may be electrically connected to a portion (e.g., a source region) of the fifth active layer ACT5, which is included in the fifth transistor T5, through a seventh contact hole CH7.

The second transistor T2 may include the second active layer ACT2 and a second gate electrode GE2. The second gate electrode GE2 may overlap a portion of the second active layer ACT2.

The second active layer ACT2 may include a channel region that overlaps the second gate electrode GE2 and a source region and a drain region, which are located on opposite sides of the channel region. The source region of the second active layer ACT2 may be electrically connected to a data line DL. For example, the source region of the second active layer ACT2 may be electrically connected to a third connection electrode CNE3 through an eighth contact hole CH8 and may be electrically connected to a data line DL (e.g., a first data line DLr, a second data line DLg, or a third data line DLb) of each subpixel SPX through the third connection electrode CNE3. The third connection electrode CNE3 may be electrically connected to the data line DL of each subpixel SPX through a second via hole VH2 (or a contact hole). The drain region of the second active layer ACT2 may be electrically connected to the first, fifth, and eighth active layers ACT1, ACT5, and ACT8 included in the first, fifth, and eighth transistors T1, T5, and T8. For example, the drain region of the second active layer ACT2 may be electrically connected to the source region of the first active layer ACT1 and the drain region of each of the fifth and eighth active layers ACT5 and ACT8.

The second gate electrode GE2 may be electrically connected to a write scan line GWL. For example, the second gate electrode GE2 and the write scan line GWL may be integrally formed and may be formed as substantially one conductive pattern. In this case, a portion of the write scan line GWL, which overlaps the second active layer ACT2, may function as the second gate electrode GE2.

The third transistor T3 may include the third active layer ACT3 and a third gate electrode GE3. The third gate electrode GE3 may overlap a portion of the third active layer ACT3.

The third active layer ACT3 may include a channel region that overlaps the third gate electrode GE3 and a source region and a drain region, which are located on opposite sides of the channel region. The source region of the third active layer ACT3 may be electrically connected to the first gate electrode GE1 of the first transistor T1 and the fourth active layer ACT4 of the fourth transistor T4. For example, the source region of the third active layer ACT3 may be electrically connected to the first connection electrode CNE1 through the fifth contact hole CH5 and may be electrically connected to the first gate electrode GE1 of the first transistor T1 through the first connection electrode CNE1. In addition, the third active layer ACT3 and the fourth active layer ACT4 may be integrally formed, and the source region of the third active layer ACT3 may be electrically connected to a drain region of the fourth active layer ACT4. The drain region of the third active layer ACT3 may be electrically connected to the first active layer ACT1 of the first transistor T1. For example, the drain region of the third active layer ACT3 may be connected to the drain electrode DE1 of the first transistor T1 through the third contact hole CH3 and may be electrically connected to the drain region of the first active layer ACT1 through the drain electrode DE1 of the first transistor T1.

The third gate electrode GE3 may be electrically connected to a control scan line GCL. For example, the third gate electrode GE3 and the control scan line GCL may be integrally formed and may be formed as substantially one conductive pattern. In this case, a portion of the control scan line GCL, which overlaps the third active layer ACT3, may function as the third gate electrode GE3.

In one or more embodiments, the backplane layer BPL of the display panel 100 may further include a first light blocking pattern LBP1 located under the third active layer ACT3. The first light blocking pattern LBP1 may extend in the first direction DR1 and overlap the channel region of the third active layer ACT3 and the control scan line GCL. The first light blocking pattern LBP1 may block light incident from under the third active layer ACT3 toward the channel region of the third active layer ACT3. Accordingly, the operating characteristics of the third transistor T3 can be stabilized.

The fourth transistor T4 may include the fourth active layer ACT4 and a fourth gate electrode GE4. The fourth gate electrode GE4 may overlap a portion of the fourth active layer ACT4.

The fourth active layer ACT4 may include a channel region that overlaps the fourth gate electrode GE4 and a source region and a drain region, which are located on opposite sides of the channel region. The source region of the fourth active layer ACT4 may be electrically connected to a third power line VIL. For example, the source region of the fourth active layer ACT4 may be electrically connected to the third power line VIL through a ninth contact hole CH9. In addition, the drain region of the fourth active layer ACT4 may be electrically connected to the first gate electrode GE1 of the first transistor T1 and the third active layer ACT3 of the third transistor T3. For example, the drain region of the third active layer ACT3 may be electrically connected to the first gate electrode GE1 of the first transistor T1 through the first connection electrode CNE1 and may be integrally formed with the source region of the third active layer ACT3. For example, the third active layer ACT3 and the fourth active layer ACT4 of each of the first pixel circuit PXC1, the second pixel circuit PXC2, and the third pixel circuit PXC3 may be integrated with each other to form one semiconductor pattern. In one or more embodiments, the third active layer ACT3 and the fourth active layer ACT4 may include an oxide semiconductor. Accordingly, leakage current of the subpixels SPX can be reduced or prevented.

The fourth gate electrode GE4 may be electrically connected to an initialization scan line GIL. For example, the fourth gate electrode GE4 and the initialization scan line GIL may be integrally formed and may be formed as substantially one conductive pattern. In this case, a portion of the initialization scan line GIL, which overlaps the fourth active layer ACT4, may function as the fourth gate electrode GE4.

In one or more embodiments, the backplane layer BPL of the display panel 100 may further include a second light blocking pattern LBP2 located under the fourth active layer ACT4. The second light blocking pattern LBP2 may extend in the first direction DR1 and overlap the channel region of the fourth active layer ACT4 and the initialization scan line GIL. The first light blocking pattern LBP1 and the second light blocking pattern LBP2 may be located in (e.g., at) the same layer within the backplane layer BPL, but the present disclosure is not limited to this case. The second light blocking pattern LBP2 may block light incident from under the fourth active layer ACT4 toward the channel region of the fourth active layer ACT4. Accordingly, the operating characteristics of the fourth transistor T4 can be stabilized.

In one or more embodiments, the third and fourth active layers ACT3 and ACT4 of the third and fourth transistors T3 and T4 may overlap the write scan line GWL. The boosting capacitor Cbst may be formed between the third and fourth active layers ACT3 and ACT4 and the write scan line GWL.

The boosting capacitor Cbst may include a first electrode BCE1 and a second electrode BCE2, which overlap each other. The first electrode BCE1 of the boosting capacitor Cbst may be integrally formed with the write scan line GWL. The second electrode BCE2 of the boosting capacitor Cbst may be integrally formed with a portion (e.g., the source or drain region) of each of the third and fourth active layers ACT3 and ACT4. In one or more embodiments, the capacitance of the boosting capacitor Cbst may be adjusted by controlling the size of an area where the third and fourth active layers ACT3 and ACT4 overlap the write scan line GWL. For example, the capacitance of the boosting capacitor Cbst may be increased by increasing a width of the third and fourth active layers ACT3 and ACT4 and/or the write scan line GWL in a portion where the third and fourth active layers ACT3 and ACT4 cross the write scan line GWL.

The fifth transistor T5 may include the fifth active layer ACT5 and a fifth gate electrode GE5. The fifth gate electrode GE5 may overlap a portion of the fifth active layer ACT5.

The fifth active layer ACT5 may include a channel region which overlaps the fifth gate electrode GE5 and a source region and a drain region, which are located on opposite sides of the channel region. The source region of the fifth active layer ACT5 may be electrically connected to the first power line VDL. For example, the source region of the fifth active layer ACT5 may be electrically connected to the second connection electrode CNE2 through the seventh contact hole CH7 and may be electrically connected to the first power line VDL through the second connection electrode CNE2. The drain region of the fifth active layer ACT5 may be electrically connected to the first, second, and eighth active layers ACT1, ACT2, and ACT8 included in the first, second, and eighth transistors T1, T2 and T8. For example, the drain region of the fifth active layer ACT5 may be electrically connected to the source region of the first active layer ACT1 and the drain region of each of the second and eighth active layers ACT2 and ACT8.

In one or more embodiments, the fifth active layer ACT5 may cross a first emission control line EL1 and a second emission control line EL2, which are electrically connected to the subpixels SPX of a corresponding pixel PX. For example, the fifth active layer ACT5 may have a roughly “U” or “Y” shape around the first emission control line EL1 and the second emission control line EL2 and may cross the first emission control line EL1 and the second emission control line EL2.

The fifth gate electrode GE5 may be electrically connected to any one of the emission control lines EL1 or EL2. For example, the fifth gate electrode GE5 may be electrically connected to the first emission control line EL1 or the second emission control line EL2, which is located in a corresponding horizontal line (e.g., corresponding pixel row), through a tenth contact hole CH10_1 or CH10_2. For example, the fifth gate electrode GE5 included in the first pixel circuit PXC1 may be electrically connected to the first emission control line EL1 through a tenth contact hole CH10_1 overlapping the first emission control line EL1, and the fifth gate electrode GE5 included in each of the second and third pixel circuits PXC2 and PXC3 may be electrically connected to the second emission control line EL2 through a tenth contact hole CH10_2 overlapping the second emission control line EL2.

The sixth transistor T6 may include the sixth active layer ACT6 and a sixth gate electrode GE6. The sixth gate electrode GE6 may overlap a portion of the sixth active layer ACT6.

The sixth active layer ACT6 may include a channel region that overlaps the sixth gate electrode GE6 and a source region and a drain region, which are located on opposite sides of the channel region. The source region of the sixth active layer ACT6 may be electrically connected to the first and third active layers ACT1 and ACT3 included in the first and third transistors T1 and T3. For example, the source region of the sixth active layer ACT6 may be electrically connected to the drain region of each of the first and third active layers ACT1 and ACT3. The drain region of the sixth active layer ACT6 may be electrically connected to a light emitting element LE. For example, the drain region of the sixth active layer ACT6 may be electrically connected to a fourth connection electrode CNE4 through an eleventh contact hole CH11 and may be electrically connected to a pixel electrode of each subpixel SPX through the fourth and fifth connection electrodes CNE4 and CNE5. The fourth connection electrode CNE4 may be electrically connected to the fifth connection electrode CNE5 through a third via hole VH3 (or a contact hole). The fifth connection electrode CNE5 may be electrically connected to the pixel electrode of each subpixel SPX through an anode contact hole ANH of each subpixel SPX (a cathode contact hole in the case of a display panel having a common-anode structure). For example, the fifth connection electrode CNE5 of the first pixel circuit PXC1 may be electrically connected to a first pixel electrode, which is connected to a light emitting element LE of a first subpixel SPX1, through a first anode contact hole ANH1 overlapping the first pixel circuit PXC1. The fifth connection electrode CNE5 of the second pixel circuit PXC2 may be electrically connected to a second pixel electrode, which is connected to a light emitting element LE of a second subpixel SPX2, through a second anode contact hole ANH2 overlapping the second pixel circuit PXC2. The fifth connection electrode CNE5 of the third pixel circuit PXC3 may be electrically connected to a third pixel electrode, which is connected to a light emitting element LE of a third subpixel SPX3, through a third anode contact hole ANH3 overlapping the third pixel circuit PXC3. In one or more embodiments, the sixth active layer ACT6 may cross the first emission control line EL1 and the second emission control line EL2, which are electrically connected to a corresponding pixel PX.

The sixth gate electrode GE6 may be electrically connected to any one emission control line EL. For example, the sixth gate electrode GE6 may be electrically connected to the first emission control line EL1 or the second emission control line EL2, which is located in a corresponding horizontal line (e.g., corresponding pixel row), through the tenth contact hole CH10_1 or CH10_2. For example, the sixth gate electrode GE6 included in the first pixel circuit PXC1 may be electrically connected to the first emission control line EL1 through the tenth contact hole CH10_1 overlapping the first emission control line EL1, and the sixth gate electrode GE6 included in each of the second and third pixel circuits PXC2 and PXC3 may be electrically connected to the second emission control line EL2 through the tenth contact hole CH10_2 overlapping the second emission control line EL2.

In one or more embodiments, the fifth and sixth gate electrodes GE5 and GE6 of the first pixel circuit PXC1 may be formed as one conductive pattern overlapping the first emission control line EL1 and may be electrically connected to the first emission control line EL1 through one tenth contact hole CH10_1 located between the fifth gate electrode GE5 and the sixth gate electrode GE6 of the first pixel circuit PXC1. In addition, the fifth and sixth gate electrodes GE5 and GE6 of the second and third pixel circuits PXC2 and PXC3 may be formed as one conductive pattern overlapping the second emission control line EL2 and may be electrically connected to the second emission control line EL2 through one tenth contact hole CH10_2 located between the second and third pixel circuits PXC2 and PXC3. Accordingly, the design structure of the pixel circuits PXC can be further simplified or optimized.

The seventh transistor T7 may include the seventh active layer ACT7 and a seventh gate electrode GE7. The seventh gate electrode GE7 may overlap a portion of the seventh active layer ACT7.

The seventh active layer ACT7 may include a channel region that overlaps the seventh gate electrode GE7 and a source region and a drain region, which are located on opposite sides of the channel region. The source region of the seventh active layer ACT7 may be electrically connected to the sixth active layer ACT6 and the light emitting element LE. For example, the sixth and seventh active layers ACT6 and ACT7 may be integrally formed, and the source region of the seventh active layer ACT7 may be electrically connected to the drain region of the sixth active layer ACT6. In addition, the source region of the seventh active layer ACT7 may be electrically connected to the fourth connection electrode CNE4 through the eleventh contact hole CH11 and may be electrically connected to the pixel electrode of each subpixel SPX through the fourth and fifth connection electrodes CNE4 and CNE5. The drain region of the seventh active layer ACT7 may be electrically connected to a fourth power line VAIL. For example, the drain region of the seventh active layer ACT7 may be electrically connected to the sixth connection electrode CNE6 through a twelfth contact hole CH12 and may be electrically connected to the fourth power line VAIL through the sixth connection electrode CNE6. The sixth connection electrode CNE6 may be electrically connected to the fourth power line VAIL through a thirteenth contact hole CH13.

The seventh gate electrode GE7 may be electrically connected to a bias scan line GBL. For example, the seventh gate electrode GE7 and the bias scan line GBL may be integrally formed and may be formed as substantially one conductive pattern. In this case, a portion of the bias scan line GBL, which overlaps the seventh active layer ACT7, may function as the seventh gate electrode GE7.

The eighth transistor T8 may include the eighth active layer ACT8 and an eighth gate electrode GE8. The eighth gate electrode GE8 may overlap a portion of the eighth active layer ACT8.

The eighth active layer ACT8 may include a channel region that overlaps the eighth gate electrode GE8 and a source region and a drain region, which are located on opposite sides of the channel region. The source region of the eighth active layer ACT8 may be electrically connected to a fifth power line VOBL. For example, the source region of the eighth active layer ACT8 may be electrically connected to a seventh connection electrode CNE7 through a fourteenth contact hole CH14 and may be electrically connected to the fifth power line VOBL through the seventh connection electrode CNE7. The seventh connection electrode CNE7 may be electrically connected to the fifth power line VOBL through a fifteenth contact hole CH15. The drain region of the eighth active layer ACT8 may be electrically connected to the first, second, and fifth active layers ACT1, ACT2, and ACT5 included in the first, second, and fifth transistors T1, T2, and T5. For example, the drain region of the eighth active layer ACT8 may be electrically connected to the source region of the first active layer ACT1 and the drain region of each of the second and fifth active layers ACT2 and ACT5.

In one or more embodiments, the first active layer ACT1, the second active layer ACT2, the fifth active layer ACT5, the sixth active layer ACT6, the seventh active layer ACT7, and the eighth active layer ACT8 of each of the first pixel circuit PXC1, the second pixel circuit PXC2, and the third pixel circuit PXC3 may be integrally formed and may be formed as substantially one semiconductor pattern. The first active layer ACT1, the second active layer ACT2, the fifth active layer ACT5, the sixth active layer ACT6, the seventh active layer ACT7, and the eighth active layer ACT8 may include the same semiconductor material, for example, polycrystalline silicon.

The eighth gate electrode GE8 may be electrically connected to the bias scan line GBL. For example, the eighth gate electrode GE8 and the bias scan line GBL may be integrally formed and may be formed as substantially one conductive pattern. In this case, a portion of the bias scan line GBL, which overlaps the eighth active layer ACT8, may function as the eighth gate electrode GE8.

When the backplane layer BPL further includes second power lines VSL located in the display area DA as in the embodiments of FIGS. 9 through 12, the second power lines VSL may be electrically connected to common electrodes CE (e.g., the common electrodes CE of FIG. 8) on the backplane layer BPL. For example, the second power lines VSL may be electrically connected to the common electrodes CE, which are located in the light emitting element layer on the backplane layer BPL, through cathode contact holes CDH (anode contact holes in the case of a display panel having a common-cathode structure) located in pixel areas PXA and may be electrically connected to the light emitting elements LE of the subpixels SPX through the common electrodes CE. In one or more embodiments, each of the cathode contact holes CDH may be located in a pixel area PXA and may overlap the second pixel circuit PXC2, but the present disclosure is not limited to this case. The number or positions of the cathode contact holes CDH in each pixel area PXA or the display area DA may vary depending on embodiments.

Signal lines and power lines PL of the backplane layer BPL may be located around circuit elements to which the lines are connected. In one or more embodiments, the first power line VDL may have a relatively large width at positions corresponding to the first transistor T1, the third transistor T3, and the fourth transistor T4 and may cover at least a portion of each of the first transistor T1, the third transistor T3, and the fourth transistor T4. For example, the first power line VDL may entirely or partially cover the channel region of each of the first transistor T1, the third transistor T3, and the fourth transistor T4. For example, the first power line VDL, which overlaps the first pixel circuit PXC1, may cover the channel region of each of the first transistor T1, the third transistor T3, and the fourth transistor T4 of the first pixel circuit PXC1, and the first power line VDL, which overlaps the second and third pixel circuits PXC2 and PXC3, may cover the channel region of each of the first transistors T1, the third transistors T3, and the fourth transistors T4 of the second and third pixel circuits PXC2 and PXC3. Accordingly, light incident from above the backplane layer BPL toward the channel regions of the first transistors T1, the third transistors T3 and the fourth transistors T4 can be blocked and/or reduced. Accordingly, the operating characteristics of the first transistors T1, the third transistors T3, and the fourth transistors T4 may be stabilized. In addition, because the first transistors T1, the third transistors T3, and the fourth transistors T4 are at least partially covered with the first power line VDL located on the first transistors T1, the third transistors T3, and the fourth transistors T4, the operating characteristics of the subpixels SPX can be improved without a light blocking pattern on the first transistors T1, the third transistors T3, and the fourth transistors T4. For example, the first power line VDL may be integrally formed with a light blocking pattern located on the first transistors T1, the third transistors T3, and the fourth transistors T4. Accordingly, the design structure of the backplane layer BPL can be further improved or optimized, and a space can be secured between patterns included in the backplane layer BPL.

In one or more embodiments, the subpixels SPX may be driven with driving currents Ids which are differentiated or optimized according to the optimal consumption efficiency of the light emitting elements LE. In addition, pixel transistors PXT located in current paths through which the driving currents Ids flow in the subpixels SPX may have different sizes according to their respective driving currents Ids. For example, the first transistors T1 of at least two subpixels SPX from among the first subpixel SPX1, the second subpixel SPX2, and the third subpixel SPX3 may have different sizes (e.g., ratios of a channel width to a channel length).

In one or more embodiments, the first subpixel SPX1 may be driven with a greater driving current Ids than the second subpixel SPX2 and the third subpixel SPX3 in response to a data voltage Vdata of each gray level. In this case, a size of the first transistor T1 of the first subpixel SPX1 may be larger than a size of the first transistor T1 of each of the second subpixel SPX2 and the third subpixel SPX3. For example, a ratio of a channel width to a channel length of the first transistor T1 of the first subpixel SPX1 may be greater than a ratio of a channel width to a channel length of the first transistor T1 of each of the second subpixel SPX2 and the third subpixel SPX3. Similarly, a size (e.g., a ratio of a channel width to a channel length) of the fifth transistor T5 of the first subpixel SPX1 may be larger than a size (e.g., a ratio of a channel width to a channel length) of the fifth transistor T5 of each of the second subpixel SPX2 and the third subpixel SPX3, and a size of the sixth transistor T6 of the first subpixel SPX1 may be larger than a size of the sixth transistor T6 of each of the second subpixel SPX2 and the third subpixel SPX3. Accordingly, the current handling capability of the first transistor T1 included in the first subpixel SPX1 may be increased.

When the subpixels SPX are driven with the driving currents Ids improved or optimized according to the optimal consumption efficiency of their respective light emitting elements LE, the consumption efficiency and lifespan of the light emitting elements LE may be improved. Accordingly, the power consumption and lifespan of the display device 10 may be improved.

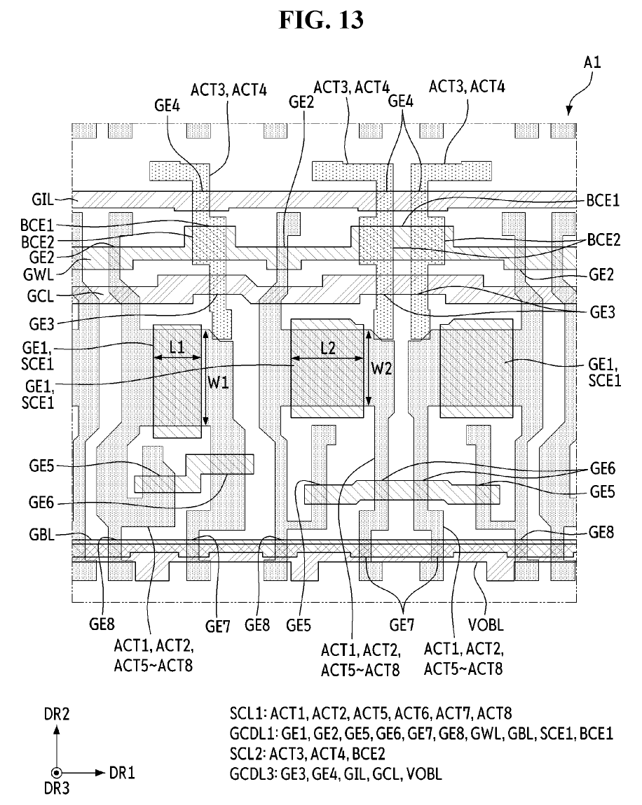

FIG. 13 is a layout view illustrating patterns included in a first semiconductor layer, a first gate conductive layer, a second semiconductor layer and a third gate conductive layer of a backplane layer according to one or more embodiments. For example, FIG. 13 shows, in detail, patterns of a first semiconductor layer SCL1, a first gate conductive layer GCDL1, a second semiconductor layer SCL2, and a third gate conductive layer GCDL3 located in the area A1 of FIG. 9.

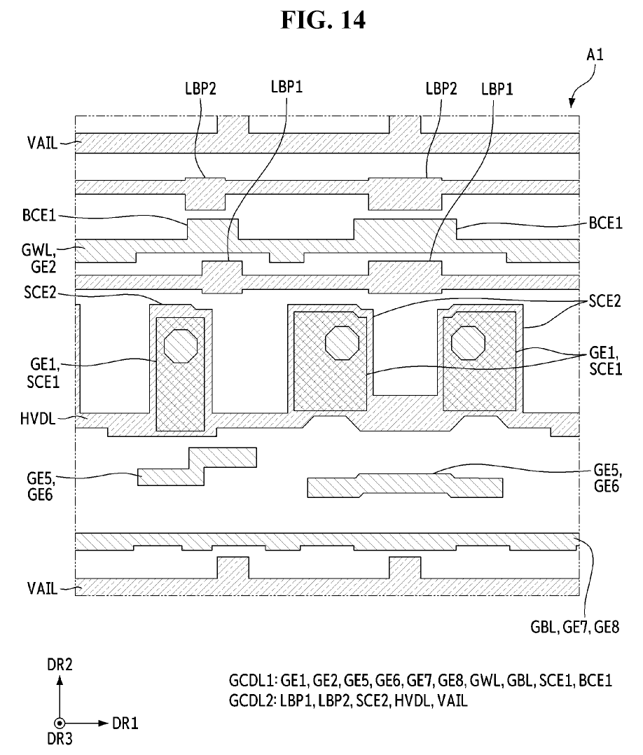

FIG. 14 is a layout view illustrating patterns included in a first gate conductive layer and a second gate conductive layer according to one or more embodiments. For example, FIG. 14 shows, in detail, patterns of the first gate conductive layer GCDL1 and a second gate conductive layer GCDL2 located in the area A1 of FIG. 9.

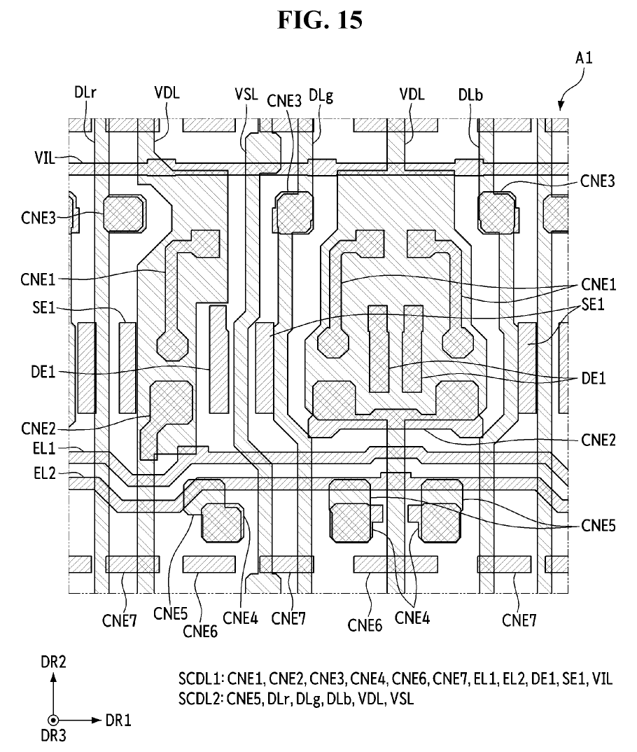

FIG. 15 is a layout view illustrating patterns included in a first source-drain conductive layer and a second source-drain conductive layer of a backplane layer according to one or more embodiments. For example, FIG. 15 shows, in detail, patterns of a first source-drain conductive layer SCDL1 and a second source-drain conductive layer SCDL2 located in the area A1 of FIG. 9.

Referring to FIGS. 13 through 15 in addition to FIGS. 9 through 12, circuit elements and wirings of a backplane layer BPL may be located in a plurality of semiconductor layers and conductive layers. For example, the circuit elements and the wirings of the backplane layer BPL may be formed as patterns of the first semiconductor layer SCL1, the first gate conductive layer GCDL1, the second gate conductive layer GCDL2, the second semiconductor layer SCL2, the third gate conductive layer GCDL3, the first source-drain conductive layer SCDL1, and the second source-drain conductive layer SCDL2 of the backplane layer BPL.

The first semiconductor layer SCL1 may include first, second, fifth, sixth, seventh, and eighth active layers ACT1, ACT2, ACT5, ACT6, ACT7, and ACT8.

The first gate conductive layer GCDL1 may include first, second, fifth, sixth, seventh, and eighth gate electrodes GE1, GE2, GE5, GE6, GE7 and GE8, a write scan line GWL, a bias scan line GBL, first electrodes SCE1 of storage capacitors Cst, and first electrodes BCE1 of boosting capacitors Cbst.

In each subpixel SPX, an area where the first active layer ACT1 and the first gate electrode GE1 overlap may include a channel region of a first transistor T1. In one or more embodiments, a first subpixel SPX1 may be driven with a larger driving current Ids than a second subpixel SPX2, and a ratio (W1/L1) of a width W1 to a length L1 of the channel region of the first transistor T1 included in the first subpixel SPX1 may be greater than a ratio (W2/L2) of a width W2 to a length L2 of the channel region of the first transistor T1 included in the second subpixel SPX2. For example, compared with the first active layer ACT1 of the second subpixel SPX2, the first active layer ACT1 of the first subpixel SPX1 may have a reduced size in the first direction DR1 corresponding to a length direction of the channel region and may have an increased size in the second direction DR2 corresponding to a width direction of the channel region. Accordingly, compared with the first transistor T1 of the second subpixel SPX2, the first transistor T1 of the first subpixel SPX1 may have a reduced size in the first direction DR1 and an increased size in the second direction DR2. In one or more embodiments, as the width W1 of the channel region of the first transistor T1 increases in the first subpixel SPX1, the first transistor T1 may be located closer to third and fourth transistors T3 and T4.

Similarly, the first subpixel SPX1 may be driven with a larger driving current Ids than a third subpixel SPX3, and the ratio (W1/L1) of the width W1 to the length L1 of the channel region of the first transistor T1 included in the first subpixel SPX1 may be greater than a ratio of a width to a length of the channel region of the first transistor T1 included in the third subpixel SPX3. In one or more embodiments, the first transistor T1 of the second subpixel SPX2 and the first transistor T1 of the third subpixel SPX3 may have substantially the same size and may be symmetrical to each other, but the present disclosure is not limited to this case.

In one or more embodiments, because the first subpixel SPX1 is driven with a larger driving current Ids than the second and third subpixels SPX2 and SPX3, sizes of fifth and sixth transistors T5 and T6 of the first subpixel SPX1 may also be increased. For example, ratios of widths to lengths of channel regions of the fifth and sixth transistors T5 and T6 of the first subpixel SPX1 may be greater than ratios of widths to lengths of the channel regions of the fifth and sixth transistors T5 and T6 of each of the second and third subpixels SPX2 and SPX3, respectively. For example, in the first subpixel SPX1, widths (e.g., horizontal lengths along the first direction DR1) of channel regions of the fifth and sixth active layers ACT5 and ACT6, which overlap the fifth and sixth gate electrodes GE5 and GE6, may be increased and thereby improving the operating characteristics of the first subpixel SPX1.

The second gate conductive layer GCDL2 may include first light blocking patterns LBP1, second light blocking patterns LBP2, second electrodes SCE2 of the storage capacitors Cst, a horizontal power line HVDL, and a fourth power line VAIL.

The second semiconductor layer SCL2 may include third and fourth active layers ACT3 and ACT4 and second electrodes BCE2 of the boosting capacitors Cbst.

The third gate conductive layer GCDL3 may include third and fourth gate electrodes GE3 and GE4, an initialization scan line GIL, a control scan line GCL, and a fifth power line VOBL.

The first source-drain conductive layer SCDL1 may include first, second, third, fourth, sixth, and seventh connection electrodes CNE1, CNE2, CNE3, CNE4, CNE6, and CNE7, first and second emission control lines EL1 and EL2, source and drain electrodes SE1 and DE1 of each first transistor T1, and a third power line VIL.

The second source-drain conductive layer SCDL2 may include fifth connection electrodes CNE5, first, second, and third data lines DLr, DLg, and DLb, and first and second power lines VDL and VSL.

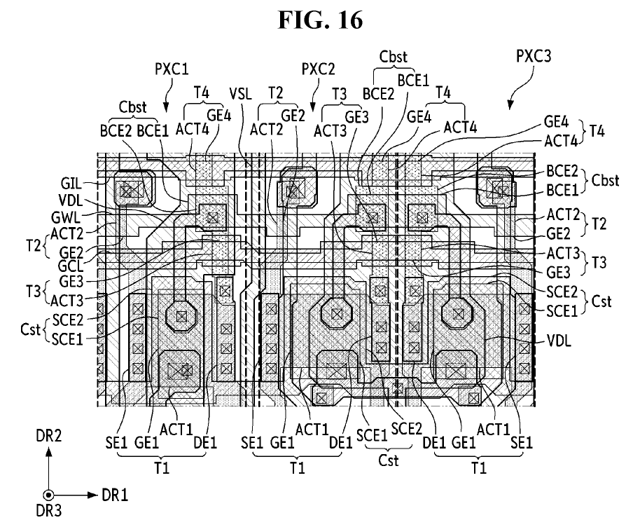

FIG. 16 is a layout view illustrating, in detail, part of a first pixel circuit, a second pixel circuit, and a third pixel circuit according to one or more embodiments. For example, FIG. 16 shows, in detail, first, second, third, and fourth transistors T1, T2, T3 and T4, a storage capacitor Cst, and a boosting capacitor Cbst of each of a first pixel circuit PXC1, a second pixel circuit PXC2, and a third pixel circuit PXC3.

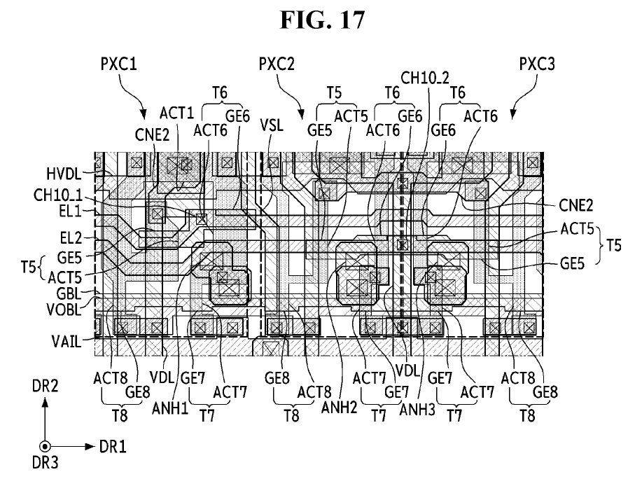

FIG. 17 is a layout view illustrating, in detail, part of the first pixel circuit, the second pixel circuit, and the third pixel circuit according to one or more embodiments. For example, FIG. 17 shows, in detail, fifth, sixth, seventh, and eighth transistors T5, T6, T7 and T8 of each of the first pixel circuit PXC1, the second pixel circuit PXC2, and the third pixel circuit PXC3.

Referring to FIGS. 16 and 17 in addition to FIGS. 9 through 15, the second pixel circuit PXC2 and the third pixel circuit PXC3 may be symmetrical to each other. For example, the second pixel circuit PXC2 and the third pixel circuit PXC3 may share one first power line VDL and may be flipped with respect to the first power line VDL. For example, the second pixel circuit PXC2 and the third pixel circuit PXC3 may be connected in common to one first power line VDL in each pixel area PXA and may be symmetrical to each other with respect to the one first power line VDL.

In one or more embodiments, the second pixel circuit PXC2 and the third pixel circuit PXC3 may contact each other in an area where one first power line VDL is located and may be designed symmetrically so that they are substantially symmetrical and/or inverted to each other with respect to the first power line VDL. For example, the second pixel circuit PXC2 and the third pixel circuit PXC3 may be substantially symmetrical to each other with respect to a central axis of the first power line VDL (e.g., a central axis of a vertical direction extending in the second direction DR2).

Specifically, the first through eighth transistors T1 through T8, the storage capacitor Cst, and the boosting capacitor Cbst of the second pixel circuit PXC2 may be located at positions facing the first through eighth transistors T1 through T8, the storage capacitor Cst, and the boosting capacitor Cbst of the third pixel circuit PXC3 in the first direction DR1, respectively. In addition, the first through eighth transistors T1 through T8, the storage capacitor Cst, and the boosting capacitor Cbst of the second pixel circuit PXC2 may be substantially symmetrical to the first through eighth transistors T1 through T8, the storage capacitor Cst, and the boosting capacitor Cbst of the third pixel circuit PXC3 with respect to a boundary between the second pixel circuit PXC2 and the third pixel circuit PXC3.

In one or more embodiments, the first transistors T1 of the first pixel circuit PXC1, the second pixel circuit PXC2, and the third pixel circuit PXC3 may be sequentially arranged along the first direction DR1. When the second pixel circuit PXC2 and the third pixel circuit PXC3 are symmetrical to each other, a drain electrode DE1 of the first transistor T1 included in the second pixel circuit PXC2 and a drain electrode DE1 of the first transistor T1 included in the third pixel circuit PXC3 may be located adjacent to each other in the first direction DR1. A drain electrode DE1 of the first transistor T1 included in the first pixel circuit PXC1 and a source electrode SE1 of the first transistor T1 included in the second pixel circuit PXC2 may be located adjacent to each other in the first direction DR1. A source electrode SE1 of the first transistor T1 included in the first pixel circuit PXC1 may be adjacent to a source electrode SE1 of the first transistor T1 included in the third pixel circuit PXC3 of another pixel PX adjacent in the first direction DR1. A source electrode SE1 of the first transistor T1 included in the third pixel circuit PXC3 may be adjacent to a source electrode SE1 of the first transistor T1 included in the first pixel circuit PXC1 of another pixel PX adjacent in the first direction DR1.

In one or more embodiments, the third and fourth transistors T3 and T4 of the second pixel circuit PXC2 and the third and fourth transistors T3 and T4 of the third pixel circuit PXC3 may be located adjacent to each other in the first direction DR1. For example, the third and fourth transistors T3 and T4 of the second pixel circuit PXC2 and the third and fourth transistors T3 and T4 of the third pixel circuit PXC3 may be located around the boundary between the second pixel circuit PXC2 and the third pixel circuit PXC3.

The first power line VDL shared by the second pixel circuit PXC2 and the third pixel circuit PXC3 may have an increased width in a central portion of the second and third pixel circuits PXC2 and PXC3 so as to overlap the first, third, and fourth transistors T1, T3, and T4 of the second and third pixel circuits PXC2 and PXC3. In addition, the first power line VDL shared by the second pixel circuit PXC2 and the third pixel circuit PXC3 may be located in an area between a second anode contact hole ANH2 and a third anode contact hole ANH3 and may extend in the second direction DR2 between the second anode contact hole ANH2 and the third anode contact hole ANH3. For example, the first power line VDL shared by the second pixel circuit PXC2 and the third pixel circuit PXC3 may pass through the area between the second anode contact hole ANH2 and the third anode contact hole ANH3 (e.g., a center between the second anode contact hole ANH2 and the third anode contact hole ANH3).

Each of first and second emission control lines EL1 and EL2 may cross or overlap fifth and sixth active layers ACT5 and ACT6 included in the fifth and sixth transistors T5 and T6 of the first pixel circuit PXC1, the second pixel circuit PXC2, and the third pixel circuit PXC3. However, the first and second emission control lines EL1 and EL2 may be located in a different conductive layer from fifth and sixth gate electrodes GE5 and GE6 included in the fifth and sixth transistors T5 and T6 of the first pixel circuit PXC1, the second pixel circuit PXC2, and the third pixel circuit PXC3. For example, the first and second emission control lines EL1 and EL2 may be located in a first source-drain conductive layer SCDL1, and the fifth and sixth gate electrodes GE5 and GE6 may be located in a first gate conductive layer GCDL1.

The fifth and sixth gate electrodes GE5 and GE6 of the first pixel circuit PXC1 may overlap the first emission control line EL1 and may be electrically connected to the first emission control line EL1 through one tenth contact hole CH10_1. For example, the tenth contact hole CH10_1 of the first pixel circuit PXC1 may be located between the fifth gate electrode GE5 and the sixth gate electrode GE6 of the first pixel circuit PXC1.

The fifth and sixth gate electrodes GE5 and GE6 of the second pixel circuit PXC2 and the fifth and sixth gate electrodes GE5 and GE6 of the third pixel circuit PXC3 may overlap the second emission control line EL2 and may be electrically connected to the second emission control line EL2 through one tenth contact hole CH10_2. In one or more embodiments, the fifth and sixth gate electrodes GE5 and GE6 of the second pixel circuit PXC2 and the fifth and sixth gate electrodes GE5 and GE6 of the third pixel circuit PXC3 may be integrated with each other to form one conductive pattern and may share one tenth contact hole CH10_2. For example, the tenth contact hole CH10_2 of the second and third pixel circuits PXC2 and PXC3 may be located between the fifth and sixth gate electrodes GE5 and GE6 of the second pixel circuit PXC2 and the fifth and sixth gate electrodes GE5 and GE6 of the third pixel circuit PXC3 (e.g., between the sixth gate electrode GE6 of the second pixel circuit PXC2 and the sixth gate electrode GE6 of the third pixel circuit PXC3).

Fifth and eighth active layers ACT5 and ACT8 of each of the pixel circuits PXC may extend downward from an end of a first active layer ACT1 of each of the pixel circuits PXC. For example, the fifth and eighth active layers ACT5 and ACT8 of each of the first pixel circuit PXC1 and the second pixel circuit PXC2 may be formed from a portion of a semiconductor pattern which extends downward from a left end of the first active layer ACT1 of each of the first pixel circuit PXC1 and the second pixel circuit PXC2 and may be located in a lower left portion of each of the first pixel circuit PXC1 and the second pixel circuit PXC2. On the other hand, the fifth and eighth active layers ACT5 and ACT8 of the third pixel circuit PXC3 may be formed from another portion of a semiconductor pattern which extends downward from a right end of the first active layer ACT1 of the third pixel circuit PXC3 and may be located in a lower right portion of the third pixel circuit PXC3. A portion of a semiconductor pattern that extends from an end of the first active layer ACT1 of each of the pixel circuits PXC (e.g., an end connected to the source electrode SE1) to the fifth and eighth active layers ACT5 and ACT8 may have a roughly “U” or “Y” shape around the first and second emission control lines EL1 and EL2 and may intersect or overlap the first and second emission control lines EL1 and EL2. Another portion of the semiconductor pattern that extends from another end of the first active layer ACT1 of each of the pixel circuits PXC (e.g., an end connected to the drain electrode DE1) to the sixth active layer ACT6 may extend in roughly the second direction DR2 around the first and second emission control lines EL1 and EL2 and may cross or overlap the first and second emission control lines EL1 and EL2. Because the first and second emission control lines EL1 and EL2 are located in a different conductive layer from the fifth and sixth gate electrodes GE5 and GE6, even if a semiconductor pattern of a first semiconductor layer SCL1, which includes the first, second, fifth, sixth, seventh and eighth active layers ACT1, ACT2, ACT5, ACT6, ACT7, and ACT8 of each of the pixel circuits PXC, overlaps both the first and second emission control lines EL1 and EL2, it is possible to appropriately adjust or select the positions at which the fifth and sixth transistors T5 and T6 are formed in each subpixel SPX by adjusting the positions of the fifth and sixth gate electrodes GE5 and GE6.

A semiconductor pattern of the first semiconductor layer SCL1 included in each of the pixel circuits PXC may be electrically connected to a second connection electrode CNE2 around the first transistor T1. In addition, the semiconductor pattern of the first semiconductor layer SCL1 included in each of the pixel circuits PXC may be electrically connected to the first power line VDL through the second connection electrode CNE2. In one or more embodiments, the second connection electrode CNE2 of each of the pixel circuits PXC may be adjacent to the first and second emission control lines EL1 and EL2. Accordingly, the size of the semiconductor pattern of the first semiconductor layer SCL1 can be reduced or minimized, and the design structure of the pixel circuits PXC can be improved.

In one or more embodiments, the second and third pixel circuits PXC2 and PXC3 may share one second connection electrode CNE2. For example, the second connection electrode CNE2 of the second and third pixel circuits PXC2 and PXC3 may be formed as one conductive pattern.

In one or more embodiments, the second connection electrode CNE2 of the second and third pixel circuits PXC2 and PXC3 may overlap the first transistors T1 and the first power line VDL of the second and third pixel circuits PXC2 and PXC3 and may extend in the first direction DR1 in an area where the second and third pixel circuits PXC2 and PXC3 are located. The second connection electrode CNE2 of the second and third pixel circuits PXC2 and PXC3 may be electrically connected to a second electrode SCE2 of the storage capacitor Cst and a horizontal power line HVDL through one sixth contact hole CH6. In addition, the second connection electrode CNE2 of the second and third pixel circuits PXC2 and PXC3 may be connected in common to the fifth active layers ACT5 of the fifth transistors T5 included in the second and third pixel circuits PXC2 and PXC3.

According to the above-described embodiments, pixel circuits PXC of subpixels SPX can be efficiently arranged in each pixel area PXA. For example, the second pixel circuit PXC2 and the third pixel circuit PXC3 may be arranged in a flipped form, and data lines DL, power lines PL, etc. may be appropriately arranged according to the shape of the second pixel circuit PXC2 and the third pixel circuit PXC3. Accordingly, a space for placing additional wiring, etc. can be secured. For example, a space in which at least one wiring can be placed may be created between the first pixel circuit PXC1 and the second and third pixel circuits PXC2 and PXC3 included in each pixel PX and between the pixel circuits PXC of two pixels PX adjacent to each other in the first direction DR1 (e.g., between the third pixel circuit PXC3 of a pixel PX located on the left and the first pixel circuit PXC1 of a pixel PX located on the right).

In one or more embodiments, second power lines VSL may be placed in the above space. In one or more embodiments, the second power lines VSL may be electrically connected to common electrodes CE within a display area DA. For example, the second power lines VSL may be electrically connected to the common electrodes CE, which are located on a backplane layer BPL, through cathode contact holes CDH formed in every at least one horizontal line (e.g., formed in every at least one pixel row). A mesh-shaped power line VSLM (e.g., the mesh-shaped power line VSLM of FIG. 8) may be formed in the display area DA by the second power lines VSL and the common electrodes CE. Accordingly, a drop in a second driving voltage VSS transmitted to light emitting elements LE may be reduced or minimized, and the power consumption of the display device 10 may be reduced.

In one or more embodiments, a size of the first transistor T1 included in a first subpixel SPX1 may be different from a size of the first transistor T1 included in each of a second subpixel SPX2 and a third subpixel SPX3. For example, when the first subpixel SPX1 is driven with a larger driving current Ids than the second subpixel SPX2 and the third subpixel SPX3 in response to a data voltage Vdata of each gray level, a ratio (e.g., W1/L1) of a channel width (e.g., W1 of FIG. 13) to a channel length (e.g., L1 of FIG. 13) of the first transistor T1 of the first subpixel SPX1 may be greater than a ratio (e.g., W2/L2) of a channel width (e.g., W2 of FIG. 13) to a channel length (e.g., L2 of FIG. 13) of each of the second subpixel SPX2 and the third subpixel SPX3. For example, the size of the first transistor T1 of each of the subpixels SPX may be differentiated or optimized according to the driving current Ids of each of the subpixels SPX by adjusting the size (e.g., area) of an area where the first active layer ACT1 and a first gate electrode GE1 overlap in each of the subpixels SPX. Similarly, a ratio of a channel width to a channel length of the fifth transistor T5 of the first subpixel SPX1 may be greater than a ratio of a channel width to a channel length of the fifth transistor T5 of each of the second subpixel SPX2 and the third subpixel SPX3, and a ratio of a channel width to a channel length of the sixth transistor T6 of the first subpixel SPX1 may be greater than a ratio of a channel width to a channel length of the sixth transistor T6 of each of the second subpixel SPX2 and the third subpixel SPX3. Accordingly, the operation of the subpixels SPX can be stabilized, and the power consumption of the display device 10 can be improved.

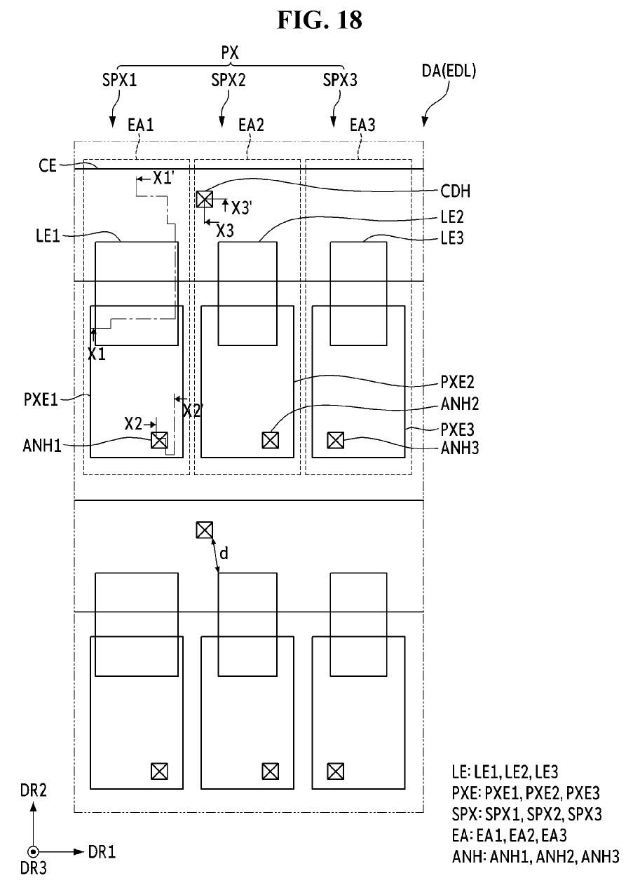

FIG. 18 is a layout view of a light emitting element layer of a display panel according to one or more embodiments. For example, FIG. 18 shows light emitting elements LE, pixel electrodes PXE, and a common electrode CE included in subpixels SPX of each pixel PX in a portion of a display area DA where two pixels PX adjacent to each other in the second direction DR2 are located.

Referring to FIG. 18 in addition to FIGS. 3 through 17, each of the subpixels SPX may include a pixel electrode PXE and a light emitting element LE located in an emission area EA. In one or more embodiments, when the light emitting element LE is a micro-LED of a flip-chip type or a lateral type, each of the subpixels SPX may further include a common electrode CE located on a surface (e.g., a lower surface or an upper surface) of the light emitting element LE together with the pixel electrode PXE.

Although the emission areas EA of the subpixels SPX have the same size in FIG. 18, the present disclosure is not limited to this case. For example, the sizes of the emission areas EA of the subpixels SPX may also be differentiated or optimized according to the emission characteristics or target luminances of the light emitting elements LE and/or subpixels SPX.

In addition, although the pixel electrodes PXE are located only within their respective emission areas EA in FIG. 18, embodiments are not limited to this case. For example, a portion of at least one pixel electrode PXE may be located in a non-emission area around an emission area EA. For example, the size, shape, and/or arrangement direction of the pixel electrodes PXE may vary depending on embodiments.

In one or more embodiments, the subpixels SPX of each pixel PX may be arranged along the first direction DR1. In addition, the subpixels SPX of each pixel PX may share one common electrode CE. For example, the common electrode CE may extend in the first direction DR1 in each horizontal line (e.g., in each pixel row) of the display area DA, and the subpixels SPX of the pixels PX located in the corresponding horizontal line (e.g., in the corresponding pixel row) may share one common electrode CE.

A first subpixel SPX1 may include a first pixel electrode PXE1, a first light emitting element LE1, and a common electrode CE (or a portion of the common electrode CE) located in a first emission area EA1. The first emission area EA1 may refer to an emission area EA of the first subpixel SPX1. The first light emitting element LE1 may refer to a light emitting element LE of the first subpixel SPX1.

A second subpixel SPX2 may include a second pixel electrode PXE2, a second light emitting element LE2, and the common electrode CE located in a second emission area EA2. The second emission area EA2 may refer to an emission area EA of the second subpixel SPX2. The second light emitting element LE2 may refer to a light emitting element LE of the second subpixel SPX2.

The third subpixel SPX3 may include a third pixel electrode PXE3, a third light emitting element LE3, and the common electrode CE located in a third emission area EA3. The third emission area EA3 may refer to an emission area EA of the third subpixel SPX3. The third light emitting element LE3 may refer to a light emitting element LE of the third subpixel SPX3.

In each pixel PX, the first pixel electrode PXE1, the second pixel electrode PXE2, and the third pixel electrode PXE3 may be arranged along the first direction DR1. The first pixel electrode PXE1, the second pixel electrode PXE2, and the third pixel electrode PXE3 may be spaced (e.g., spaced apart) from the common electrode CE in the second direction DR2.

The pixel electrodes PXE may be electrically connected to pixel circuits PXC through anode contact holes ANH, respectively. For example, the first pixel electrode PXE1 may be electrically connected to a first pixel circuit PXC1 through a first anode contact hole ANH1. The second pixel electrode PXE2 may be electrically connected to a second pixel circuit PXC2 through a second anode contact hole ANH2. The third pixel electrode PXE3 may be electrically connected to a third pixel circuit PXC3 through a third anode contact hole ANH3.

The light emitting elements LE may be located between the pixel electrodes PXE and the common electrode CE, respectively. For example, the first light emitting element LE1 may be located on the first pixel electrode PXE1 and the common electrode CE. A portion of the first light emitting element LE1 may overlap the first pixel electrode PXE1, and another portion of the first light emitting element LE1 may overlap the common electrode CE. The first light emitting element LE1 may be electrically connected between the first pixel electrode PXE1 and the common electrode CE. The second light emitting element LE2 may be located on the second pixel electrode PXE2 and the common electrode CE. A portion of the second light emitting element LE2 may overlap the second pixel electrode PXE2, and another portion of the second light emitting element LE2 may overlap the common electrode CE. The second light emitting element LE2 may be electrically connected between the second pixel electrode PXE2 and the common electrode CE. The third light emitting element LE3 may be located on the third pixel electrode PXE3 and the common electrode CE. A portion of the third light emitting element LE3 may overlap the third pixel electrode PXE3, and another portion of the third light emitting element LE3 may overlap the common electrode CE. The third light emitting element LE3 may be electrically connected between the third pixel electrode PXE3 and the common electrode CE.

Each of the light emitting elements LE may emit light of a specific color (e.g., red light, green light, blue light, or white light). In one or more embodiments, the first light emitting element LE1, the second light emitting element LE2, and the third light emitting element LE3 may emit light of different colors. For example, the first light emitting element LE1, the second light emitting element LE2, and the third light emitting element LE3 may emit light of a first color (e.g., red light), light of a second color (e.g., green light), and light of a third color (e.g., blue light), respectively.

In one or more embodiments, the light emitting elements LE of at least two subpixels SPX may have different sizes. For example, a size of the first light emitting element LE1 may be larger than a size of each of the second light emitting element LE2 and the third light emitting element LE3.

In one or more embodiments, the light emitting elements LE may have differentiated or optimized sizes according to the luminous efficiency of the light emitting elements LE. For example, at least two of the first light emitting element LE1, the second light emitting element LE2, and/or the third light emitting element LE3 may have different sizes according to the luminous efficiency of each of the first light emitting element LE1, the second light emitting element LE2, and the third light emitting element LE3. For example, when the luminous efficiency of the first light emitting element LE1 is lower than the luminous efficiency of each of the second light emitting element LE2 and the third light emitting element LE3 based on the same size and shape, the size of the first light emitting element LE1 may be larger than the size of each of the second light emitting element LE2 and the third light emitting element LE3. Accordingly, the luminous efficiency of the first light emitting element LE1 may be improved, and a difference in luminous efficiency between the first light emitting element LE1, the second light emitting element LE2 and the third light emitting element LE3 can be reduced or prevented.

In one or more embodiments, the first light emitting element LE1, the second light emitting element LE2, and the third light emitting element LE3 may emit light of the same color. In this case, at least one of a light conversion layer (e.g., a light conversion layer including wavelength conversion particles such as quantum dots) and a color filter may be located on the light emitting element LE of at least one of the first subpixel SPX1, the second subpixel SPX2, or the third subpixel SPX3 to convert light emitted from the light emitting element LE of the corresponding subpixel SPX into light corresponding to an emission color of the corresponding subpixel SPX. When the first light emitting element LE1, the second light emitting element LE2, and the third light emitting element LE3 emit light of the same color, the sizes of the first light emitting element LE1, the second light emitting element LE2, and the third light emitting element LE3 may be the same or different from each other. For example, the sizes of the light emitting elements LE of the subpixels SPX and/or the areas of the emission areas EA of the subpixels SPX may be differentiated according to the light conversion efficiency by the light conversion layer, etc.

Although FIG. 18 discloses an embodiment in which each of the first subpixel SPX1, the second subpixel SPX2, and the third subpixel SPX3 includes a single light emitting element LE, the present disclosure is not limited to this case. For example, at least one of the first subpixel SPX1, the second subpixel SPX2, and the third subpixel SPX3 may also include a plurality of light emitting elements LE.

The common electrode CE may be electrically connected to second power lines VSL. For example, the common electrode CE may be electrically connected to the second power lines VSL through a cathode contact hole CDH within the display area DA, but the present disclosure is not limited to this example. A second driving voltage VSS may be applied to the common electrode CE and the second power lines VSL.

The cathode contact hole CDH may be spaced (e.g., spaced apart) from the light emitting elements LE by a selected distance or more. For example, a distance d between the second light emitting element LE2, which is closest to the cathode contact hole CDH, and the cathode contact hole CDH may be about 10㎛ or more. In one or more embodiments, the shortest distance d between the cathode contact hole CDH and the light emitting elements LE may be set to about 11㎛ in consideration of alignment errors that may occur during a process of manufacturing the display panel 100.

Because the distance between the cathode contact hole CDH and the light emitting elements LE is secured, the light emitting elements LE may be more stably placed in the pixels PX. For example, because the distance between the cathode contact hole CDH and the light emitting elements LE is controlled to 10㎛ or more (e.g., 11㎛), the common electrode CE may be substantially flat in an area where the light emitting elements LE are located. Accordingly, the light emitting elements LE can be stably placed or bonded on the common electrode CE.

In one or more embodiments, a distance between the anode contact holes ANH and the light emitting elements LE may be equal to or greater than the shortest distance d between the cathode contact hole CDH and the light emitting elements LE. Accordingly, the pixel electrodes PXE may be substantially flat in the area where the light emitting elements LE are located. Accordingly, the light emitting elements LE can be more stably placed or bonded on the pixel electrodes PXE and the common electrode CE.

In one or more embodiments, the common electrode CE may extend to a non-display area NDA around the display area DA and may be electrically connected to a power bus line (e.g., a bus line to which the second driving voltage VSS is applied) located in the non-display area NDA. As the second power lines VSL are located in a backplane layer BPL in the display area DA, the resistance of wiring including the second power lines VSL can be reduced.

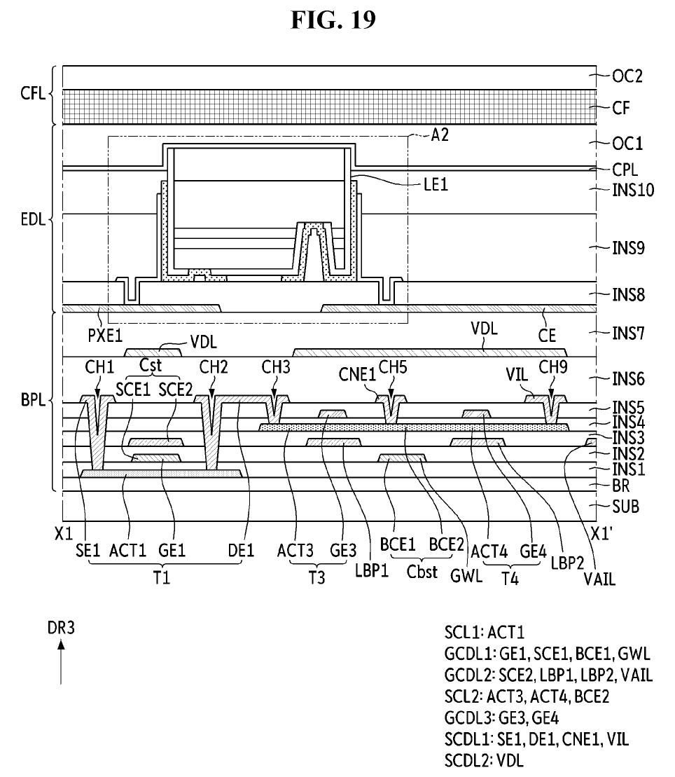

FIG. 19 is a cross-sectional view illustrating an example of a cross-section of a display panel corresponding to the line X1-X1’ of FIGS. 9 and 18. For example, FIG. 19 shows an embodiment of a cross-section of a display panel 100 corresponding to a portion of a first subpixel SPX1. In one or more embodiments, the first subpixel SPX1, a second subpixel SPX2, and a third subpixel SPX3 may have substantially the same or similar cross-sectional structures. For example, corresponding circuit elements of the first subpixel SPX1, the second subpixel SPX2, and the third subpixel SPX3 (e.g., first transistors T1 of the first subpixel SPX1, the second subpixel SPX2, and the third subpixel SPX3) may be located in substantially the same layer and may have substantially the same or similar cross-sectional structures.

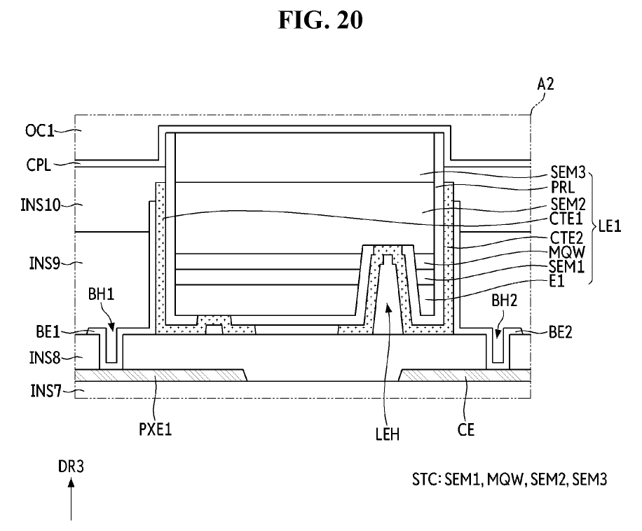

FIG. 20 is a detailed cross-sectional view of an area A2 of FIG. 19. In one or more embodiments, a first light emitting element LE1, a second light emitting element LE2, and a third light emitting element LE3 may have substantially the same or similar cross-sectional structures.

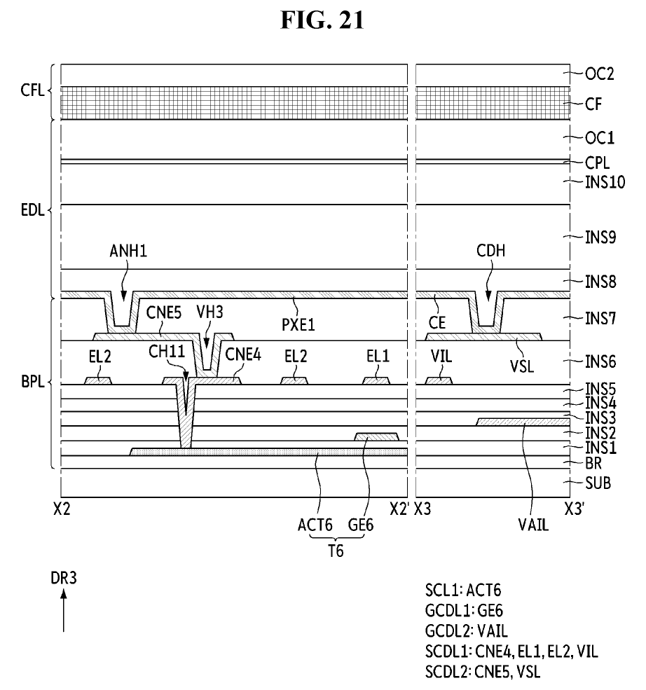

FIG. 21 is a cross-sectional view illustrating an example of a cross-section of a display panel corresponding to the lines X2-X2’ and X3-X3’ of FIGS. 9 and 18.

Referring to FIGS. 19 through 21 in addition to FIGS. 9 through 18, a display panel 100 may include a substrate SUB, and a backplane layer BPL, and a light emitting element layer EDL located on the substrate SUB. In one or more embodiments, the display panel 100 may further include a color filter layer CFL located on the light emitting element layer EDL. The backplane layer BPL, the light emitting element layer EDL, and the color filter layer CFL may be sequentially located on the substrate SUB along the third direction DR3 (e.g., a thickness direction of the substrate SUB).

The substrate SUB may include an insulating material such as glass or polymer resin. When the substrate SUB includes polymer resin, it may be a flexible substrate that can be stretched. The polymer resin may be acryl resin, epoxy resin, phenolic resin, polyamide resin, and/or polyimide resin.

The substrate SUB may include a display area DA and a non-display area NDA. The display area DA may include pixel areas PXA in which pixels PX are located. Each pixel area PXA may include emission areas EA of subpixels SPX.

The backplane layer BPL may include circuit elements included in pixel circuits PXC of the subpixels SPX and wirings connected to the subpixels SPX. In one or more embodiments, the backplane layer BPL may be entirely formed on a surface of the substrate SUB.

The backplane layer BPL may include at least one semiconductor layer, conductive layers, and insulating layers. In one or more embodiments, when the pixel circuits PXC include at least two types of pixel transistors PXT including different materials, the backplane layer BPL may include a plurality of semiconductor layers.

For example, the backplane layer BPL may include a barrier layer BR (or a buffer layer), a first semiconductor layer SCL1 (e.g., a polycrystalline silicon semiconductor layer), a first insulating layer INS1 (e.g., a first inorganic insulating layer), a first gate conductive layer GCDL1 (or a first conductive layer), a second insulating layer INS2 (e.g., a second inorganic insulating layer), a second gate conductive layer GCDL2 (or a second conductive layer), a third insulating layer INS3 (e.g., a third inorganic insulating layer), a second semiconductor layer SCL2 (e.g., an oxide semiconductor layer), a fourth insulating layer INS4 (e.g., a fourth inorganic insulating layer), a third gate conductive layer GCDL3 (or a third conductive layer), a fifth insulating layer INS5 (e.g., a fifth inorganic insulating layer), a first source-drain conductive layer SCDL1 (or a fourth conductive layer), a sixth insulating layer INS6 (e.g., a first organic insulating layer), a second source-drain conductive layer SCDL2 (or a fifth conductive layer), and a seventh insulating layer INS7 (e.g., a second organic insulating layer), which are sequentially located on the substrate SUB along the third direction DR3.

The barrier layer BR may be located on the substrate SUB. The barrier layer BR may protect circuit elements of the backplane layer BPL and light-emitting elements LE on the backplane layer BPL from moisture introduced through the substrate SUB which is vulnerable to moisture penetration. In one or more embodiments, the barrier layer BR may include a plurality of inorganic layers.

The circuit elements of the backplane layer BPL may be located on the barrier layer BR. For example, pixel transistors PXT, a storage capacitor Cst, and a boosting capacitor Cbst of each of the pixel circuits PXC included in a corresponding pixel PX may be located on the barrier layer BR in each pixel area PXA. In addition, wirings of the backplane layer BPL may be located on the barrier layer BR. For example, a write scan line GWL, an initialization scan line GIL, a control scan line GCL, a bias scan line GBL, a first emission control line EL1, a second emission control line EL2, a first data line DLr, a second data line DLg, a third data line DLb, a first power line VDL, a second power line VSL, a third power line VIL, a fourth power line VAIL, a fifth power line VOBL, and a horizontal power line HVDL may be located on the barrier layer BR.

In one or more embodiments, each of the pixel circuits PXC may include first type transistors and second type transistors. The first type transistors and the second type transistors may be located in different layers within the backplane layer BPL.

For example, each of the pixel circuits PXC may include first, second, fifth, sixth, seventh, and eighth transistors T1, T2, T5, T6, T7 and T8, which are P-type transistors, and third and fourth transistors T3 and T4, which are N-type transistors. First, second, fifth, sixth, seventh, and eighth active layers ACT1, ACT2, ACT5, ACT6, ACT7 and ACT8 of the first, second, fifth, sixth, seventh, and eighth transistors T1, T2, T5, T6, T7, and T8 and third and fourth active layers ACT3 and ACT4 of the third and fourth transistors T3 and T4 may be located in different semiconductor layers included in the backplane layer BPL. In one or more embodiments, the first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8 and the third and fourth active layers ACT3 and ACT4 of the third and fourth transistors T3 and T4 may include different semiconductor materials, but the present disclosure is not limited to this case. In addition, first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8 and the third and fourth gate electrodes GE3 and GE4 of the third and fourth transistors T3 and T4 may be located in different conductive layers included in the backplane layer BPL.

Specifically, the first semiconductor layer SCL1 may be located on the barrier layer BR. The first semiconductor layer SCL1 may include an active layer of each of the first type transistors. For example, the first semiconductor layer SCL1 may include the first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8. FIGS. 19 and 21 show only some of the pixel transistors PXT included in each pixel circuit PXC. In FIGS. 19 and 21, the first active layer ACT1 and the sixth active layer ACT6 from among the active layers included in the first semiconductor layer SCL1 are illustrated. In one or more embodiments, the first, second, fifth, sixth, seventh and eighth active layers ACT1, ACT2, ACT5, ACT6, ACT7 and ACT8 of each pixel circuit PXC may be integrally formed using the same semiconductor material. For example, as illustrated in FIGS. 9 through 17, the first, second, fifth, sixth, seventh, and eighth active layers ACT1, ACT2, ACT5, ACT6, ACT7, and ACT8 of each of a first pixel circuit PXC1, a second pixel circuit PXC2, and a third pixel circuit PXC3 may be connected to each other to form one semiconductor pattern.

The patterns of the first semiconductor layer SCL1 (e.g., the first, second, fifth, sixth, seventh, and eighth active layers ACT1, ACT2, ACT5, ACT6, ACT7, and ACT8) may include a first semiconductor material. In one or more embodiments, the first semiconductor material may be, but is not limited to, polycrystalline silicon (e.g., low-temperature polycrystalline silicon). For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO) and/or indium-tin-gallium-zinc oxide (ITGZO), or other oxide semiconductors) or monocrystalline silicon.

The first insulating layer INS1 may be located on the first semiconductor layer SCL1 and the barrier layer BR. The first insulating layer INS1 may include at least one insulating material (e.g., silicon nitride (SiNx), silicon oxide (SiOx), silicon oxynitride (SiON), titanium oxide (TiOx), aluminum oxide (AlOx), and/or other inorganic insulating materials) and may be formed as a single layer or a multilayer.

The first gate conductive layer GCDL1 may be located on the first insulating layer INS1. The first gate conductive layer GCDL1 may include a gate electrode of each of the first type transistors. For example, the first gate conductive layer GCDL1 may include the first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8. The first gate conductive layer GCDL1 may further include at least one conductive pattern and/or wiring. For example, the first gate conductive layer GCDL1 may further include a first electrode SCE1 of the storage capacitor Cst, a first electrode BCE1 of the boosting capacitor Cbst, the write scan line GWL, and the bias scan line GBL. In FIGS. 19 and 21, the first gate electrode GE1, the sixth gate electrode GE6, the first electrode SCE1 of the storage capacitor Cst, the first electrode BCE1 of the boosting capacitor Cbst, and the write scan line GWL among the patterns of the first gate conductive layer GCDL1 are illustrated.

In one or more embodiments, the first gate electrode GE1 of each pixel circuit PXC and the first electrode SCE1 of the storage capacitor Cst may be integrally formed, and the second gate electrode GE2, the first electrode BCE1 of the boosting capacitor Cbst and the write scan line GWL (e.g., the write scan line GWL connected to the subpixels SPX of a corresponding horizontal line (e.g., a corresponding pixel row)) may be integrally formed. In addition, the seventh gate electrode GE7, the eighth gate electrode GE8, and the bias scan line GBL (e.g., the bias scan line GBL connected to the subpixels SPX of a corresponding horizontal line) may be integrally formed.

The patterns of the first gate conductive layer GCDL1 (e.g., the first, second, fifth, sixth, seventh, and eighth gate electrodes GE1, GE2, GE5, GE6, GE7, and GE8, the first electrode SCE1 of the storage capacitor Cst, the first electrode BCE1 of the boosting capacitor Cbst, the write scan line GWL, and the bias scan line GBL) may include the same conductive material.

The second insulating layer INS2 may be located on the first gate conductive layer GCDL1 and the first insulating layer INS1. The second insulating layer INS2 may include at least one insulating material (e.g., an inorganic insulating material) and may be formed as a single layer or a multilayer.

The second gate conductive layer GCDL2 may be located on the second insulating layer INS2. The second gate conductive layer GCDL2 may include a second electrode SCE2 of the storage capacitor Cst. The first electrode SCE1 and the second electrode SCE2 of the storage capacitor Cst may overlap each other with the second insulating layer INS2 therebetween. The second insulating layer INS2 may be located between the first electrode SCE1 and the second electrode SCE2. The second electrode SCE2 of the storage capacitor Cst may be opened at a portion (e.g., a fourth contact hole CH4 and its surroundings) where the first electrode SCE1 of the storage capacitor Cst is connected to a first connection electrode CNE1. The second gate conductive layer GCDL2 may further include at least one conductive pattern and/or wiring. For example, the second gate conductive layer GCDL2 may further include a first light blocking pattern LBP1, a second light blocking pattern LBP2, the horizontal power line HVDL, and the fourth power line VAIL. In FIGS. 19 and 21, the second electrode SCE2 of the storage capacitor Cst, the first light blocking pattern LBP1, the second light blocking pattern LBP2, and the fourth power line VAIL among the patterns of the second gate conductive layer GCDL2 are illustrated.

In one or more embodiments, the first light blocking patterns LBP1 of the subpixels SPX located in each horizontal line (e.g., each pixel row) may be integrally formed, and the second light blocking patterns LBP2 of the subpixels SPX located in each horizontal line (e.g., each pixel row) may be integrally formed. In addition, the second electrodes SCE2 of the storage capacitors Cst of the subpixels SPX located in each horizontal line (e.g., each pixel row) and the horizontal power line HVDL may be integrally formed.

The patterns of the second gate conductive layer GCDL2 (e.g., the second electrode SCE2 of the storage capacitor Cst, the first light blocking pattern LBP1, the second light blocking pattern LBP2, the horizontal power line HVDL, and the fourth power line VAIL) may include the same conductive material.

The third insulating layer INS3 may be located on the second gate conductive layer GCDL2 and the second insulating layer INS2. The third insulating layer INS3 may include at least one insulating material (e.g., an inorganic insulating material) and may be formed as a single layer or a multilayer.

The second semiconductor layer SCL2 may be located on the third insulating layer INS3. The second semiconductor layer SCL2 may include an active layer of each of the second type transistors. For example, the second semiconductor layer SCL2 may include the third and fourth active layers ACT3 and ACT4 of the third and fourth transistors T3 and T4. In one or more embodiments, the third and fourth active layers ACT3 and ACT4 of each pixel circuit PXC may be integrally formed using the same semiconductor material. For example, as illustrated in FIGS. 9 through 13, the third and fourth active layers ACT3 and ACT4 of each of the first pixel circuit PXC1, the second pixel circuit PXC2, and the third pixel circuit PXC3 may be connected to each other to form one semiconductor pattern. In one or more embodiments, the second semiconductor layer SCL2 may further include a second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 (e.g., the third and fourth active layers ACT3 and ACT4 and the second electrode BCE2 of the boosting capacitor Cbst) may include a second semiconductor material. In one or more embodiments, the second semiconductor material may be an oxide semiconductor, but the present disclosure is not limited to this case. For example, the second semiconductor material may also be polycrystalline silicon or monocrystalline silicon.

The fourth insulating layer INS4 may be located on the second semiconductor layer SCL2 and the third insulating layer INS3. The fourth insulating layer INS4 may include at least one insulating material (e.g., an inorganic insulating material) and may be formed as a single layer or a multilayer.

The third gate conductive layer GCDL3 may be located on the fourth insulating layer INS4. The third gate conductive layer GCDL3 may include a gate electrode of each of the second type transistors. For example, the third gate conductive layer GCDL3 may include the third and fourth gate electrodes GE3 and GE4 of the third and fourth transistors T3 and T4. The third gate conductive layer GCDL3 may further include at least one conductive pattern and/or wiring. For example, the third gate conductive layer GCDL3 may further include the initialization scan line GIL, the control scan line GCL, and the fifth power line VOBL. In FIGS. 19 and 21, the third gate electrode GE3 and the fourth gate electrode GE4 among the patterns of the third gate conductive layer GCDL3 are illustrated.

In one or more embodiments, the third gate electrode GE3 and the control scan line GCL (e.g., the control scan line GCL connected to the subpixels SPX of a corresponding horizontal line (e.g., the corresponding pixel row)) may be integrally formed. In addition, the fourth gate electrode GE4 and the initialization scan line GIL (e.g., the initialization scan line GIL connected to the subpixels SPX of a corresponding horizontal line (e.g., the corresponding pixel row)) may be integrally formed.

The patterns of the third gate conductive layer GCDL3 (e.g., the third and fourth gate electrodes GE3 and GE4, the initialization scan line GIL, the control scan line GCL, and the fifth power line VOBL) may include the same conductive material.

The fifth insulating layer INS5 may be located on the third gate conductive layer GCDL3 and the fourth insulating layer INS4. The fifth insulating layer INS5 may include at least one insulating material (e.g., an inorganic insulating material) and may be formed as a single layer or a multilayer.

The first source-drain conductive layer SCDL1 may be located on the fifth insulating layer INS5. The first source-drain conductive layer SCDL1 may include at least one electrode, conductive pattern and/or wiring. For example, the first source-drain conductive layer SCDL1 may include source and drain electrodes SE1 and DE1 of the first transistor T1, first, second, third, fourth, sixth, and seventh connection electrodes CNE1, CNE2, CNE3, CNE4, CNE6, and CNE7, the first and second emission control lines EL1 and EL2, and the third power line VIL. In FIGS. 19 and 21, the source and drain electrodes SE1 and DE1 of the first transistor T1, the first and fourth connection electrodes CNE1 and CNE4, the first and second emission control lines EL1 and EL2, and the third power line VIL among the patterns of the first source-drain conductive layer SCDL1 are illustrated.

The patterns of the first source-drain conductive layer SCDL1 (e.g., the source and drain electrodes SE1 and DE1 of the first transistor T1, the first, second, third, fourth, sixth, and seventh connection electrodes CNE1, CNE2, CNE3, CNE4, CNE6, and CNE7, the first and second emission control lines EL1 and EL2, and the third power line VIL) may include the same conductive material.

The sixth insulating layer INS6 may be located on the first source-drain conductive layer SCDL1 and the fifth insulating layer INS5. The sixth insulating layer INS6 may include at least one insulating material (e.g., acryl resin, epoxy resin, phenolic resin, polyamide resin, polyimide resin, and/or other organic insulating materials) and may be formed as a single layer or a multilayer.

The second source-drain conductive layer SCDL2 may be located on the sixth insulating layer INS6. The second source-drain conductive layer SCDL2 may include at least one electrode, conductive pattern and/or wiring. For example, the second source-drain conductive layer SCDL2 may include a fifth connection electrode CNE5, the first, second, and third data lines DLr, DLg, and DLb, and the first and second power lines VDL and VSL. In FIGS. 19 and 21, the fifth connection electrode CNE5, the first power line VDL, and the second power line VSL among the patterns of the second source-drain conductive layer SCDL2 are illustrated.

The patterns of the second source-drain conductive layer SCDL2 (e.g., the fifth connection electrode CNE5, the first, second, and third data lines DLr, DLg, and DLb, and the first and second power lines VDL and VSL) may include the same conductive material.

The seventh insulating layer INS7 may be located on the second source-drain conductive layer SCDL2 and the sixth insulating layer INS6. The seventh insulating layer INS7 may include at least one insulating material (e.g., an organic insulating material) and may be formed as a single layer or a multilayer.

The patterns included in each of the conductive layers of the backplane layer BPL may include at least one conductive material. For example, the electrodes, conductive patterns and/or wirings included in each of the first gate conductive layer GCDL1, the second gate conductive layer GCDL2, the third gate conductive layer GCDL3, the first source-drain conductive layer SCDL1, and the second source-drain conductive layer SCDL2 may include copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and/or other metals, an alloy thereof, or other conductive materials. In one or more embodiments, the electrodes, conductive patterns and/or wirings located in the same conductive layer may be concurrently (e.g., simultaneously) formed using the same conductive material. At least two of the conductive layers of the backplane layer BPL may include the same conductive material or different conductive materials.

In one or more embodiments, the patterns included in each of the conductive layers of the backplane layer BPL may have a single-layer or multilayer structure. For example, each of the electrodes, conductive patterns, and/or wirings included in each of the first gate conductive layer GCDL1, the second gate conductive layer GCDL2, the third gate conductive layer GCDL3, the first source-drain conductive layer SCDL1, and the second source-drain conductive layer SCDL2 may have a single-layer or multilayer structure. At least two of the conductive layers of the backplane layer BPL may have the same cross-sectional structure or different cross-sectional structures.

In one or more embodiments, the patterns of the second source-drain conductive layer SCDL2 may include a metal (e.g., molybdenum (Mo), aluminum (Al), chromium (Cr), gold (Au), titanium (Ti), nickel (Ni), neodymium (Nd), copper (Cu) ,and/or other metals, or an alloy thereof) and may have a single-layer or multilayer structure. For example, the electrodes, conductive patterns and/or wirings included in the second source-drain conductive layer SCDL2 may be low-resistance patterns formed in a three-layer structure of titanium/aluminum/titanium (Ti/Al/Ti). Alternatively, the patterns of the second source-drain conductive layer SCDL2 may include other low-resistance materials and/or structures. When the resistance of the patterns included in the second source-drain conductive layer SCDL2 is reduced or minimized, the resistance of the first power line VDL and the second power line VSL, through which a driving current Ids of each of the subpixels SPX flows, may be reduced or minimized. Accordingly, the image quality of the display device 10 may be uniformized, and power consumption may be improved.

The light emitting element layer EDL may be located on the seventh insulating layer INS7. The light emitting element layer EDL may include pixel electrodes PXE, light emitting elements LE, and a common electrode CE included in the subpixels SPX. In addition, the light emitting element layer EDL may further include insulating layers. In one or more embodiments, the insulating layers of the light emitting element layer EDL may include eighth, ninth, and tenth insulating layers INS8, INS9, and INS10, a capping layer CPL, and a first overcoat layer OC1.

A pixel electrode layer including the pixel electrodes PXE of the subpixels SPX may be located on the seventh insulating layer INS7. For example, the pixel electrode layer may include a first pixel electrode PXE1, a second pixel electrode PXE2, and a third pixel electrode PXE3. In one or more embodiments, each of the light emitting elements LE may be a flip-chip type micro-LED. The flip-chip type micro-LED refers to an LED in which first and second contact electrodes CTE1 and CTE2 are formed on a surface (e.g., a lower surface) of a light emitting element LE. When the light-emitting elements LE are flip-chip type micro-LEDs, the pixel electrode layer may further include the common electrode CE. For example, the pixel electrodes PXE and the common electrode CE of the subpixels SPX may be located in (e.g., at) the same layer and may be formed concurrently (e.g., simultaneously) using the same conductive material.

The first pixel electrode PXE1 of the first subpixel SPX1 may be electrically connected to the fifth connection electrode CNE5 of the first subpixel SPX1 through a first anode contact hole ANH1 (e.g., a contact hole that penetrates the seventh insulating layer INS7 to expose the fifth connection electrode CNE5 of the first subpixel SPX1). The second pixel electrode PXE2 of the second subpixel SPX2 may be electrically connected to the fifth connection electrode CNE5 of the second subpixel SPX2 through a second anode contact hole ANH2 (e.g., a contact hole that penetrates the seventh insulating layer INS7 to expose the fifth connection electrode CNE5 of the second subpixel SPX2). The third pixel electrode PXE3 of the third subpixel SPX3 may be electrically connected to the fifth connection electrode CNE5 of the third subpixel SPX3 through a third anode contact hole ANH3 (e.g., a contact hole that penetrates the seventh insulating layer INS7 to expose the fifth connection electrode CNE5 of the third subpixel SPX3). Accordingly, the first pixel electrode PXE1, the second pixel electrode PXE2, and the third pixel electrode PXE3 may be electrically connected to the first pixel circuit PXC1, the second pixel circuit PXC2, and the third pixel circuit PXC3, respectively. In addition, the first pixel circuit PXC1, the second pixel circuit PXC2, and the third pixel circuit PXC3 may control voltages applied to the first pixel electrode PXE1, the second pixel electrode PXE2, and the third pixel electrode PXE3.

The common electrode CE shared by the first, second, and third subpixels SPX1, SPX2, and SPX3 may be electrically connected to the second power line VSL of the backplane layer BPL through a cathode contact hole CDH (e.g., a contact hole that penetrates the seventh insulating layer INS7 to expose the second power line VSL of the backplane layer BPL). Accordingly, a second driving voltage VSS applied to the second power line VSL may be transmitted to the common electrode CE.

In one or more embodiments, the patterns of the pixel electrode layer (e.g., the pixel electrodes PXE and the common electrode CE) may include the same conductive material. In one or more embodiments, the patterns of the pixel electrode layer may include a metal (e.g., at least one of molybdenum (Mo), aluminum (Al), chromium (Cr), gold (Au), titanium (Ti), nickel (Ni), neodymium (Nd), copper (Cu) and/or other metals, and/or an alloy thereof) and may have a single-layer or multilayer structure. For example, the patterns of the pixel electrode layer may be low-resistance patterns formed in a three-layer structure of titanium/aluminum/titanium (Ti/Al/Ti). Alternatively, the patterns of the pixel electrode layer may include other low-resistance materials (e.g., copper (Cu)) and/or structures. When the resistance of the patterns included in the pixel electrode layer is reduced or minimized, a first driving voltage VDD and the second driving voltage VSS can be stably transmitted to the light emitting elements LE of the subpixels SPX.

The eighth insulating layer INS8 may be located on the pixel electrodes PXE and the common electrode CE. The eighth insulating layer INS8 temporarily fixes or attaches the light emitting elements LE to prevent the light emitting elements LE from tilting or falling during a process of transferring the light emitting elements LE to the display panel 100. For example, the eighth insulating layer INS8 may be a layer for temporarily attaching the light emitting elements LE onto the pixel electrodes PXE and the common electrode CE. To facilitate the temporary attachment, a thickness of the eighth insulating layer INS8 may be greater than a thickness of each of the pixel electrodes PXE and the common electrode CE and greater than a thickness of each of the first and second contact electrodes CTE1 and CTE2 of the light emitting elements LE.

Although the eighth insulating layer INS8 is located over the entire display area DA in FIGS. 19 through 21, the present disclosure is not limited to this case. For example, the eighth insulating layer INS8 may be located only on portions of the pixel electrodes PXE and the common electrode CE which overlap the light emitting elements LE and may expose other portions of the pixel electrodes PXE and the common electrode CE.

The eighth insulating layer INS8 may include at least one insulating material, for example, an organic insulating material. For example, the eighth insulating layer INS8 may be a photosensitive organic layer such as a photoresist. Alternatively, the eighth insulating layer INS8 may include acryl resin, epoxy resin, phenolic resin, polyamide resin, and/or polyimide resin.

The light emitting elements LE may be located on the eighth insulating layer INS8. For example, the first light emitting element LE1 may be located on the first pixel electrode PXE1 and the common electrode CE of the first subpixel SPX1. The second light emitting element LE2 may be located on the second pixel electrode PXE2 and the common electrode CE of the second subpixel SPX2. The third light emitting element LE3 may be located on the third pixel electrode PXE3 and the common electrode CE of the third subpixel SPX3.

In one or more embodiments, each of the light emitting elements LE may be a micro-LED including an inorganic material. For example, each of the light emitting elements LE may include an inorganic material such as gallium nitride (GaN). Each of the light emitting elements LE may have a length of several to hundreds of ㎛ in each of the first direction DR1, the second direction DR2, and the third direction DR3. For example, each of the light emitting elements LE may have a length of about 100㎛ or less in each of the first direction DR1, the second direction DR2, and the third direction DR3.

The light emitting elements LE may be grown on a semiconductor substrate such as a silicon substrate and/or a sapphire substrate. The light emitting elements LE may be directly transferred from the semiconductor substrate onto the pixel electrodes PXE and the common electrode CE of the display panel 100. Alternatively, the light emitting elements LE may be transferred onto the pixel electrodes PXE and the common electrode CE of the display panel 100 through an electrostatic method using an electrostatic head or a stamp method using an elastic polymer material, such as PDMS and/or silicon, as a transfer substrate.

Each of the light emitting elements LE may include a conductive layer E1, a semiconductor stack STC, contact electrodes CTE1 and CTE2, and a protective layer PRL. The semiconductor stack STC may include a first semiconductor layer SEM1, an active layer MQW (e.g., a light emitting layer), and a second semiconductor layer SEM2 sequentially arranged along the third direction DR3. In one or more embodiments, the semiconductor stack STC may further include a third semiconductor layer SEM3 on the second semiconductor layer SEM2.

The conductive layer E1 may be located on a lower surface of the first semiconductor layer SEM1. Although the conductive layer E1 covers the entire lower surface of the first semiconductor layer SEM1 in FIG. 20, the present disclosure is not limited to this case. For example, the conductive layer E1 may also be located on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd) and/or copper (Cu), and/or may include a transparent conductive material such as metal oxide.

The first semiconductor layer SEM1 may be located on the conductive layer E1. The first semiconductor layer SEM1 may include a semiconductor material layer, for example, gallium nitride (GaN) doped with a first conductivity type dopant such as magnesium (Mg), zinc (Zn), calcium (Ca), strontium (Sr), and/or barium (Ba).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light through the recombination of electron-hole pairs in response to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may include InGaN, and the barrier layers may include GaN and/or AlGaN, but the present disclosure is not limited to this case. Alternatively, the active layer MQW may be a structure in which semiconductor materials having a large band gap energy and semiconductor materials having a small band gap energy are alternately stacked or may include Group III to V semiconductor materials depending on the wavelength band of light to be emitted by the active layer MQW.

When the active layer MQW includes indium gallium nitride (InGaN), the color of light emitted by the active layer MQW may vary depending on indium content. For example, as the indium content increases, the wavelength band of light emitted by the active layer MQW may move to a red wavelength band, and as the indium content decreases, the wavelength band of light emitted by the active layer MQW may move to a blue wavelength band. For example, the indium content of the active layer MQW of a light emitting element LE, which emits light of a third color (blue light), may be about 10 to 20 wt%.

The second semiconductor layer SEM2 may be located on the active layer MQW. The second semiconductor layer SEM2 may be a semiconductor material layer, for example, gallium nitride (GaN) doped with a second conductivity type dopant such as silicon (Si), germanium (Ge), and/or tin (Sn).

The third semiconductor layer SEM3 may be located on the second semiconductor layer SEM2. The third semiconductor layer SEM3 may be a semiconductor material layer having an n-type dopant, which is lower than a selected threshold value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant which is lower than a selected threshold value.

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer can be omitted.

A superlattice layer may be located between the active layer MQW and the second semiconductor layer SEM2. The superlattice layer may be a layer for alleviating the stress between the second semiconductor layer SEM2 and the active layer MQW. For example, the superlattice layer may include InGaN and/or GaN. The superlattice layer can be omitted.

The protective layer PRL may be located on side surfaces of the first semiconductor layer SEM1, side surfaces of the active layer MQW, and side surfaces of the second semiconductor layer SEM2. The protective layer PRL may be a layer for protecting side surfaces of each light emitting element LE. The protective layer PRL may include an inorganic material, for example, silicon nitride (SiNₓ), silicon oxide (SiOx), silicon oxynitride (SiON), titanium oxide (TiOx), aluminum oxide (AlOx), and/or other inorganic insulating materials.

In FIG. 20, the protective layer PRL is located on the side surfaces and a lower surface of the conductive layer E1, the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC. In one or more other embodiments, the protective layer PRL may not be located on side surfaces of the third semiconductor layer SEM3. However, the present disclosure is not limited to this case. For example, in one or more embodiments, the protective layer PRL may also be located on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH may be formed to penetrate the conductive layer E1, the first semiconductor layer SEM1, and the active layer MQW of each light emitting element LE and expose the second semiconductor layer SEM2. The hole LEH may have a circular planar shape, but the present disclosure is not limited to this case. For example, the hole LEH may also have an elliptical planar shape or a polygonal planar shape such as a quadrangle.

The protective layer PRL may be located on sidewalls of the conductive layer E1, sidewalls of the first semiconductor layer SEM1, and sidewalls of the active layer MQW exposed in the hole LEH. The protective layer PRL may not cover the second semiconductor layer SEM2 in the hole LEH. Accordingly, the second semiconductor layer SEM2 may be exposed without being covered by the protective layer PRL.

The first contact electrode CTE1 may be located on at least one side surface of the semiconductor stack STC and at least one side surface and a lower surface of the conductive layer E1. The first contact electrode CTE1 may be located on the lower surface of the conductive layer E1 exposed without being covered by the protective layer PRL. Therefore, the first contact electrode CTE1 may be electrically connected to the conductive layer E1.

The second contact electrode CTE2 may be located on at least one side surface of the semiconductor stack STC and at least one side surface and the lower surface of the conductive layer E1. Here, the first contact electrode CTE1 may be located on a first side surface of the semiconductor stack STC and a first side surface of the conductive layer E1, but the second contact electrode CTE2 may be located on a second side surface of the semiconductor stack STC and a second side surface of the conductive layer E1.

The second contact electrode CTE2 may be located on the protective layer PRL, which is located in the hole LEH, and the second semiconductor layer SEM2, which is exposed without being covered by the protective layer PRL in the hole LEH. Therefore, the second contact electrode CTE2 may be electrically connected to the second semiconductor layer SEM2 in the hole LEH.

Although the first contact electrode CTE1 and the second contact electrode CTE2 of each of the light emitting elements LE are located on the eighth insulating layer INS8 in FIGS. 19 and 20, the present disclosure is not limited to this case. For example, the eighth insulating layer INS8 may be located on a lower surface and a portion of a side surface of the first contact electrode CTE1 and a lower surface and a portion of a side surface of the second contact electrode CTE2 of each of the light emitting elements LE. Alternatively, the eighth insulating layer INS8 may be located on the side surfaces of the conductive layer E1 of each of the light emitting elements LE. Alternatively, the eighth insulating layer INS8 may be located on the side surfaces of the first semiconductor layer SEM1, the side surfaces of the active layer MQW, and the side surfaces of the second semiconductor layer SEM2 of each of the light emitting elements LE. In this case, the eighth insulating layer INS8 may be located on a portion of each of the side surfaces of the second semiconductor layer SEM2.

Each of the first contact electrode CTE1 and the second contact electrode CTE2 may be located on three side surfaces of the semiconductor stack STC. For example, when the semiconductor stack STC includes first through fourth side surfaces, the first contact electrode CTE1 may be located on the first side surface, the second side surface, and the third side surface, and the second contact electrode CTE2 may be located on the second side surface, the third side surface, and the fourth side surface.

Each of the first contact electrode CTE1 and the second contact electrode CTE2 may include at least one conductive material, for example, molybdenum (Mo), aluminum (Al), chromium (Cr), gold (Au), titanium (Ti), nickel (Ni), neodymium (Nd), and/or copper (Cu). In one or more embodiments, to increase reflectivity, the first contact electrode CTE1 and the second contact electrode CTE2 may have a two-layer structure of chromium (Cr) and gold (Au), a three-layer structure of titanium (Ti), aluminum (Al) and titanium (Ti), or a three-layer structure of indium tin oxide (ITO), silver (Ag) and indium tin oxide (ITO).

When each of the first contact electrode CTE1 and the second contact electrode CTE2 includes a metal with high reflectivity, light travelling toward the side of a light emitting element LE from among the light emitted from the active layer MQW of the light emitting element LE may be reflected by the first contact electrode CTE1 and the second contact electrode CTE2 to an upper surface of the light emitting element LE. Accordingly, a loss of light of the light emitting element LE can be reduced, which, in turn, increases the light efficiency of the light emitting element LE. Therefore, in order to increase the light efficiency of the light emitting element LE, the first contact electrode CTE1 and the second contact electrode CTE2 may cover most of the side surfaces of the semiconductor stack STC.

A first bridge electrode BE1 (or an eighth connection electrode) connects the first contact electrode CTE1 of a light emitting element LE and each pixel electrode PXE. For example, the first bridge electrode BE1 of the first subpixel SPX1 may connect the first contact electrode CTE1 of the first light emitting element LE1 and the first pixel electrode PXE1. Similarly, the first bridge electrode BE1 of the second subpixel SPX2 may connect the first contact electrode CTE1 of the second light emitting element LE2 and the second pixel electrode PXE2, and the first bridge electrode BE1 of the third subpixel SPX3 may connect the first contact electrode CTE1 of the third light emitting element LE3 and the third pixel electrode PXE3.

The first bridge electrode BE1 may be connected to each pixel electrode PXE which is exposed through a first connection hole BH1 penetrating the eighth insulating layer INS8. In addition, the first bridge electrode BE1 may be located on an upper surface of the eighth insulating layer INS8 and the first contact electrode CTE1 of each light emitting element LE. In one or more embodiments, if the eighth insulating layer INS8 is located only on a portion of a pixel electrode PXE which overlaps a light emitting element LE, the first connection hole BH1 may be unnecessary. For example, the first bridge electrode BE1 may be located directly on the pixel electrode PXE which is exposed around the light emitting element LE.

A second bridge electrode BE2 (or a ninth connection electrode) connects the second contact electrode CTE2 of each light emitting element LE and the common electrode CE. For example, the second bridge electrode BE2 of the first subpixel SPX1 may connect the second contact electrode CTE2 of the first light emitting element LE1 and the common electrode CE. Similarly, the second bridge electrode BE2 of the second subpixel SPX2 may connect the second contact electrode CTE2 of the second light emitting element LE2 and the common electrode CE, and the second bridge electrode BE2 of the third subpixel SPX3 may connect the second contact electrode CTE2 of the third light emitting element LE3 and the common electrode CE. In one or more embodiments, if the eighth insulating layer INS8 is located only on a portion of the common electrode CE which overlaps a light emitting element LE, a second connection hole BH2 may be unnecessary. For example, the second bridge electrode BE2 may be located directly on the common electrode CE which is exposed around the light emitting element LE.

The second bridge electrode BE2 may be connected to the common electrode CE which is exposed through the second connection hole BH2 penetrating the eighth insulating layer INS8. In addition, the second bridge electrode BE2 may be located on the upper surface of the eighth insulating layer INS8 and the second contact electrode CTE2.

Each of the first bridge electrode BE1 and the second bridge electrode BE2 may include at least one conductive material, for example, molybdenum (Mo), aluminum (Al), chromium (Cr), gold (Au), titanium (Ti), nickel (Ni), neodymium (Nd), and/or copper (Cu). Alternatively, each of the first bridge electrode BE1 and the second bridge electrode BE2 may include a transparent conductive material (e.g., a transparent conductive oxide (TCO)) such as indium tin oxide (ITO) or indium zinc oxide (IZO).

When each of the first bridge electrode BE1 and the second bridge electrode BE2 includes a metal material with high reflectivity, such as aluminum (Al), light travelling toward the side of a light emitting element LE among the light emitted from the active layer MQW of the light emitting element LE may be reflected by the connection electrodes BE (BE1, BE2) toward the top of the light emitting element LE. Accordingly, a loss of light of the light emitting element LE may be reduced, which, in turn, increases the light efficiency of the light emitting element LE.

As illustrated in FIGS. 19 and 20, the conductive layer E1 of a light emitting element LE may be electrically connected to each pixel electrode PXE through the first contact electrode CTE1 and the first bridge electrode BE1. In addition, the second semiconductor layer SEM2 of the light emitting element LE may be electrically connected to the common electrode CE through the second contact electrode CTE2, which is formed in the hole LEH, and the second bridge electrode BE2. The pixel electrodes PXE may be referred to as anodes or first electrodes, and the common electrode CE may be referred to as a cathode or a second electrode.

The ninth insulating layer INS9 may be located on the eighth insulating layer INS8. The ninth insulating layer INS9 may partially cover the side surfaces of the light emitting elements LE. In addition, the ninth insulating layer INS9 may cover the first and second bridge electrodes BE1 and BE2, but at least a portion of each of the first and second bridge electrodes BE1 and BE2 may be exposed without being covered by the ninth insulating layer INS9.

The tenth insulating layer INS10 may be located on the ninth insulating layer INS9. The tenth insulating layer INS10 may partially cover the side surfaces of each of the light emitting elements LE. The tenth insulating layer INS10 may be located on at least a portion of each of the first and second bridge electrodes BE1 and BE2 which is exposed without being covered by the ninth insulating layer INS9. The upper surface of each of the light emitting elements LE may be exposed without being covered by the tenth insulating layer INS10.

The ninth insulating layer INS9 and the tenth insulating layer INS10 may include at least one insulating material, for example, an organic insulating material. For example, each of the ninth insulating layer INS9 and the tenth insulating layer INS10 may include an organic layer such as acryl resin, epoxy resin, phenolic resin, polyamide resin, and/or polyimide resin.

The ninth insulating layer INS9 and the tenth insulating layer INS10 may flatten steps caused by the light emitting elements LE. If the ninth insulating layer INS9 is high enough to cover most of the side surfaces of each of the light emitting elements LE, the tenth insulating layer INS10 may be omitted.

The capping layer CPL may be located on the light emitting elements LE, the ninth insulating layer INS9, and the tenth insulating layer INS10. The capping layer CPL may include at least one insulating material, for example, an inorganic insulating material.

In one or more embodiments, if the light emitting element LE of each of the subpixels SPX emits light of a color corresponding to (e.g., matching) an emission color (or emission wavelength) of the corresponding subpixel SPX, the display panel 100 may not include a light conversion layer. For example, the first overcoat layer OC1 may be located directly on the capping layer CPL.

When the subpixels SPX include light emitting elements LE which emit light corresponding to their respective emission colors, light emitted from the light emitting elements LE can be utilized more efficiently. For example, a decrease in the light efficiency of the subpixels SPX due to light conversion may be prevented. In addition, the color purity of light emitted from the subpixels SPX may be increased, and the color gamut of the subpixels SPX may be increased.

In one or more embodiments, when the light emitting element LE of at least one subpixel SPX emits light of a color different from an emission color (or emission wavelength) of the corresponding subpixel SPX, a light conversion layer may be further located on the light emitting element LE. For example, when the first light emitting element LE1 emits blue light and when the first subpixel SPX1 is a red subpixel which emits red light, a light conversion layer, which covers the first light emitting element LE1, may be placed on the capping layer CPL. The light conversion layer may include light conversion particles (e.g., red quantum dots, etc.) which convert blue light incident from the first light emitting element LE1 into red light. When the subpixels SPX include light emitting elements LE which emit light of the same color, the manufacturing efficiency of the light emitting element layer EDL and the display panel 100 including the light emitting element layer EDL may be increased, and the manufacturing cost may be reduced.

The first overcoat layer OC1 may be located on the capping layer CPL (or the light conversion layer). The first overcoat layer OC1 may be an organic layer including an organic insulating material (e.g., acryl resin, epoxy resin, phenolic resin, polyamide resin, and/or polyimide resin), and an upper surface of the first overcoat layer OC1 may be substantially flat. However, the present disclosure is not limited to this case. For example, the first overcoat layer OC1 may be an inorganic layer including an inorganic insulating material. The first overcoat layer OC1 may be formed to a sufficient thickness to include a substantially flat upper surface or may be planarized through a separate planarization process. Accordingly, the upper surface of the first overcoat layer OC1 may be substantially flat.

The color filter layer CFL may be located on the first overcoat layer OC1. The color filter layer CFL may further include color filters CF that are located in the emission areas EA of the subpixels SPX and a second overcoat layer OC2 that covers the color filters CF.

The color filter layer CFL may include the color filters CF that selectively transmit light corresponding to respective emission colors (or emission wavelengths) of the subpixels SPX. For example, if the first subpixel SPX1, the second subpixel SPX2, and the third subpixel SPX3 are subpixels SPX that emit red light, green light, and blue light, respectively, a red color filter, a green color filter, and a blue color filter may be located in the first emission area EA1 of the first subpixel SPX1, the second emission area EA2 of the second subpixel SPX2, and the third emission area EA3 of the third subpixel SPX3, respectively. In one or more embodiments, the color filters CF of the subpixels SPX may overlap each other in a non-emission area, which surrounds the emission areas EA of the subpixels SPX, to form a light blocking pattern.

The second overcoat layer OC2 may be located on the color filters CF. The second overcoat layer OC2 may be an organic layer including an organic insulating material, and an upper surface of the second overcoat layer OC2 may be substantially flat. However, the present disclosure is not limited to this case. For example, the second overcoat layer OC2 may be an inorganic layer including an inorganic insulating material. The second overcoat layer OC2 may be formed to a sufficient thickness to include a substantially flat upper surface or may be planarized through a separate planarization process. Accordingly, the upper surface of the second overcoat layer OC2 may be substantially flat.

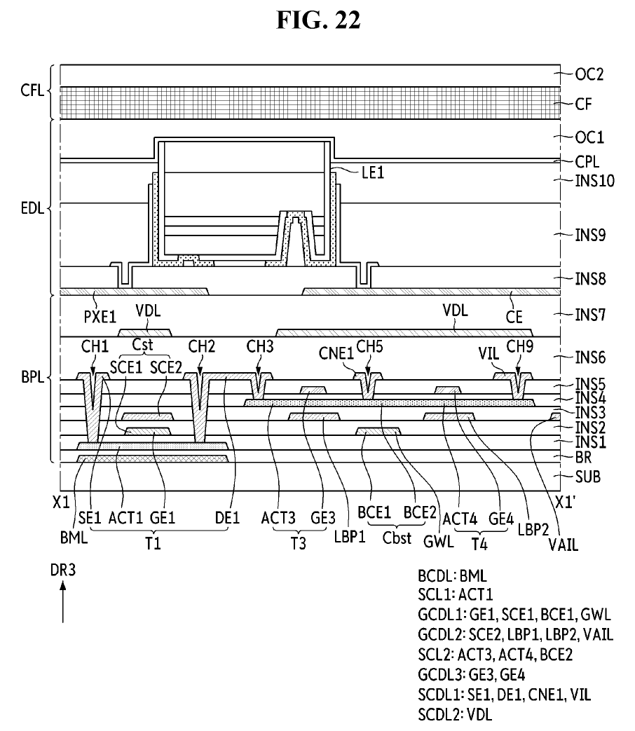

FIG. 22 is a cross-sectional view illustrating an example of a cross-section of a display panel corresponding to line X1-X1’ of FIGS. 9 and 18. For example, FIG. 22 shows an example of a cross-section of a display panel 100 corresponding to a portion of a first subpixel SPX1. Compared with FIG. 19, FIG. 22 shows an embodiment in which the display panel 100 further includes a bottom conductive layer BCDL.

Referring to FIG. 22 in addition to FIGS. 9 through 21, the display panel 100 may further include the bottom conductive layer BCDL located on a substrate SUB. For example, a backplane layer BPL may include the bottom conductive layer BCDL located between the substrate SUB and a barrier layer BR.

The bottom conductive layer BCDL may include a bottom pattern BML located under a first transistor T1. The bottom pattern BML may entirely or partially cover a lower surface of the first active layer ACT1. For example, the bottom pattern BML may be located under the first active layer ACT1 to overlap the channel region of the first active layer ACT1 (e.g., a portion of the first active layer ACT1 that overlaps the first gate electrode GE1).

In one or more embodiments, the bottom conductive layer BCDL may include a light blocking material. For example, the bottom conductive layer BCDL may include a metal, and the bottom pattern BML may be formed as a bottom metal pattern. In one or more embodiments, the bottom pattern BML may be electrically connected to a power line (e.g., a first power line VDL) to which a constant voltage is applied. In one or more embodiments, the bottom pattern BML may be formed in a display area DA as a pattern extending or connected along at least one of the first direction DR1 and the second direction DR2 when viewed on a plane defined by the first direction DR1 and the second direction DR2, but the present disclosure is not limited to this case.

The bottom pattern BML may prevent incidence of external light from under the first transistor T1 to the channel region of the first active layer ACT1. In addition, the bottom pattern BML may disperse charges that gather around the first transistor T1. Accordingly, the operating characteristics of the first transistor T1 may be stabilized.

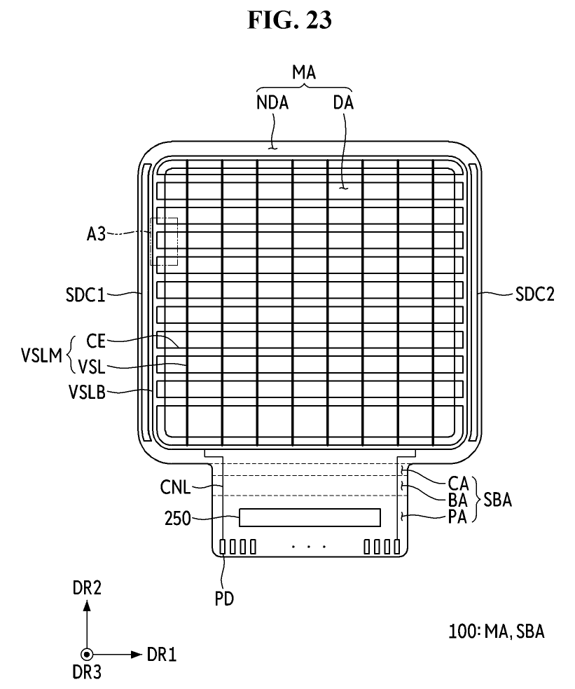

FIG. 23 is a plan view of a display panel according to one or more embodiments. In the description of the embodiment of FIG. 23, elements substantially similar or identical to those of at least one embodiment described above are indicated by like reference numerals, and thus a detailed description thereof will be omitted.

Referring to FIG. 23 in addition to FIGS. 1 through 22, the display panel 100 may include a mesh-shaped power line VSLM, which includes common electrodes CE and second power lines VSL crossing each other in a display area DA. In addition, the display panel 100 may further include a power bus line VSLB, which is connected to the mesh-shaped power line VSLM, and at least one connection line CNL.

The power bus line VSLB may be located in a non-display area NDA disposed around the display area along an edge or a periphery of the display area DA. In one or more embodiments, the power bus line VSLB may be located immediately around the display area DA. For example, at least a portion of the power bus line VSLB may be located between the display area DA and at least one scan driver. For example, at least a portion of the power bus line VSLB located on left and right sides of the display area DA may be located between the display area DA and a first scan driver SDC1 and between the display area DA and a second scan driver SDC2.

In one or more embodiments, the power bus line VSLB may be electrically connected to at least one pad PD located in a pad area PA. For example, the power bus line VSLB may be electrically connected to at least one of the pads PD of the pad area PA by at least a connection line CNL. For example, the power bus line VSLB may be electrically connected to a plurality of pads PD located at both ends of the pad area PA through a plurality of connection lines CNL located at both sides of the non-display area NDA and a sub-area SBA below the display area DA. The power bus line VSLB and a connection line CNL may be integrally formed or may be formed as separate patterns and then electrically connected to each other. At least one pad PD connected to the connection line CNL may be a power pad to which a second driving voltage VSS is applied. The power bus line VSLB may be electrically connected to a power supply unit 500 (see FIG. 3) via a connection line CNL and a pad PD electrically connected to the connection line CNL. A connection structure between the power bus line VSLB and the pad PD is not limited to the above-described embodiment and may vary depending on embodiments. In addition, a connection structure between the power bus line VSLB and the power supply unit 500 may vary depending on the position or type of the power supply unit 500.

In one or more embodiments, the power bus line VSLB may have a reduced or minimized width. For example, as the mesh-shaped power line VSLM is located in the display area DA, wiring resistance may be reduced. Accordingly, even if the width of the power bus line VSLB is reduced, the second driving voltage VSS can be smoothly transmitted to pixels PX. Therefore, the width of the non-display area NDA can be reduced, or the space utilization and/or design structure of the non-display area NDA may be improved or optimized. In addition, as the width of the power bus line VSLB is reduced, the power bus line VSLB may be appropriately placed between the display area DA and at least one scan driver.

In one or more embodiments, the power bus line VSLB may be around (e.g., may surround) the entire display area DA. For example, the power bus line VSLB may be placed on left/right and upper/lower sides of the display area DA to surround all four sides of the display area DA. For example, the power bus line VSLB may have a shape corresponding to that of the display area DA and may completely surround the display area DA. Accordingly, the second driving voltage VSS may be more smoothly transmitted to the common electrodes CE and the second power lines VSL.

The common electrodes CE of the display area DA may extend to the non-display area NDA and may be electrically connected to the power bus line VSLB. For example, each of the common electrodes CE of the display area DA may extend in both directions (or in the first direction DR1) from the display area DA toward the power bus line VSLB and may be connected to the power bus line VSLB in the non-display area NDA located on the left and right sides of the display area DA. Although the power bus line VSLB is integrally formed with the common electrodes CE in FIG. 23, the present disclosure is not limited to this case. For example, the power bus line VSLB and the common electrodes CE may be integrated with each other to form one pattern or may be formed as separate patterns, which are not integrated with each other, and then may be electrically connected to each other.

The second power lines VSL of the display area DA may extend to the non-display area NDA and may be electrically connected to the power bus line VSLB. For example, each of the second power lines VSL of the display area DA may extend in both directions (or in the second direction DR2) from the display area DA toward the power bus line VSLB and may be connected to the power bus line VSLB in the non-display area NDA located on the upper and lower sides of the display area DA. The power bus line VSLB and the second power lines VSL may be integrated with each other to form one pattern or may be formed as separate patterns, which are not integrated with each other, and then may be electrically connected to each other.

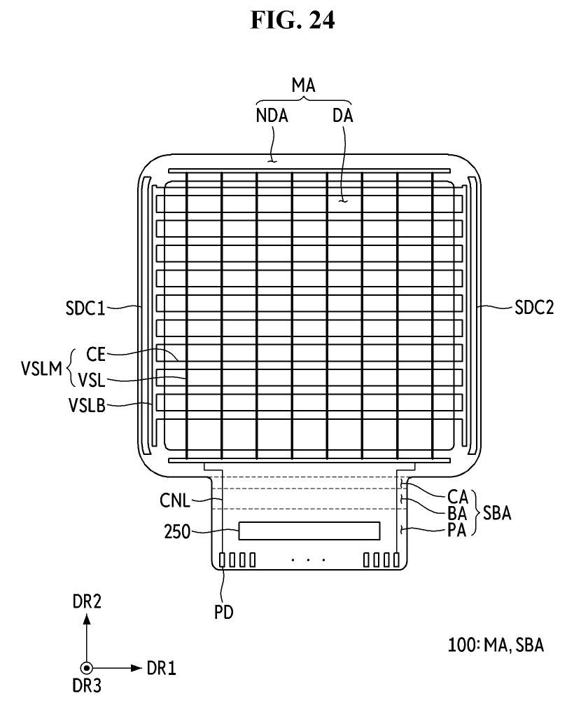

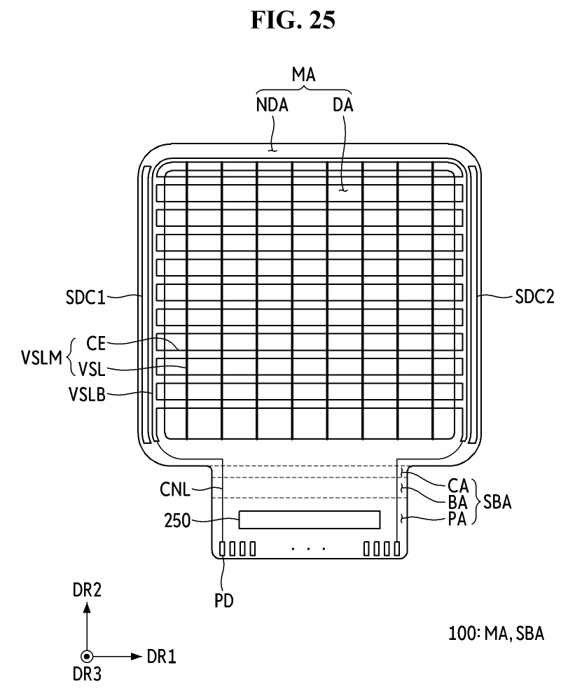

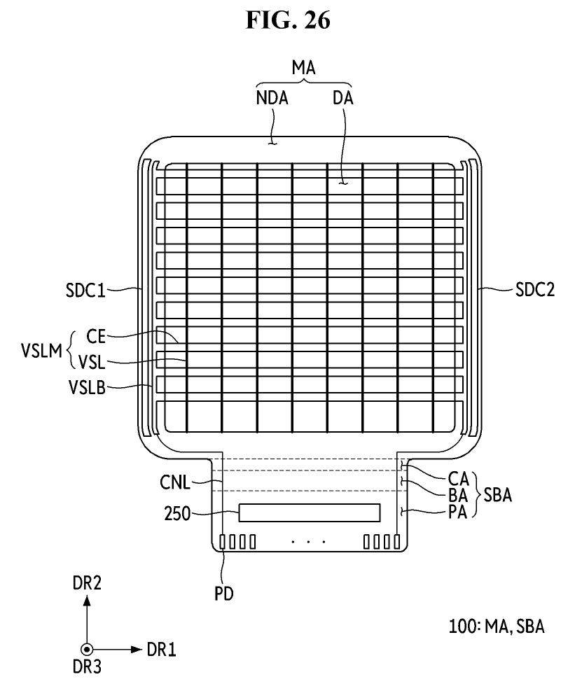

FIG. 24 is a plan view of a display panel according to one or more embodiments. FIG. 25 is a plan view of a display panel according to one or more embodiments. FIG. 26 is a plan view of a display panel according to one or more embodiments. For example, FIGS. 24, 25, and 26 show embodiments different from the embodiment of FIG. 23 in relation to a power bus line VSLB.

Referring to FIGS. 24 through 26 in addition to FIG. 23, the shape, size, and/or position of the power bus line VSLB may vary depending on embodiments.

In one or more embodiments, the power bus line VSLB may include a plurality of patterns that is located on different sides of a display area DA and separated from each other, as illustrated in FIG. 24. For example, the power bus line VSLB may include a plurality of patterns that is located on left, right, upper, and lower sides of the display area DA, respectively, and are separated from each other. Patterns of the power bus line VSLB, which are located on the left and right sides of the display area DA, may be connected to both ends of each of common electrodes CE, and patterns of the power bus lines VSLB, which are located on the upper and lower sides of the display area DA, may be connected to both ends of each of second power lines VSL. Alternatively, the power bus line VSLB may include only some of the patterns located on the left, right, upper, and lower sides of the display area DA. For example, the power bus lines VSLB may include only one of the patterns located on the upper and lower sides of the display area DA. In this case, the pattern of the power bus lines VSLB, which is located on the upper or lower side of the display area DA, may be connected to an end of each of the second power lines VSL. Similarly, the power bus line VSLB may include only one of the patterns located on the left and right sides of the display area DA. In this case, the pattern of the power bus line VSLB, which is located on the left or right side of the display area DA, may be connected to an end of each of the common electrodes CE.

In one or more embodiments, the power bus line VSLB may surround the display area DA except for one of the upper and lower sides of the display area DA. For example, the power bus line VSLB may surround the left, right, and upper sides of the display area DA as illustrated in FIG. 25. In this case, the power bus line VSLB may be connected to both ends of each of the common electrodes CE on the left and right sides of the display area DA and may be connected to an end of each of the second power lines VSL on the upper side of the display area DA. Alternatively, the power bus line VSLB may surround the left, right, and lower sides of the display area DA. In this case, the power bus line VSLB may be connected to an end of each of the second power lines VSL on the lower side of the display area DA.

In one or more embodiments, the power bus line VSLB may be located only on the left and right sides of the display area DA and may not be located on the upper and lower sides of the display area DA, as illustrated in FIG. 26. In this case, the power bus line VSLB may be connected to both ends of each of the common electrodes CE on the left and right sides of the display area DA, and the second power lines VSL may be electrically connected to the common electrodes CE in the display area DA.

The power bus line VSLB may have a form in which one of the above-described embodiments is applied alone or in which at least two of the above-described embodiments are applied in combination. The power bus line VSLB may also have various forms in addition to the above-described embodiments.

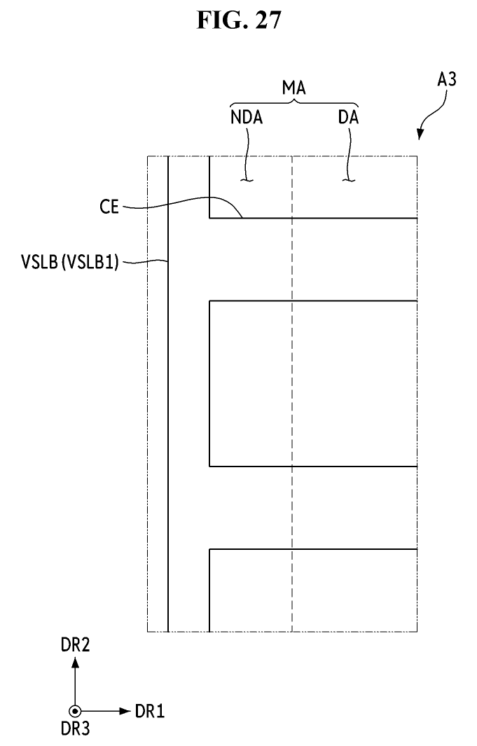

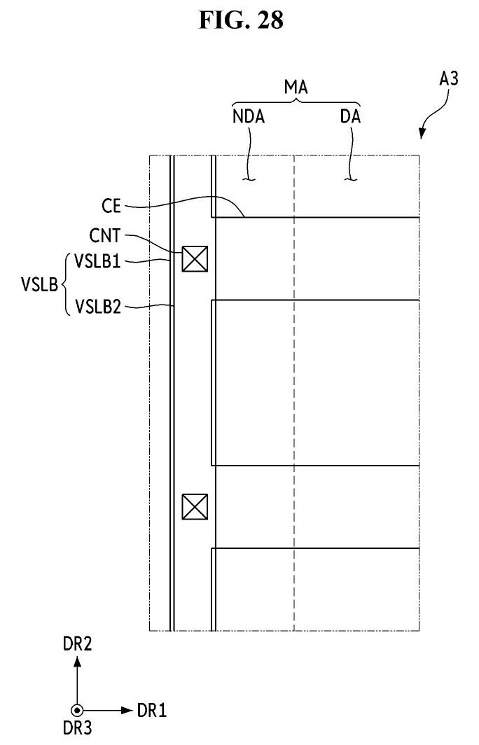

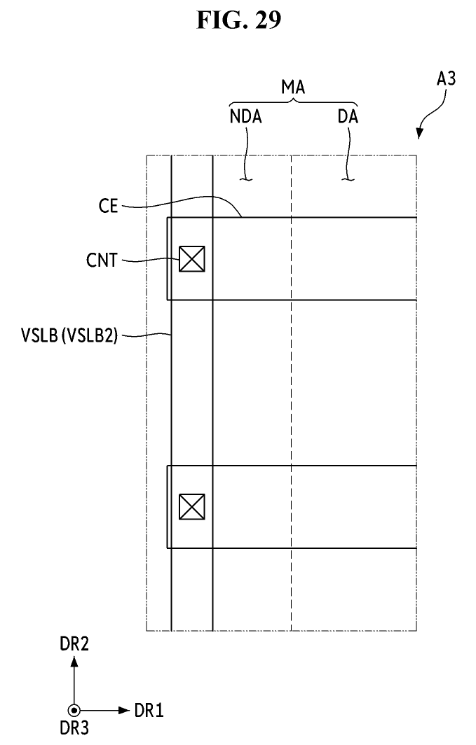

FIG. 27 is a detailed plan view of an area A3 of FIG. 23. FIG. 28 is a detailed plan view of the area A3 of FIG. 23. FIG. 29 is a detailed plan view of the area A3 of FIG. 23. For example, FIGS. 27 through 29 show part of the common electrodes CE and the power bus line VSLB located in the area A3 of FIG. 23 and show different embodiments in relation to the structure of the common electrodes CE and the power bus line VSLB.

Referring to FIGS. 27 through 29 in addition to FIGS. 23 through 26, the power bus line VSLB may include a pattern which is integrated or not integrated with the common electrodes CE. In addition, the power bus line VSLB may be formed as a single layer or a multilayer.

In one or more embodiments, the common electrodes CE and the power bus line VSLB may be integrally formed as illustrated in FIG. 27 and may be formed as substantially one pattern. For example, the power bus line VSLB may be formed as a single layer including a first wiring layer VSLB1 which is located in (e.g., at) the same layer as the common electrodes CE and extends from the common electrodes CE.

In one or more embodiments, the power bus line VSLB may be formed as a multilayer including a first wiring layer VSLB1, which is integrally formed with the common electrodes CE, and a second wiring layer VSLB2, which overlaps the first wiring layer VSLB1, as illustrated in FIG. 28. In one or more embodiments, the second wiring layer VSLB2 may be located within a backplane layer BPL. For example, the second wiring layer VSLB2 may be formed as a single-layer or multilayer pattern included in at least one of the conductive layers included in the backplane layer BPL. In one or more embodiments, the first wiring layer VSLB1 and the second wiring layer VSLB2 may be located in different conductive layers with at least one insulating layer located between the first wiring layer VSLB1 and the second wiring layer VSLB2 and may be electrically connected to each other through at least one contact hole CNT (e.g., a plurality of contact holes CNT) formed in the at least one insulating layer. Although FIG. 28 discloses a structure in which a plurality of contact holes CNT is arranged along the second direction DR2, the present disclosure is not limited to this case. For example, the contact holes CNT of FIG. 28 may also be integrated into a single contact hole CNT extending in the second direction DR2 or an opening of an insulating layer (e.g., an opening penetrating an insulating layer between the first wiring layer VSLB1 and the second wiring layer VSLB2 and extending in the second direction DR2).

In one or more embodiments, the power bus line VSLB may include a second wiring layer VSLB2, which is formed as a separate pattern from the common electrodes CE and connected to the common electrodes CE, as illustrated in FIG. 29. In one or more embodiments, the second wiring layer VSLB2 may be electrically connected to each of the common electrodes CE through at least one contact hole CNT (or an opening of an insulating layer).

The power bus line VSLB may have a structure in which one of the above-described embodiments is applied alone or in which at least two of the above-described embodiments are applied in combination. For example, the power bus line VSLB may include at least one of the first wiring layer VSLB1 or the second wiring layer VSLB2 and may be electrically connected to the common electrodes CE. In addition, the power bus line VSLB may have various structures in addition to the above-described embodiments.

According to the embodiments described with reference to FIGS. 3 through 29, a display device 10 may include common electrodes CE and second power lines VSL, which cross each other in a display area DA. The common electrodes CE and the second power lines VSL may be electrically connected to each other to form a mesh-shaped power line VSLM. In the display device 10 according to the embodiments and an electronic device including the same, a drop of a second driving voltage VSS transmitted to pixels PX through the common electrodes CE and the second power lines VSL may be reduced. Accordingly, the power consumption of the display device 10 and the electronic device including the same may be reduced.

Additionally, the display device 10 according to the embodiments may further include a power bus line VSLB which is located in a non-display area NDA and electrically connected to the common electrodes CE and the second power lines VSL of the display area DA. In one or more embodiments, because the common electrodes CE and the second power lines VSL are connected in a mesh form, wiring resistance may be reduced. Accordingly, a width of the power bus line VSLB may be reduced. In one or more embodiments, at least a portion of the power bus line VSLB may be located between the display area DA and a scan driver (e.g., a first scan driver SDC1 and a second scan driver SDC2). In the display device 10 according to the embodiments and the electronic device including the same, the design structure of a display panel 100 including the power bus line VSLB may be improved, and the size of the non-display area NDA may be reduced or minimized.

In one or more embodiments, pixel circuits PXC of a second subpixel SPX2 and a third subpixel SPX3 included in one pixel PX may be designed symmetrically in a flipped form. Therefore, pixel circuits PXC and wirings can be efficiently placed in the display area DA, and the integration density of the pixels PX may be improved. Accordingly, the design structure of the display panel 100 (e.g., the design structure of a backplane layer BPL) may be improved or optimized, and a design space for placing additional wiring, etc. may be secured. In one or more embodiments, the second power lines VSL may be placed in the secured design space. Accordingly, the mesh-shaped power line VSLM can be appropriately or easily formed in the display area DA.

In one or more embodiments, emission control lines EL of at least two of the subpixels SPX that form one pixel PX may be separated. For example, a first subpixel SPX1 and second and third subpixels SPX2 and SPX3 may be connected to different emission control lines EL. Accordingly, an emission period of the first subpixel SPX1 and an emission period of the second and third subpixels SPX2 and SPX3 may be independently or individually controlled. For example, a driving current Ids of the first subpixel SPX1 and a driving current Ids of the second and third subpixels SPX2 and SPX3 may be appropriately controlled or differentiated according to the optimal consumption efficiency of light emitting elements LE included in the subpixels SPX, and the emissions periods of the first subpixel SPX1 and the second and third subpixels SPX2 and SPX3 may be individually controlled according to the respective driving currents Ids to uniformly maintain the luminance of the subpixels SPX. Accordingly, the lifespan, image quality, and power consumption of the display device 10 may be improved.

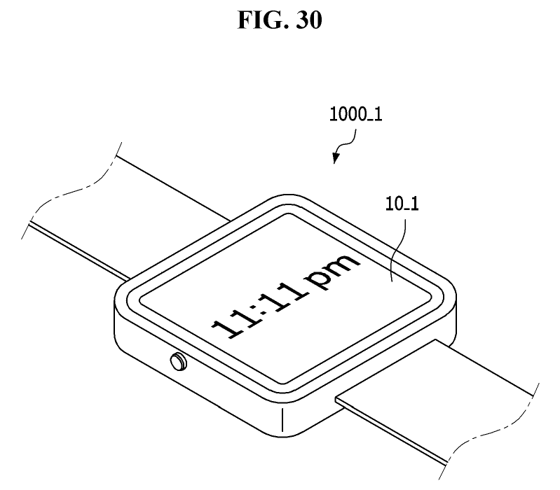

FIG. 30 is an example view of a smart watch 1000_1 including a display device 10_1 according to one or more embodiments. Referring to FIG. 30, the display device 10_1 according to the embodiment may be applied to the smart watch 1000_1 which is one of smart devices.

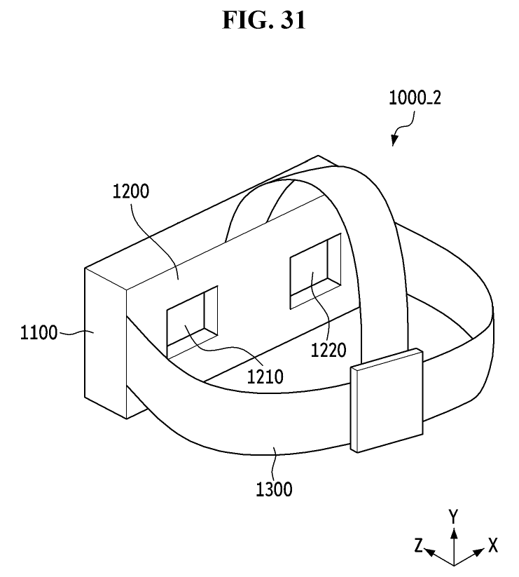

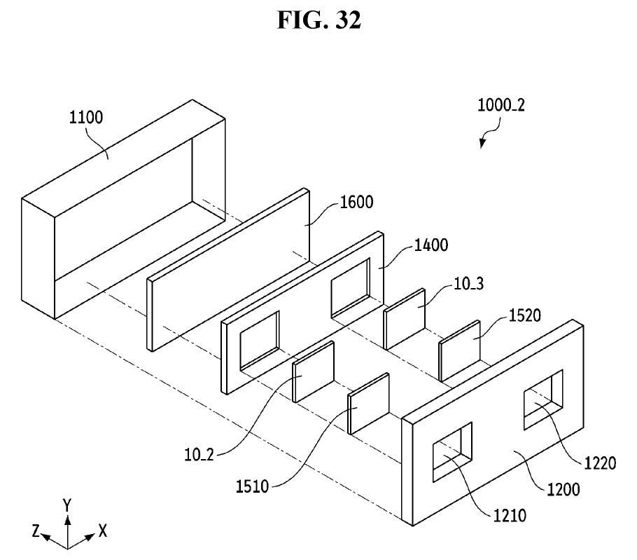

FIGS. 31 and 32 are example views of a head-mounted display device including display devices according to one or more embodiments. FIGS. 31 and 32 show a VR device as a head-mounted display device 1000_2 to which display devices 10_2 and 10_3 according to an embodiment are applied.

Referring to FIGS. 31 and 32, a head-mounted display device 1000_2 according to one or more embodiments includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to a user’s left eye, and the second display device 10_3 provides an image to the user’s right eye. Each of the first display device 10_2 and the second display device 10_3 may be the display device 10 according to at least one of the embodiments described above. Therefore, a description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600 and may be located between the second display device 10_3 and the control circuit board 1600. The middle frame 1400 supports and fixes the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user’s left eye to the first display device 10_2 and transmit the digital video data DATA corresponding to a right image optimized for the user’s right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are located separately in FIGS. 31 and 32, the present disclosure is not limited to this case. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is magnified as a virtual image by the first optical member 1510, through the first eyepiece 1210 and can view an image of the second display device 10_3, which is magnified as a virtual image by the second optical member 1520, through the second eyepiece 1220.

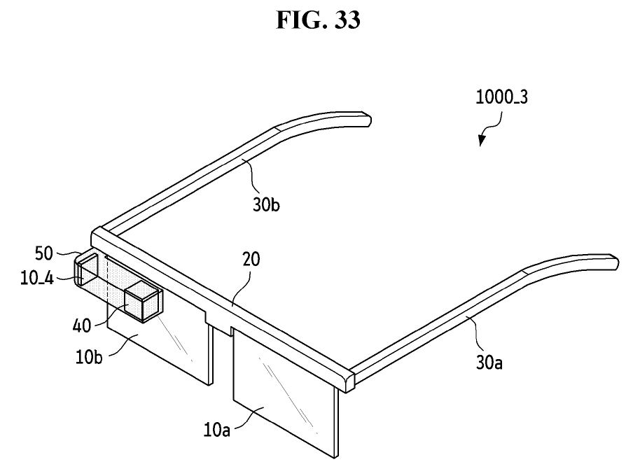

The head-mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1100 is implemented to be lightweight and small, the head-mounted display device 1000_2 may include an eyeglass frame as illustrated in FIG. 33 instead of the head-mounted band 1300.

In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 33 is an example view of a head-mounted display device including a display device according to one or more embodiments. FIG. 33 shows a VR (or AR) device as a head-mounted display device to which a display device 10_4 according to one or more embodiments is applied.

Referring to FIG. 33, a head-mounted display device 1000_3 according to one or more embodiments may be a device in the form of glasses. The head-mounted display device 1000_3 according to the embodiment may include the display device 10_4, a left lens 10a, a right lens 10b, a support frame 20, eyeglass frame legs 30a and 30b, a reflective member 40, and a display device housing 50.

In FIG. 33, a case where the head-mounted display device 1000_3 is a glasses-type display device including the eyeglass frame legs 30a and 30b is illustrated as an example. That is, the head-mounted display device 1000_3 according to the embodiment is not limited to the one shown in FIG. 33 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye. For example, the user may view an AR image, into which a virtual image displayed on the display device 10_4 and a real image viewed through the right lens 10b are combined, through the right eye.

Although the display device housing 50 is located at a right end of the support frame 20 in FIG. 33, the present disclosure is not limited to this case. For example, the display device housing 50 may also be located at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

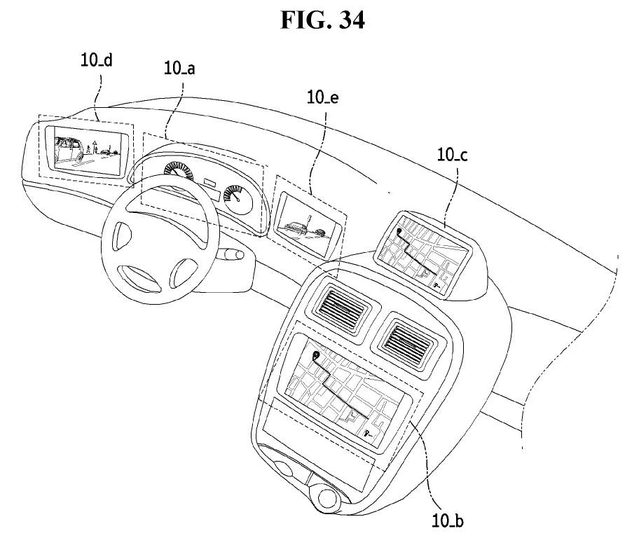

FIG. 34 is an example view illustrating a vehicle instrument cluster and center fascia including display devices according to one or more embodiments. FIG. 34 illustrates a vehicle to which display devices 10_a, 10_b, 10_c, 10_d, and 10_e according to one or more embodiments are applied.

Referring to FIG. 34, the display devices 10_a, 10_b, and 10_c, according to the embodiment may be applied to an instrument cluster of the vehicle, a center fascia of the vehicle, and/or a center information display (CID) located on a dashboard of the vehicle. In addition, the display devices 10_d and 10_e according to the embodiment may be applied to room mirror displays that replace side mirrors of the vehicle.

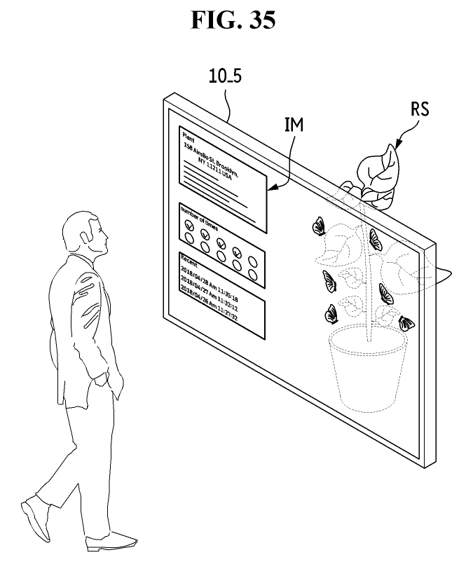

FIG. 35 is an example view of a transparent display device including a display device according to one or more embodiments.

Referring to FIG. 35, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to a transparent display device, a substrate of the display device 10_5 may include a light transmitting portion that can transmit light or may include a material that can transmit light.

In FIGS. 30 through 35, the smart watch 1000_1, the head-mounted display devices 1000_2 and 1000_3, the instrument cluster and center fascia of the vehicle, and the transparent display device are shown as examples of electronic devices that may include the display devices 10, 10_1, 10_2, 10_3, 10_4, 10_5, 10_a, 10_b, 10_c, 10_d and 10_e according to the embodiments. However, the present disclosure is not limited to these examples. For example, a display device 10 according to at least one of the embodiments described above may be included in electronic devices of other types or structures in addition to the electronic devices shown in FIGS. 30 through 35.

An electronic device according to one or more embodiments may further include additional elements in addition to a display device 10. For example, the electronic device may further include a housing or a case for accommodating the display device 10, in addition to the display device 10 (or display module) including a display panel 100. In addition, the electronic device may further include at least one of a processor that controls the display device 10 or the display module (e.g., a processor that transmits digital video data DATA and/or timing signals to the timing controller 251 of FIG. 3), a memory that is referenced by the processor (e.g., a memory that stores the digital video data DATA or an input control signal), and a power module (e.g., a power module that includes a power supply module, such as a power adapter or a battery device, and a power conversion module for generating power necessary for the operation of the electronic device (e.g., a power supply voltage, etc. input to the power supply unit 500 of FIG. 3) by converting power supplied by the power supply module).

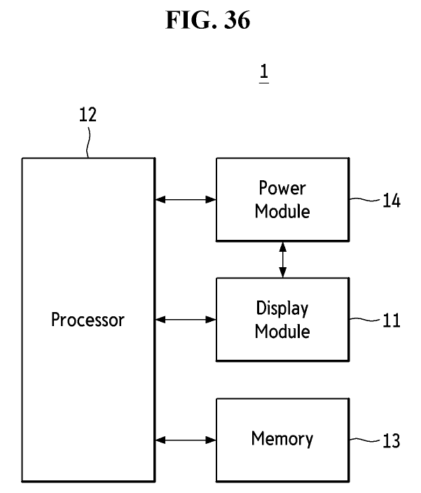

FIG. 36 is a block diagram of an electronic device 1 according to one or more embodiments. Referring to FIG. 36, the electronic device 1 according to the embodiment may include a display module 11, a processor 12, a memory 13, and a power module 14.

The electronic device 1 may output various information in the form of images through the display module 11. When the processor 12 executes an application stored in the memory 13, image information provided by the application may be provided to a user through the display module 11.

The display module 11 may include a display panel 100 for displaying an image. For example, the display module 11 may include a display panel 100 according to at least one of the embodiments described above.

The processor 12 may include at least one of a central processing unit (CPU), an application processor (AP), a graphic processing unit (GPU), a communication processor (CP), an image signal processor (ISP), and/or a controller.

The memory 13 may store data information necessary for the operation of the processor 12 or the display module 11. For example, the memory 13 may store an image data signal and/or an input control signal.

The processor 12 may control the display module 11 using information stored in the memory 13. The processor 12 may transmit an image data signal and/or an input control signal stored in the memory 13 to the display module 11. For example, when the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module, which generates power necessary for the operation of the electronic device 1 by converting power supplied by the power supply module.

At least one of the elements of the electronic device 1 described above may be included in the display device 10 according to the above-described embodiments. In addition, some of individual modules functionally included in one module may be included in the display device 10, and other modules may be provided separately from the display device 10. For example, the display device 10 may include the display module 11, and the processor 12, the memory 13, and the power module 14 may be provided not in the display device 10, but in the form of other devices within the electronic device 1.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
pixels located in a display area where an image is displayed, each of the pixels comprising a plurality of pixel circuits located in a backplane layer of the display device, a plurality of pixel electrodes and a common electrode located on the backplane layer, and a plurality of light emitting elements electrically connected between the pixel electrodes and the common electrode;
first power lines located in the backplane layer in the display area and electrically connected to the pixel circuits of the pixels; and
second power lines located in the backplane layer in the display area and electrically connected to the common electrode of the pixels,
wherein the common electrode and the second power lines cross each other in the display area and are electrically connected to each other.

2. The display device of claim 1, further comprising a power bus line located in a non-display area surrounding the display area, wherein the common electrode is electrically connected to the power bus line by extending to the non-display area.

3. The display device of claim 2, further comprising at least one scan driver located in the non-display area and electrically connected to the pixel circuits of the pixels, wherein at least a portion of the power bus line is located between the display area and the scan driver.

4. The display device of claim 2, wherein the power bus line is located on a left side and a right side of the display area, and the common electrode extends in both directions from the display area toward the power bus line.

5. The display device of claim 4, wherein the power bus line is further located on at least one of an upper side and a lower side of the display area.

6. The display device of claim 2, wherein the power bus line comprises at least one of a first wiring layer which is located on a same layer as the common electrode and extends from the common electrode, and a second wiring layer which is located in the backplane layer and electrically connected to the common electrode through at least one contact hole.

7. The display device of claim 1, wherein the pixels are arranged along a first direction and a second direction in the display area,
wherein two or more pixels of the pixels of each pixel row are arranged along the first direction and share the common electrode extending in the first direction, and
wherein common electrodes of two or more pixels of the pixels, which are arranged along the second direction, are arranged along the second direction.

8. The display device of claim 7, wherein the second power lines are arranged along the first direction in the display area and each of the second power lines extend in the second direction.

9. The display device of claim 8, wherein the pixel circuits comprise a first pixel circuit, a second pixel circuit, and a third pixel circuit arranged along the first direction in each pixel area where each of the pixels is located.

10. The display device of claim 9, wherein the second power lines are located between the first pixel circuit and the second pixel circuit of each of the pixels.

11. The display device of claim 9, wherein the second power lines are located between pixel circuits of two pixels adjacent to each other in the first direction.

12. The display device of claim 9, wherein the pixel electrodes comprise a first pixel electrode, a second pixel electrode, and a third pixel electrode located on the first pixel circuit, the second pixel circuit, and the third pixel circuit, respectively, and are electrically connected to the first pixel circuit, the second pixel circuit, and the third pixel circuit, respectively, and
wherein the common electrode is located on a same layer as the first pixel electrode, the second pixel electrode, and the third pixel electrode and faces the first pixel electrode, the second pixel electrode, and the third pixel electrode in the second direction.

13. The display device of claim 12, wherein the light emitting elements comprise a first light emitting element located on the first pixel electrode and the common electrode, a second light emitting element located on the second pixel electrode and the common electrode, and a third light emitting element located on the third pixel electrode and the common electrode.

14. The display device of claim 9, wherein the first power lines are arranged along the first direction in the display area and extend in the second direction.

15. The display device of claim 14, wherein the first power lines and the second power lines are located on a same layer and spaced from each other in the first direction.

16. The display device of claim 14, wherein one of the first power lines overlaps the first pixel circuit, and an other of the first power lines overlaps the second pixel circuit and the third pixel circuit.

17. The display device of claim 16, wherein the second pixel circuit and the third pixel circuit are connected in common to the other of the first power lines and are symmetrical to each other with respect to the other of the first power lines.

18. The display device of claim 17, further comprising:
a first emission control line extending in the first direction in the display area and electrically connected to the first pixel circuit; and
a second emission control line extending in the first direction in the display area and electrically connected to the second pixel circuit and the third pixel circuit.

19. The display device of claim 1, wherein the common electrode and the second power lines are electrically connected to each other in the display area through a plurality of contact holes in an insulating layer located between the common electrode and the second power lines.

20. An electronic device comprising:
a display module comprising a display panel;
a memory configured to store an image data signal or an input control signal; and
a processor configured to transmit the image data signal or the input control signal, which is stored in the memory, to the display module,
wherein the display panel comprises:
pixels located in a display area, each of the pixels comprising a plurality of pixel circuits located in a backplane layer of the display panel, a plurality of pixel electrodes and a common electrode located on the backplane layer, and a plurality of light emitting elements electrically connected between the pixel electrodes and the common electrode;
first power lines located in the backplane layer in the display area and electrically connected to the pixel circuits of the pixels; and
second power lines located inside the backplane layer in the display area and electrically connected to the common electrode of the pixels,
wherein the common electrode and the second power lines cross each other inside the display area and are electrically connected to each other.
